(19) United States
(12) Patent Application Publication
(10) Pub. No.: US 2023/0350289 A1
(43) Pub. Date: Nov. 2, 2023

(54) COMPOSITION FOR FORMING UNDERLAYER FILM, COLOR FILTER, METHOD FOR MANUFACTURING COLOR FILTER, SOLID-STATE IMAGING ELEMENT, AND IMAGE DISPLAY DEVICE

(71) Applicant: FUJIFILM Corporation, Tokyo (JP)

(72) Inventors: Kazuya OOTA, Haibara-gun (JP); Akio MIZUNO, Haibara-gun (JP); Shoichi NAKAMURA, Haibara-gun (JP); Masahiro MORI, Haibara-gun (JP); Hirotaka MOTOHASHI, Haibara-gun (JP)

(73) Assignee: FUJIFILM Corporation, Tokyo (JP)

(21) Appl. No.: 18/165,758

(22) Filed: Feb. 7, 2023

Related U.S. Application Data
(63) Continuation of application No. PCT/JP2021/030943, filed on Aug. 24, 2021.

(30) Foreign Application Priority Data
Aug. 28, 2020 (JP) 2020-143986

(51) Int. Cl. G03F 7/00; G03F 7/11; G03F 7/20; H04N 25/11; G03F 7/16; G03F 7/028

(52) U.S. Cl. CPC G03F 7/0007; G03F 7/028; G03F 7/11; G03F 7/16; G03F 7/2002; H04N 25/11

(57) ABSTRACT

Provided are a composition for forming an underlayer film of a color filter, the composition including a resin A and a solvent B, in which the resin A includes a resin a-1 having an alkyleneoxy structure, a content of the resin a-1 in a total solid content of the composition for forming an underlayer film is 50% by mass or more, and a concentration of solid contents of the composition for forming an underlayer film is 1% by mass or less; a color filter using the composition for forming an underlayer film; a method for manufacturing a color filter; a solid-state imaging element; and an image display device.

### CROSS REFERENCE TO RELATED APPLICATIONS

This application is a Continuation of PCT International Application No. PCT/JP2021/030943 filed on Aug. 24, 2021, which claims priority under 35 U.S.C §119(a) to Japanese Patent Application No. 2020-143986 filed on Aug. 28, 2020. Each of the above application(s) is hereby expressly incorporated by reference, in its entirety, into the present application.

### BACKGROUND OF THE INVENTION

### 1. Field of the Invention

The present invention relates to a composition for forming an underlayer film of a color filter. The present invention further relates to a color filter, a method for manufacturing a color filter, a solid-state imaging element, and an image display device.

### 2. Description of the Related Art

In recent years, as a digital camera, a mobile phone with a camera, and the like have been further spreading, there has been a greatly increasing demand for a solid-state imaging element such as a charge coupled device (CCD) image sensor. A color filter has been used as a key device in a display or an optical element.

In the manufacturing of the color filter, for the purpose of improving adhesiveness of a pixel to a support, an underlayer film is formed on the support, and then the pixel is formed on the underlayer film.

WO2016/013344A discloses an invention relating to a resin composition for forming an underlayer film of a color filter, which contains a homopolymer or copolymer having a specific structural unit, an acid compound, a solvent, and a crosslinking agent in an amount of 0% to 35% by mass with respect to a content of a solid content of the resin composition.

### SUMMARY OF THE INVENTION

In the manufacturing of the color filter, by forming the underlayer film on the support, the adhesiveness of the pixel can be improved, but in a case where the pixel of the color filter is formed on the underlayer film, residues tend to be generated on the underlayer film between pixels (in a non-pixel portion). Even in the invention disclosed in WO2016/013344A, it cannot be said that the generation of the residues on the underlayer film can be sufficiently suppressed, and there is room for further improvement.

Therefore, an object of the present invention is to provide a composition for forming an underlayer film, that an underlayer film with suppressed generation of residues on underlayer film can be formed in a case where a pixel is formed on the underlayer film. Another object of the present invention is to provide a color filter, a method for manufacturing a color filter, a solid-state imaging element, and an image display device.

According to the studies conducted by the present inventor, it has been found that the above-described objects can be achieved by using a composition for forming an underlayer film, which will be described later, thereby leading to completion of the present invention. The present invention provides the following.

<1> A composition for forming an underlayer film of a color filter, the composition comprising:
a resin A; and
a solvent B,
in which the resin A includes a resin a-1 having an alkyleneoxy structure,
a content of the resin a-1 in a total solid content of the composition for forming an underlayer film is 50% by mass or more, and
a concentration of solid contents of the composition for forming an underlayer film is 1% by mass or less.

<2> The composition for forming an underlayer film according to <1>,

in which a content of the resin A in the total solid content of the composition for forming an underlayer film is 50% by mass or more.

<3> The composition for forming an underlayer film according to <1> or <2>,
in which the alkyleneoxy structure included in the resin a-1 is a structure represented by Formula (AO-1),

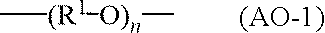

in the formula, R¹ represents an alkylene group and n represents a number of 2 or more.

<4> The composition for forming an underlayer film according to any one of <1> to <3>,

in which an acid value of the resin a-1 is 40 mgKOH/g or less.

<5> The composition for forming an underlayer film according to any one of <1> to <4>,

in which the resin a-1 includes a polymerizable group.

<6> The composition for forming an underlayer film according to any one of <1> to <4>,

in which the resin a-1 includes a repeating unit having a group including an alkyleneoxy structure and a repeating unit having a polymerizable group.

<7> The composition for forming an underlayer film according to <5> or <6>,

in which the polymerizable group is an ethylenically unsaturated bond-containing group or a cyclic ether group.

<8> The composition for forming an underlayer film according to any one of <1> to <7>, further comprising:

a surfactant.

<9> The composition for forming an underlayer film according to any one of <1> to <8>, further comprising:

a polymerizable compound other than the resin A.

<10> The composition for forming an underlayer film according to <9>,

in which a total content of the resin A and the polymerizable compound in the total solid content of the composition for forming an underlayer film is 70% to 100% by mass.

<11> The composition for forming an underlayer film according to <9> or <10>,
in which the polymerizable compound includes a compound having an ethylenically unsaturated bond-containing group, and
the composition for forming an underlayer film further includes a photopolymerization initiator.

<12> A color filter comprising:
a support;
an underlayer film formed on the support; and
a pixel formed on the underlayer film,
in which the underlayer film includes a resin a-1 having an alkyleneoxy structure in an amount of 50% by mass or more, and
a film thickness of the underlayer film is 30 nm or less.

<13> The color filter according to <12>,
in which a partition wall is formed on a surface of the support,
the underlayer film is formed on the support and in a region comparted by the partition wall, and
the pixel is formed on the underlayer film.

<14> A method for manufacturing a color filter, comprising:
a step of forming an underlayer film by applying the composition for forming an underlayer film according to any one of <1> to <10> onto a support; and
a step of forming a pixel on the underlayer film,
in which the step of forming the pixel includes a step of applying a composition for forming a pixel to form a composition layer for forming a pixel, a step of exposing the composition layer for forming a pixel in a patterned manner, and a step of removing a non-exposed portion of the composition layer for forming a pixel by development.

<15> The method for manufacturing a color filter according to <14>,

in which in the exposing step, the composition layer for forming a pixel is exposed by irradiation with light having a wavelength of 300 nm or less.

<16> The method for manufacturing a color filter according to <14> or <15>,

in which the step of forming the underlayer film and the step of forming the pixel are alternately performed two or more times to form two or more types of pixels.

<17> A solid-state imaging element comprising:

the color filter according to <12> or <13>.

<18> An image display device comprising:

the color filter according to <12> or <13>.

According to the present invention, it is possible to provide a composition for forming an underlayer film, that an underlayer film with suppressed generation of residues on underlayer film can be formed in a case where a pixel is formed on the underlayer film. In addition, according to the present invention, it is possible to provide a color filter, a method for manufacturing a color filter, a solid-state imaging element, and an image display device.

### BRIEF DESCRIPTION OF THE DRAWINGS

FIG. 1 is a side-sectional view showing an embodiment of a support having a partition wall.

FIG. 2 is a plan view as viewed from directly above the support.

FIG. 3 is a view showing an embodiment of a color filter.

### DESCRIPTION OF THE PREFERRED EMBODIMENTS

Hereinafter, the details of the present invention will be described.

In the present specification, unless specified as a substituted group or as an unsubstituted group, a group (atomic group) denotes not only a group (atomic group) having no substituent but also a group (atomic group) having a substituent. For example, an “alkyl group” includes not only an alkyl group having no substituent (unsubstituted alkyl group), but also an alkyl group having a substituent (substituted alkyl group).

In the present specification, unless specified otherwise, “exposure” denotes not only exposure using light but also drawing using a corpuscular beam such as an electron beam or an ion beam. In addition, generally, examples of the light used for exposure include an actinic ray or radiation, for example, a bright light spectrum of a mercury lamp, a far ultraviolet ray represented by excimer laser, an extreme ultraviolet ray (EUV light), an X-ray, or an electron beam.

In the present specification, a numerical range represented by “to” means a range including numerical values before and after “to” as a lower limit value and an upper limit value.

In the present specification, a total solid content denotes the total mass of all the components of the composition excluding a solvent.

In the present specification, “(meth)acrylate” represents either or both of acrylate and methacrylate, “(meth)acryl” represents either or both of acryl and methacryl, “(meth)allyl” represents either or both of allyl and methallyl, and “(meth)acryloyl” represents either or both of acryloyl and methacryloyl.

In the present specification, in structural formulae, Me represents a methyl group, Et represents an ethyl group, Bu represents a butyl group, and Ph represents a phenyl group.

In the present specification, the term “step” is not only an independent step, but also includes a step which is not clearly distinguished from other steps in a case where an intended action of the step is obtained.

In the present specification, a weight-average molecular weight (Mw) and a number-average molecular weight (Mn) are each defined as a value in terms of polystyrene through measurement by means of gel permeation chromatography (GPC).

In the present specification, symbols (for example, A, B, and the like) added before or after the name are terms used to distinguish the constitutional components, and the type of the constitutional components, the number of constitutional components, and the superiority or inferiority of the constitutional components are not limited.

### Composition for Forming Underlayer Film

The composition for forming an underlayer film of a color filter according to an embodiment of the present invention includes a resin A and a solvent B, in which the resin A includes a resin a-1 having an alkyleneoxy structure, a content of the resin a-1 in a total solid content of the composition for forming an underlayer film is 50% by mass or more, and a concentration of solid contents of the composition for forming an underlayer film is 1% by mass or less.

By manufacturing a color filter in which a pixel is formed on an underlayer film formed of the composition for forming an underlayer film according to the embodiment of the present invention, it is possible to suppress generation of residues in a non-pixel portion (between pixels) on the underlayer film. The reason for obtaining such an effect is presumed as follows. That is, since the composition for forming an underlayer film according to the embodiment of the present invention includes the resin a-1 having an alkyleneoxy structure in an amount of 50% by mass or more in the total solid content, an underlayer film having high hydrophilicity can be formed. It is presumed that, due to the high hydrophilicity of the underlayer film, interaction with a coloring material such as a pigment on the surface of the underlayer film can be weakened. Therefore, for example, in a case where a composition layer for forming a pixel is formed by applying a composition for forming a pixel, the composition layer for forming a pixel is exposed in a patterned manner, and then a non-exposed portion of the composition layer for forming a pixel is removed by development to form a pixel, the composition layer for forming a pixel in the non-exposed portion can be sufficiently removed by the development, and as a result, it is presumed that the generation of residues in the non-pixel portion (between pixels) on the underlayer film can be suppressed.

In addition, since the concentration of solid contents of the composition for forming an underlayer film is 1% by mass or less, even in a case where there is a step on a surface of the support or a partition wall is provided on the surface of the support, the underlayer film can be formed on the surface of the support.

The concentration of solid contents of the composition for forming an underlayer film according to the embodiment of the present invention is preferably 0.01% to 1% by mass. The lower limit is preferably 0.05% by mass or more and more preferably 0.1% by mass or more. The upper limit is preferably 0.7% by mass or less and more preferably 0.5% by mass or less. In a case where the concentration of solid contents of the composition for forming an underlayer film is within the above-described range, coating properties of the composition for forming an underlayer film are good, and an underlayer film which is thin and has litter variation in the film thickness can be formed.

Hereinafter, each material used in the composition for forming an underlayer film will be described.

### «Resin»

The composition for forming an underlayer film according to the embodiment of the present invention includes a resin A (hereinafter, referred to as a resin). The resin included in the composition for forming an underlayer film according to the embodiment of the present invention includes a resin a-1 (hereinafter, also referred to as a specific resin) having an alkyleneoxy structure.

### (Specific Resin)

The alkyleneoxy structure included in the specific resin is preferably a structure represented by Formula (AO-1).

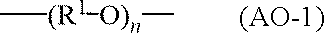

In the formula, R¹ represents an alkylene group and n represents a number of 2 or more.

The number of carbon atoms in the alkylene group represented by R¹ in Formula (AO-1) is preferably 1 to 20, more preferably 1 to 10, still more preferably 1 to 5, even more preferably 2 to 5, particularly preferably 2 or 3, and most preferably 2. The alkylene group represented by R¹ is preferably a linear or branched alkylene group, and more preferably a linear alkylene group. The alkylene group represented by R¹ is preferably an ethylene group, a propylene group, or an isopropylene group, and more preferably an ethylene group.

n in Formula (AO-1) represents an integer of 2 or more, and from the reason that the generation of residues can be suppressed more effectively, it is preferably an integer of 3 or more, more preferably an integer of 4 or more, and still more preferably an integer of 5 or more. From the viewpoint of solubility in a solvent, the upper limit is preferably 200 or less, and more preferably 100 or less.

A terminal structure of the alkyleneoxy structure included in the specific resin is not particularly limited. The terminal structure may be a hydrogen atom or a substituent. Examples of the substituent include an alkyl group, a polymerizable group, and an aryl group. Examples of the polymerizable group include an ethylenically unsaturated bond-containing group and a cyclic ether group. Examples of the ethylenically unsaturated bond-containing group include a vinyl group, a (meth)allyl group, and a (meth)acryloyl group. Examples of the cyclic ether group include an epoxy group and an oxetanyl group.

From the reason of production suitability of the resin and reduction of residues, the terminal structure of the alkyleneoxy structure is preferably an alkyl group.

The specific resin is preferably a resin having a group represented by Formula (AO-2).

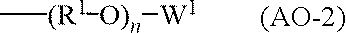

In the formula, R¹ represents an alkylene group, W¹ represents a hydrogen atom or a substituent, and n represents a number of 2 or more.

R¹ and n in Formula (AO-2) have the same meaning as R¹ and n in Formula (AO-1).

W¹ in Formula (AO-2) is preferably a substituent. Examples of the substituent include the above-described substituent.

The specific resin is preferably a resin including a polymerizable group. According to the aspect, the generation of residues can be suppressed more effectively. The polymerizable group may be included in the terminal structure of the alkyleneoxy structure, or may be included in other sites.

The specific resin is preferably a resin including a repeating unit which has a group including an alkyleneoxy structure.

Examples of the repeating unit which has a group including an alkyleneoxy structure include a repeating unit represented by Formula (a-1-1).

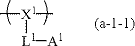

In Formula (a-1-1), X¹ represents a trivalent linking group, L¹ represents a single bond or a divalent linking group, and A¹ represents a group including an alkyleneoxy structure.

Examples of the trivalent linking group represented by X¹ in Formula (a-1-1) include a poly(meth)acrylic linking group, a polyalkyleneimine-based linking group, a polyester-based linking group, a polyurethane-based linking group, a polyuria-based linking group, a polyamide-based linking group, a polyether-based linking group, and a polystyrene-based linking group. Among these, a poly(meth)acrylic linking group, a polyalkyleneimine-based linking group, or a polyester-based linking group is preferable, and a poly(meth)acrylic linking group is more preferable.

Examples of the divalent linking group represented by L¹ in Formula (a-1-1) include an alkylene group (preferably an alkylene group having 1 to 12 carbon atoms), an arylene group (preferably an arylene group having 6 to 20 carbon atoms), —NH—, —SO—, —SO₂—, —CO—, —O—, —COO—, —OCO—, —S—, and a group formed by a combination of two or more these groups. The alkylene group is preferably a linear or branched alkylene group, and more preferably a linear alkylene group. The alkylene group and arylene group may have a substituent or may be unsubstituted. Examples of the substituent include a hydroxy group and an alkoxy group, and a hydroxy group is preferable from the viewpoint of production suitability.

Examples of the group including an alkyleneoxy structure, represented by A¹ in Formula (a-1-1), include the group represented by Formula (AO-2) described above.

A content of the repeating unit which has a group including an alkyleneoxy structure in all repeating units of the specific resin is preferably 30% to 100% by mass, more preferably 40% to 100% by mass, and still more preferably 60% to 100% by mass.

The specific resin is preferably a resin which includes the repeating unit including a group having an alkyleneoxy structure and a repeating unit having a polymerizable group. According to the aspect, the generation of residues can be suppressed more effectively.

Examples of the repeating unit having a polymerizable group include a repeating unit represented by Formula (a-1-2).

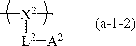

In Formula (a-1-2), X² represents a trivalent linking group, L² represents a single bond or a divalent linking group, and A² represents a polymerizable group.

Examples of the trivalent linking group represented by X² in Formula (a-1-2) include a poly(meth)acrylic linking group, a polyalkyleneimine-based linking group, a polyester-based linking group, a polyurethane-based linking group, a polyuria-based linking group, a polyamide-based linking group, a polyether-based linking group, and a polystyrene-based linking group. Among these, a poly(meth)acrylic linking group, a polyalkyleneimine-based linking group, or a polyester-based linking group is preferable, and a poly(meth)acrylic linking group is more preferable.

Examples of the divalent linking group represented by L² in Formula (a-1-2) include an alkylene group (preferably an alkylene group having 1 to 12 carbon atoms), an arylene group (preferably an arylene group having 6 to 20 carbon atoms), —NH—, —SO—, —SO₂—, —CO—, —O—, —COO—, —OCO—, —S—, and a group formed by a combination of two or more these groups. The alkylene group is preferably a linear or branched alkylene group, and more preferably a linear alkylene group. The alkylene group and arylene group may have a substituent or may be unsubstituted. Examples of the substituent include a hydroxy group and an alkoxy group, and a hydroxy group is preferable from the viewpoint of production suitability.

Examples of the polymerizable group represented by A² in Formula (a-1-2) include an ethylenically unsaturated bond-containing group and a cyclic ether group, and an ethylenically unsaturated bond-containing group is preferable. Examples of the ethylenically unsaturated bond-containing group include a vinyl group, a (meth)allyl group, and a (meth)acryloyl group. Examples of the cyclic ether group include an epoxy group and an oxetanyl group.

A content of the repeating unit having a polymerizable group in all repeating units of the specific resin is preferably 1% to 100% by mass, more preferably 5% to 60% by mass, and still more preferably 5% to 40% by mass.

In addition, the total content of the repeating unit including a group having an alkyleneoxy structure and the repeating unit having a polymerizable group in all repeating units of the specific resin is preferably 40% to 100% by mass, more preferably 80% to 100% by mass, and still more preferably 90% to 100% by mass.

In addition, a proportion of the repeating unit including a group having an alkyleneoxy structure and the repeating unit having a polymerizable group in the specific resin is that the repeating unit having a polymerizable group with respect to 100 parts by mass of the repeating unit including a group having an alkyleneoxy structure is preferably 1 to 200 parts by mass, more preferably 2 to 100 parts by mass, and still more preferably 5 to 50 parts by mass.

The specific resin can further include a repeating unit having an acid group. Examples of the acid group include a carboxyl group, a phosphoric acid group, a sulfo group, and a phenolic hydroxy group. A content of the repeating unit having an acid group in all repeating units of the specific resin is preferably 20% by mass or less, more preferably 10% by mass or less, and still more preferably 5% by mass or less. From the reason that the generation of development residues can be further suppressed, it is particularly preferable that the specific resin does not include the repeating unit having an acid group.

The specific resin can further include a repeating unit other than the above-described repeating units (also referred to as other repeating units). A content of the other repeating units in all repeating units of the specific resin is preferably 30% by mass or less, more preferably 20% by mass or less, and still more preferably 10% by mass or less.

A weight-average molecular weight of the specific resin is preferably 3,000 to 100,000. The upper limit is preferably 50,000 or less and more preferably 30,000 or less. The lower limit is preferably 5,000 or more and more preferably 7,000 or more.

An acid value of the specific resin is preferably 40 mgKOH/g or less, more preferably 20 mgKOH/g or less, still more preferably 5 mgKOH/g or less, even more preferably 1 mgKOH/g or less, and particularly preferably 0 mgKOH/g.

A polymerizable group value of the specific resin is preferably 5 mmol/g or less, more preferably 3.0 mmol/g or less, and still more preferably 1.5 mmol/g or less. The lower limit is preferably 0.05 mmol/g or more and more preferably 0.1 mmol/g or more. The polymerizable group value of the specific resin is a numerical value representing a molar amount of the polymerizable group per 1 g of the solid content of the specific resin. With regard to the polymerizable group value of the specific resin, a low-molecular-weight component (a) of a polymerizable group site is extracted from the specific resin by an alkali treatment, a content of the low-molecular-weight component is measured by high-performance liquid chromatography (HPLC), and the polymerizable group value of the specific resin can be calculated by the following expression. In a case where the polymerizable group site cannot be extracted from the specific resin by the alkali treatment, a value measured by a nuclear magnetic resonance (NMR) method is used.

Polymerizable group value of specific resin [mmol/g] = (Content of low-molecular-weight component (a) [ppm]/Molecular weight of low-molecular-weight component (a) [g/mol]/(Weighed value of specific resin [g]) × (Concentration of specific resin in sample [% by mass]/100) × 10)

The specific resin is preferably a resin which does not include a fluorine atom and a silicon atom. According to the aspect, the generation of residues can be suppressed more effectively.

In the specific resin, a content of halogen is preferably less than 1.0% by mass and more preferably less than 0.5% by mass with respect to the solid content of the resin, and it is particularly preferable that the specific resin does not substantially contain liberated halogen.

### (Other Resins)

The composition for forming an underlayer film according to the embodiment of the present invention can further contain a resin not including an alkyleneoxy structure (hereinafter, also referred to as other resins), in addition to the above-described specific resin. The other resins are not particularly limited, and examples thereof include a (meth)acrylic resin, an ene-thiol resin, a polycarbonate resin, a polyether resin, a polyarylate resin, a polysulfone resin, a polyethersulfone resin, a polyphenylene resin, a polyarylene ether phosphine oxide resin, a polyimide resin, a polyamideimide resin, a polyolefin resin, a cyclic olefin resin, a polyester resin, and a styrene resin.

A weight-average molecular weight of the other resins is preferably 3,000 to 100,000. The upper limit is preferably 50,000 or less and more preferably 30,000 or less. The lower limit is preferably 5,000 or more and more preferably 7,000 or more.

An acid value of the other resins is preferably 40 mgKOH/g or less, more preferably 20 mgKOH/g or less, still more preferably 5 mgKOH/g or less, even more preferably 1 mgKOH/g or less, and particularly preferably 0 mgKOH/g.

The other resins are also preferably a resin having a polymerizable group. Examples of the polymerizable group include an ethylenically unsaturated bond-containing group and a cyclic ether group, and an ethylenically unsaturated bond-containing group is preferable.

A content of the specific resin in the total solid content of the composition for forming an underlayer film is 50% by mass or more, preferably 70% by mass or more and more preferably 90% by mass or more. The upper limit may be 100% by mass or less. In addition, the content of the specific resin is preferably 0.005% to 1% by mass with respect to the total mass of the composition for forming an underlayer film. The lower limit is preferably 0.025% by mass or more and more preferably 0.05% by mass or more. The upper limit is preferably 0.7% by mass or less and more preferably 0.5% by mass or less.

In addition, the content of the specific resin in the resin is preferably 50% to 100% by mass, more preferably 70% to 100% by mass, still more preferably 90% to 100% by mass, and particularly preferably 95% by mass or more.

In addition, a content of the resin in the total solid content of the composition for forming an underlayer film is preferably 50% by mass or more, more preferably 70% by mass or more, and still more preferably 90% by mass or more. The upper limit may be 100% by mass or less. In addition, the content of the resin is preferably 0.005% to 1% by mass with respect to the total mass of the composition for forming an underlayer film. The lower limit is preferably 0.025% by mass or more and more preferably 0.05% by mass or more. The upper limit is preferably 0.7% by mass or less and more preferably 0.5% by mass or less.

The resin may be used singly or in combination of two or more kinds thereof. In a case where two or more kinds thereof are used in combination, the total amount thereof is within the above-described range.

### «Solvent»

The composition for forming an underlayer film according to the embodiment of the present invention includes a solvent B (hereinafter, referred to as a solvent). The solvent is preferably an organic solvent. The solvent is not particularly limited as long as it satisfies solubility of each component and coating properties of the composition for forming an underlayer film. Examples of the organic solvent include an ester-based solvent, a ketone-based solvent, an alcohol-based solvent, an amide-based solvent, an ether-based solvent, and a hydrocarbon-based solvent. The details of the organic solvent can be found in paragraph No. 0223 of WO2015/166779A, the content of which is incorporated herein by reference. In addition, an ester-based solvent in which a cyclic alkyl group is substituted or a ketone-based solvent in which a cyclic alkyl group is substituted can also be preferably used.

A boiling point of the organic solvent is preferably 100° C. to 200° C., more preferably 105° C. to 190° C., and still more preferably 110° C. to 180° C.

Specific examples of the organic solvent include polyethylene glycol monomethyl ether, dichloromethane, methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, 3-pentanone, 4-heptanone, cyclohexanone, 2-methylcyclohexanone, 3-methylcyclohexanone, 4-methylcyclohexanone, cycloheptanone, cyclooctanone, cyclohexyl acetate, cyclopentanone, ethylcarbitol acetate, butylcarbitol acetate, propylene glycol monomethyl ether, propylene glycol monomethyl ether acetate, 3-methoxy-N,N-dimethylpropanamide, 3-butoxy-N,N-dimethylpropanamide, γ-butyrolactone, N-methyl-2-pyrrolidone, propylene glycol diacetate, sulfolane, anisole, 1,4-diacetoxybutane, diethylene glycol monoethyl ether acetate, butane diacetate-1,3-diyl, dipropylene glycol methyl ether acetate, and diacetone alcohol. In this case, it may be preferable that the content of aromatic hydrocarbons (such as benzene, toluene, xylene, and ethylbenzene) as the organic solvent is low (for example, 50 parts per million (ppm) by mass or less, 10 ppm by mass or less, or 1 ppm by mass or less with respect to the total amount of the organic solvent) in consideration of environmental aspects and the like.

In the present invention, an organic solvent having a low metal content is preferably used. For example, the metal content in the organic solvent is preferably 10 mass parts per billion (ppb) or less. Optionally, an organic solvent having a metal content at a mass parts per trillion (ppt) level may be used. For example, such an organic solvent is available from Toyo Gosei Co., Ltd. (The Chemical Daily, Nov. 13, 2015).

Examples of a method for removing impurities such as a metal from the organic solvent include distillation (such as molecular distillation and thin-film distillation) and filtration using a filter. The filter pore size of the filter used for the filtration is preferably 10 µm or less, more preferably 5 µm or less, and still more preferably 3 µm or less. As a material of the filter, polytetrafluoroethylene, polyethylene, or nylon is preferable.

The organic solvent may include an isomer (a compound having the same number of atoms and a different structure). In addition, only one kind of isomers may be included, or a plurality of isomers may be included.

The organic solvent preferably has the content of peroxides of 0.8 mmol/L or less, and more preferably, the organic solvent does not substantially include peroxides.

A content of the solvent is an amount such that the concentration of solid contents of the composition for forming an underlayer film is 1% by mass or less. That is, the content of the solvent is 99% by mass or more with respect to the total mass of the composition for forming an underlayer film. The content of the solvent is preferably 99% to 99.99% by mass with respect to the total mass of the composition for forming an underlayer film. The lower limit is preferably 99.3% by mass or more and more preferably 99.5% by mass or more. The upper limit is preferably 99.95% by mass or less and more preferably 99.9% by mass or less. In a case where the content of the solvent is within the above-described range, coating properties of the composition for forming an underlayer film are good, and an underlayer film which is thin and has litter variation in the film thickness can be formed.

### «Surfactant»

The composition for forming an underlayer film can contain a surfactant. As the surfactant, various surfactants such as a fluorine-based surfactant, a nonionic surfactant, a cationic surfactant, an anionic surfactant, and a silicone-based surfactant can be used. Examples of the surfactant include surfactants described in paragraph Nos. 0238 to 0245 of WO2015/166779A, the contents of which are incorporated herein by reference.

The surfactant is preferably a fluorine-based surfactant or a silicone-based surfactant.

Examples of the fluorine-based surfactant include surfactants described in paragraph Nos. 0060 to 0064 of JP2014-041318A (paragraph Nos. 0060 to 0064 of the corresponding WO2014/017669A) and the like, surfactants described in paragraph Nos. 0117 to 0132 of JP2011-132503A, and surfactants described in JP2020-008634A, the contents of which are incorporated herein by reference. Examples of a commercially available product of the fluorine-based surfactant include: MEGAFACE F-171, F-172, F-173, F-176, F-177, F-141, F-142, F-143, F-144, F-437, F-475, F-477, F-479, F-482, F-554, F-555-A, F-556, F-557, F-558, F-559, F-560, F-561, F-563, F-565, F-568, F-575, F-780, EXP, MFS-330, R-01, R-40, R-40-LM, R-41, R-41-LM, RS-43, TF-1956, RS-90, R-94, RS-72-K, and DS-21 (all of which are manufactured by DIC Corporation); FLUORAD FC430, FC431, and FC171 (all of which are manufactured by Sumitomo 3M Ltd.); SURFLON S-382, SC-101, SC-103, SC-104, SC-105, SC-1068, SC-381, SC-383, S-393, and KH-40 (all of which are manufactured by Asahi Glass Co., Ltd.); POLYFOX PF636, PF656, PF6320, PF6520, and PF7002 (all of which are manufactured by OMNOVA Solutions Inc.); and FTERGENT 208G, 215M, 245F, 601AD, 601ADH2, 602A, 610FM, 710FL, 710FM, 710FS, and FTX-218 (all of which are manufactured by NEOS COMPANY LIMITED).

In addition, as the fluorine-based surfactant, an acrylic compound, which has a molecular structure having a functional group containing a fluorine atom and in which, by applying heat to the molecular structure, the functional group containing a fluorine atom is broken to volatilize a fluorine atom, can also be suitably used. Examples of such a fluorine-based surfactant include MEGAFACE DS series manufactured by DIC Corporation (The Chemical Daily, Feb. 22, 2016; Nikkei Business Daily, Feb. 23, 2016) such as MEGAFACE DS-21.

In addition, it is also preferable that a polymer of a fluorine atom-containing vinyl ether compound having a fluorinated alkyl group or a fluorinated alkylene ether group, and a hydrophilic vinyl ether compound is used as the fluorine-based surfactant. Examples of such a fluorine-based surfactant include fluorine-based surfactants described in JP2016-216602A, the contents of which are incorporated herein by reference.

A block polymer can also be used as the fluorine-based surfactant. As the fluorine-based surfactant, a fluorine-containing polymer compound including a repeating unit derived from a (meth)acrylate compound having a fluorine atom and a repeating unit derived from a (meth)acrylate compound having 2 or more (preferably 5 or more) alkyleneoxy groups (preferably ethyleneoxy groups or propyleneoxy groups) can also be preferably used. In addition, fluorine-containing surfactants described in paragraph Nos. 0016 to 0037 of JP2010-032698A, or the following compounds are also exemplified as the fluorine-based surfactant used in the present invention.

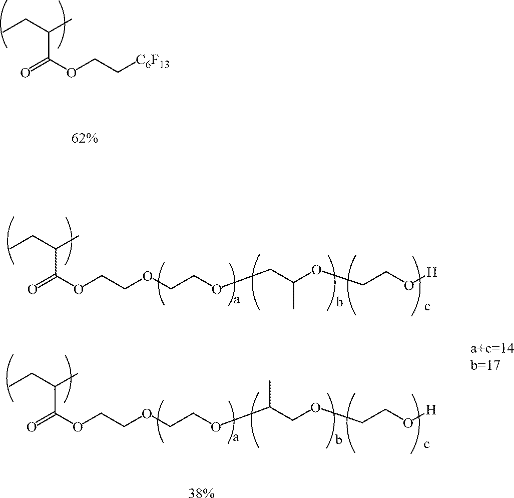

A weight-average molecular weight of the compound is preferably 3000 to 50000 and, for example, 14000. In the compound, “%” representing the proportion of a repeating unit is mol%.

In addition, as the fluorine-based surfactant, a fluorine-containing polymer having an ethylenically unsaturated bond-containing group in the side chain can be used. Specific examples thereof include compounds described in paragraph Nos. 0050 to 0090 and paragraph Nos. 0289 to 0295 of JP2010-164965A, and MEGAFACE RS-101, RS-102, RS-718K, and RS-72-K manufactured by DIC Corporation. In addition, as the fluorine-based surfactant, compounds described in paragraph Nos. 0015 to 0158 of JP2015-117327A can also be used.

In addition, from the viewpoint of environmental regulation, it is also preferable to use a surfactant described in WO2020/084854A as a substitute for the surfactant having a perfluoroalkyl group having 6 or more carbon atoms.

In addition, it is also preferable to use a fluorine-containing imide salt compound represented by Formula (fi-1) as the surfactant.

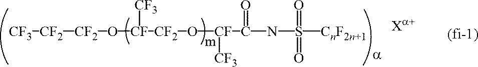

In Formula (fi-1), m represents 1 or 2, n represents an integer of 1 to 4, α represents 1 or 2, and X^{α+} represents an α-valent metal ion, a primary ammonium ion, a secondary ammonium ion, a tertiary ammonium ion, a quaternary ammonium ion, or NH₄⁺.

Examples of the silicone-based surfactant include TORAY SILICONE DC3PA, TORAY SILICONE SH7PA, TORAY SILICONE DC11PA, TORAY SILICONE SH21PA, TORAY SILICONE SH28PA, TORAY SILICONE SH29PA, TORAY SILICONE SH30PA, TORAY SILICONE SH8400, and FZ-2122 (all of which are manufactured by Dow Corning Toray Co., Ltd.); TSF-4440, TSF-4300, TSF-4445, TSF-4460, and TSF-4452 (all of which are manufactured by Momentive Performance Materials Co., Ltd.); KP-341, KF-6001, and KF-6002 (all of which are manufactured by Shin-Etsu Chemical Co., Ltd.); and BYK-307, BYK-322, BYK-323, BYK-330, BYK-3760, and BYK-UV3510 (all of which are manufactured by BYK Chemie).

Examples of the nonionic surfactant include glycerol, trimethylolpropane, trimethylolethane, an ethoxylate and propoxylate thereof (for example, glycerol propoxylate or glycerol ethoxylate), polyoxyethylene lauryl ether, polyoxyethylene stearyl ether, polyoxyethylene oleyl ether, polyoxyethylene octylphenyl ether, polyoxyethylene nonylphenyl ether, polyethylene glycol dilaurate, polyethylene glycol distearate, sorbitan fatty acid esters, PLURONIC L10, L31, L61, L62, 10R5, 17R2, and 25R2 (manufactured by BASF SE), TETRONIC 304, 701, 704, 901, 904, and 150R1 (manufactured by BASF SE), SOLSPERSE 20000 (manufactured by Lubrizol Japan Ltd.), NCW-101, NCW-1001, and NCW-1002 (all of which are manufactured by FUJIFILM Wako Pure Chemical Corporation), PIONIN D-6112, D-6112-W, and D-6315 (all of which are manufactured by Takemoto Oil&Fat Co., Ltd.), and OLFINE E1010 and SURFYNOL 104, 400, and 440 (all of which are manufactured by Nissin Chemical Co., Ltd.).

In a case where the composition for forming an underlayer film contains a surfactant, a content of the surfactant in the total solid content of the composition for forming an underlayer film is preferably 0.01% to 2.0% by mass. The lower limit is preferably 0.03% by mass or more and more preferably 0.05% by mass or more. The upper limit is preferably 1.5% by mass or less and more preferably 1.0% by mass or less.

In addition, the content of the surfactant is preferably 0.0001% to 0.1% by mass with respect to the total mass of the composition for forming an underlayer film. The lower limit is preferably 0.0005% by mass or more and more preferably 0.001% by mass or more. The upper limit is preferably 0.05% by mass or less and more preferably 0.01% by mass or less.

The surfactant may be used singly or in combination of two or more kinds thereof. In a case where two or more kinds thereof are used in combination, the total amount thereof is within the above-described range.

### «Polymerizable Compound»

The composition for forming an underlayer film can further contain a polymerizable compound in addition to the above-described resin. Examples of the polymerizable compound include a compound having an ethylenically unsaturated bond-containing group and a compound having a cyclic ether group, and a compound having an ethylenically unsaturated bond-containing group is preferable. Examples of the ethylenically unsaturated bond-containing group include a vinyl group, a (meth)allyl group, and a (meth)acryloyl group. Examples of the cyclic ether group include an epoxy group and an oxetanyl group. The compound having an ethylenically unsaturated bond-containing group can be preferably used as a radically polymerizable compound.

A molecular weight of the monomer-type polymerizable compound (polymerizable monomer) is preferably less than 2.000 and more preferably 1.500 or less. The lower limit of the molecular weight of the polymerizable monomer is preferably 100 or more and more preferably 200 or more. A weight-average molecular weight (Mw) of the resin-type polymerizable compound is preferably 2.000 to 2,000,000. The upper limit of the weight-average molecular weight is preferably 1.000.000 or less and more preferably 500.000 or less. The lower limit of the weight-average molecular weight is preferably 3.000 or more and more preferably 5.000 or more.

The compound having an ethylenically unsaturated bond-containing group as the polymerizable monomer is preferably a trifunctional to pentadecafunctional (meth)acrylate compound and more preferably a trifunctional to hexafunctional (meth)acrylate compound. Specific examples thereof include the compounds described in paragraph Nos. 0095 to 0108 of JP2009-288705A, paragraph Nos.0227 of JP2013-029760A, paragraph Nos. 0254 to 0257 of JP2008-292970A, paragraph Nos. 0034 to 0038 of JP2013-253224A, paragraph No. 0477 of JP2012-208494A, JP2017-048367A, JP6057891B, JP6031807B, and JP2017-194662A, the contents of which are incorporated herein by reference.

Examples of the compound having an ethylenically unsaturated bond-containing group include dipentaerythritol triacrylate (as a commercially available product, KAYARAD D-330 manufactured by Nippon Kayaku Co., Ltd.), dipentaerythritol tetraacrylate (as a commercially available product, KAYARAD D-320 manufactured by Nippon Kayaku Co., Ltd.), dipentaerythritol penta(meth)acrylate (as a commercially available product, KAYARAD D-310 manufactured by Nippon Kayaku Co., Ltd.), dipentaerythritol hexa(meth)acrylate (as a commercially available product, KAYARAD DPHA manufactured by Nippon Kayaku Co., Ltd., NK ESTER A-DPH-12E manufactured by Shin-Nakamura Chemical Co., Ltd.), and a compound having a structure in which these (meth)acryloyl groups are bonded through an ethylene glycol and/or a propylene glycol residue (for example, SR454 and SR499 which are commercially available products from Sartomer Company Inc.). In addition, as the compound having an ethylenically unsaturated bond-containing group, diglycerin ethylene oxide (EO)-modified (meth)acrylate (as a commercially available product, M-460 manufactured by TOAGOSEI CO., LTD.), pentaerythritol tetraacrylate (NK ESTER A-TMMT manufactured by Shin-Nakamura Chemical Co., Ltd.), 1,6-hexanediol diacrylate (KAYARAD HDDA manufactured by Nippon Kayaku Co., Ltd.), RP-1040 (manufactured by Nippon Kayaku Co., Ltd.), ARONIX TO-2349 (manufactured by TOAGOSEI CO., LTD.), NK OLIGO UA-7200 (manufactured by Shin-Nakamura Chemical Co., Ltd.), 8UH-1006 and 8UH-1012 (manufactured by Taisei Fine Chemical Co., Ltd.), Light Acrylate POB-A0 (manufactured by KYOEISHA CHEMICAL Co., Ltd.), and the like can also be used.

In addition, as the compound having an ethylenically unsaturated bond-containing group, it is also preferable to use a trifunctional (meth)acrylate compound such as trimethylolpropane tri(meth)acrylate, trimethylolpropane propyleneoxide-modified tri(meth)acrylate, trimethylolpropane ethyleneoxide-modified tri(meth)acrylate, isocyanuric acid ethyleneoxide-modified tri(meth)acrylate, and pentaerythritol tri(meth)acrylate. Examples of a commercially available product of the trifunctional (meth)acrylate compound include ARONIX M-309, M-310, M-321, M-350, M-360, M-313, M-315, M-306, M-305, M-303, M-452, and M-450 (manufactured by TOAGOSEI CO., LTD.), NK ESTER A9300, A-GLY-9E, A-GLY-20E, A-TMM-3, A-TMM-3L, A -TMM-3LM-N, A-TMPT, and TMPT (manufactured by Shin-Nakamura Chemical Co., Ltd.), and KAYARAD GPO-303, TMPTA, THE-330, TPA-330, and PET-30 (manufactured by Nippon Kayaku Co., Ltd.).

The compound having an ethylenically unsaturated bond-containing group may further have an acid group such as a carboxyl group, a sulfo group, and a phosphoric acid group. Examples of a commercially available product of such a compound include ARONIX M-305, M-510, M-520, and ARONIX TO-2349 (manufactured by TOAGOSEI CO., LTD.).

As the compound having an ethylenically unsaturated bond-containing group, a compound having a caprolactone structure can also be used. With regard to the compound having a caprolactone structure, reference can be made to the description in paragraph Nos.0042 to 0045 of JP2013-253224A, the content of which is incorporated herein by reference. Examples of the compound having a caprolactone structure include DPCA-20, DPCA-30, DPCA-60, and DPCA-120, each of which is commercially available as KAYARAD DPCA series from Nippon Kayaku Co., Ltd.

As the compound having an ethylenically unsaturated bond-containing group, a compound having an ethylenically unsaturated bond-containing group and an alkyleneoxy group can also be used. Such a compound is preferably a compound having an ethylenically unsaturated bond-containing group and an ethyleneoxy group and/or a propyleneoxy group, more preferably a compound having an ethylenically unsaturated bond-containing group and an ethyleneoxy group, and still more preferably a 3- to 6-functional (meth)acrylate compound having 4 to 20 ethyleneoxy groups. Examples of a commercially available product thereof include SR-494 manufactured by Sartomer, which is a tetrafunctional (meth)acrylate having four ethyleneoxy groups, and KAYARAD TPA-330, which is a trifunctional (meth)acrylate having three isobutyleneoxy groups.

As the compound having an ethylenically unsaturated bond-containing group, a polymerizable compound having a fluorene skeleton can also be used. Examples of a commercially available product thereof include OGSOL EA-0200 and EA-0300 (manufactured by Osaka Gas Chemicals Co., Ltd., (meth)acrylate monomer having a fluorene skeleton).

As the compound having an ethylenically unsaturated bond-containing group, it is also preferable to use a compound which does not substantially include environmentally regulated substances such as toluene. Examples of a commercially available product of such a compound include KAYARAD DPHA LT and KAYARAD DPEA-12 LT (manufactured by Nippon Kayaku Co., Ltd.).

As the compound having an ethylenically unsaturated bond-containing group, it is also preferable to use UA-7200 (manufactured by Shin-Nakamura Chemical Co., Ltd.), DPHA-40H (manufactured by Nippon Kayaku Co., Ltd.), UA-306H, UA-306T, UA-306I, AH-600, T-600, AI-600, and LINC-202UA (manufactured by KYOEISHA CHEMICAL Co., Ltd.), 8UH-1006 and 8UH-1012 (all of which are manufactured by Taisei Fine Chemical Co., Ltd.), Light Acrylate POB-A0 (manufactured by KYOEISHA CHEMICAL Co., Ltd.), and the like.

Examples of the compound having a cyclic ether group include a compound having an epoxy group and a compound having an oxetanyl group, and a compound having an epoxy group is preferable. Examples of the compound having an epoxy group include a compound having 1 to 100 epoxy groups in one molecule. The upper limit of the number of epoxy groups may be, for example, 10 or less or 5 or less. The lower limit of the number of epoxy groups is preferably 2 or more. As the epoxy compound having an epoxy group, compounds described in paragraph Nos. 0034 to 0036 of JP2013-011869A, paragraph Nos. 0147 to 0156 of JP2014-043556A, and paragraph Nos. 0085 to 0092 of JP2014-089408A, and compounds described in JP2017-179172A can also be used, the contents of which are incorporated herein by reference.

The compound having an epoxy group may be a low-molecular-weight compound (for example, a molecular weight of less than 1,000) or a high-molecular-weight compound (macromolecule) (for example, a molecular weight of 1,000 or more, and in a case of a polymer, a weight-average molecular weight of 1,000 or more). A weight-average molecular weight of the compound having an epoxy group is preferably 200 to 100,000 and more preferably 500 to 50,000. The upper limit of the weight-average molecular weight is preferably 10,000 or less, more preferably 5,000 or less, and still more preferably 3,000 or less.

Examples of a commercially available product of the compound having a cyclic ether group include EHPE 3150 (manufactured by Daicel Corporation), JER-1031S (manufactured by Mitsubishi Chemical Corporation), EPICLON N-695 (manufactured by DIC Corporation), and MARPROOF G-0150M, G-0105SA, G-0130SP, G-0250SP, G-1005S, G-1005SA, G-1010S, G-2050M, G-01100, and G-01758 (all of which are manufactured by NOF Corporation., an epoxy group-containing polymer).

In a case where the composition for forming an underlayer film contains a polymerizable compound, a content of the polymerizable compound in the total solid content of the composition for forming an underlayer film is preferably 1% to 45% by mass. The lower limit is preferably 3% by mass or more and more preferably 5% by mass or more. The upper limit is preferably 35% by mass or less and more preferably 25% by mass or less.

In addition, the content of the polymerizable compound is preferably 0.003% to 0.5% by mass with respect to the total mass of the composition for forming an underlayer film. The lower limit is preferably 0.01% by mass or more and more preferably 0.03% by mass or more. The upper limit is preferably 0.4% by mass or less and more preferably 0.3% by mass or less.

In addition, the total content of the resin and the polymerizable compound in the total solid content of the composition for forming an underlayer film is preferably 70% to 100% by mass. The lower limit is preferably 80% by mass or more and more preferably 90% by mass or more. The upper limit may be 100% by mass or less or 95% by mass or less.

In addition, the content of the resin and the polymerizable compound is preferably 0.007% to 1% by mass with respect to the total mass of the composition for forming an underlayer film. The lower limit is preferably 0.035% by mass or more and more preferably 0.07% by mass or more. The upper limit is preferably 0.7% by mass or less and more preferably 0.5% by mass or less.

The polymerizable compound may be used singly or in combination of two or more kinds thereof. In a case where two or more kinds thereof are used in combination, the total amount thereof is within the above-described range.

### «Photopolymerization Initiator»

The composition for forming an underlayer film can contain a photopolymerization initiator. The photopolymerization initiator is not particularly limited, and can be appropriately selected from known photopolymerization initiators. For example, a compound having photosensitivity to light in a range from an ultraviolet range to a visible range is preferable. The photopolymerization initiator is preferably a photoradical polymerization initiator.

Examples of the photopolymerization initiator include a halogenated hydrocarbon derivative (for example, a compound having a triazine skeleton or a compound having an oxadiazole skeleton), an acylphosphine compound, a hexaarylbiimidazole, an oxime compound, an organic peroxide, a thio compound, a ketone compound, an aromatic onium salt, an α-hydroxyketone compound, and an α-aminoketone compound. From the viewpoint of exposure sensitivity, as the photopolymerization initiator, a trihalomethyltriazine compound, a benzyldimethylketal compound, an α-hydroxyketone compound, an α-aminoketone compound, an acylphosphine compound, a phosphine oxide compound, a metallocene compound, an oxime compound, a triarylimidazole dimer, an onium compound, a benzothiazole compound, a benzophenone compound, an acetophenone compound, a cyclopentadiene-benzene-iron complex, a halomethyl oxadiazole compound, or a 3-aryl-substituted coumarin compound is preferable, a compound selected from an oxime compound, an α-hydroxyketone compound, an α-aminoketone compound, or an acylphosphine compound is more preferable, and an oxime compound is still more preferable. In addition, as the photopolymerization initiator, compounds described in paragraph Nos.0065 to 0111 of JP2014-130173A, compounds described in JP6301489B, peroxide-based photopolymerization initiators described in MATERIAL STAGE, p. 37 to 60, vol. 19, No. 3, 2019, photopolymerization initiators described in WO2018/221177A, photopolymerization initiators described in WO2018/110179A, photopolymerization initiators described in JP2019-043864A, photopolymerization initiators described in JP2019-044030A, peroxide initiators described in JP2019-167313A, aminoacetophenone-based initiators described in JP2020-055992A, and oxime-based photopolymerization initiators described in JP2013-190459A, the contents of which are incorporated herein by reference.

Examples of a commercially available product of the α-hydroxyketone compound include Omnirad 184, Omnirad 1173, Omnirad 2959, and Omnirad 127 (all of which are manufactured by IGM Resins B.V), Irgacure 184, Irgacure 1173, Irgacure 2959, and Irgacure 127 (all of which are manufactured by BASF SE). Examples of a commercially available product of the α-aminoketone compound include Omnirad 907, Omnirad 369, Omnirad 369E, and Omnirad 379EG (all of which are manufactured by IGM Resins B.V), Irgacure 907, Irgacure 369, Irgacure 369E, and Irgacure 379EG (all of which are manufactured by BASF SE). Examples of a commercially available product of the acylphosphine compound include Omnirad 819 and Omnirad TPO (both of which are manufactured by IGM Resins B.V), Irgacure 819 and Irgacure TPO (both of which are manufactured by BASF SE).

Examples of the oxime compound include the compounds described in JP2001-233842A, the compounds described in JP2000-080068A, the compounds described in JP2006-342166A, the compounds described in J. C. S. Perkin II (1979, pp. 1653 to 1660), the compounds described in J. C. S. Perkin II (1979, pp. 156 to 162), the compounds described in Journal of Photopolymer Science and Technology (1995, pp. 202 to 232), the compounds described in JP2000-066385A, the compounds described in JP2004-534797A, the compounds described in JP2006-342166A, the compounds described in JP2017-019766A, the compounds described in JP6065596B, the compounds described in WO2015/152153A, the compounds described in WO2017/051680A, the compounds described in JP2017-198865A, the compounds described in paragraph Nos. 0025 to 0038 of WO2017/164127A, and compounds described in WO2013/167515A. Specific examples of the oxime compound include 3-benzoyloxyiminobutane-2-one, 3-acetoxyiminobutane-2-one, 3-propionyloxyiminobutane-2-one, 2-acetoxyiminopentane-3-one, 2-acetoxyimino-1-phenylpropane-1-one, 2-benzoyloxyimino-1-phenylpropane-1-one, 3-(4-toluene sulfonyloxy)iminobutane-2-one, and 2-ethoxycarbonyloxyimino-1-phenylpropane-1-one. Examples of a commercially available product thereof include Irgacure OXE01, Irgacure OXE02, Irgacure OXE03, and Irgacure OXE04 (all of which are manufactured by BASF SE), TR-PBG-304 (manufactured by TRONLY), and ADEKA OPTOMER N-1919 (manufactured by ADEKA Corporation; photopolymerization initiator 2 described in JP2012-014052A). In addition, as the oxime compound, it is also preferable to use a compound having no colorability or a compound having high transparency and being resistant to discoloration. Examples of a commercially available product include ADEKA ARKLS NCI-730, NCI-831, and NCI-930 (all of which are manufactured by ADEKA Corporation).

An oxime compound having a fluorene ring can also be used as the photopolymerization initiator. Specific examples of the oxime compound having a fluorene ring include compounds described in JP2014-137466A, compounds described in JP6636081A, and compounds described in KR10-2016-0109444A.

As the photopolymerization initiator, an oxime compound having a skeleton in which at least one benzene ring of a carbazole ring is a naphthalene ring can also be used. Specific examples of such an oxime compound include the compounds described in WO2013/083505A.

An oxime compound having a fluorine atom can also be used as the photopolymerization initiator. Specific examples of the oxime compound having a fluorine atom include the compounds described in JP2010-262028A, the compounds 24, and 36 to 40 described in JP2014-500852A, and the compound (C-3) described in JP2013-164471A.

An oxime compound having a nitro group can be used as the photopolymerization initiator. The oxime compound having a nitro group is also preferably used in the form of a dimer. Specific examples of the oxime compound having a nitro group include the compounds described in paragraph Nos. 0031 to 0047 of JP2013-114249A and paragraph Nos. 0008 to 0012 and 0070 to 0079 of JP2014-137466A, the compounds described in paragraph Nos. 0007 to 0025 of JP4223071B, and ADEKA ARKLS NCI-831 (manufactured by ADEKA Corporation).

An oxime compound having a benzofuran skeleton can also be used as the photopolymerization initiator. Specific examples thereof include OE-01 to OE-75 described in WO2015/036910A.

In the present invention, as the photopolymerization initiator, an oxime compound in which a substituent having a hydroxy group is bonded to a carbazole skeleton can also be used. Examples of such a photopolymerization initiator include compounds described in WO2019/088055A.

As the photopolymerization initiator, an oxime compound having an aromatic ring group Ar^{OX1} in which an electron withdrawing group is introduced into an aromatic ring (hereinafter, also referred to as an oxime compound OX) is used can also be used. Examples of the electron withdrawing group included in the above-described aromatic ring group Ar^{OX1} include an acyl group, a nitro group, a trifluoromethyl group, an alkylsulfinyl group, an arylsulfinyl group, an alkylsulfonyl group, an arylsulfonyl group, and a cyano group. Among these, an acyl group or a nitro group is preferable, an acyl group is more preferable, and a benzoyl group is still more preferable. The benzoyl group may have a substituent. As the substituent, a halogen atom, a cyano group, a nitro group, a hydroxy group, an alkyl group, an alkoxy group, an aryl group, an aryloxy group, a heterocyclic group, a heterocyclic oxy group, an alkenyl group, an alkylsulfanyl group, an arylsulfanyl group, an acyl group, or an amino group is preferable, an alkyl group, an alkoxy group, an aryl group, an aryloxy group, a heterocyclic oxy group, an alkylsulfanyl group, an arylsulfanyl group, or an amino group is more preferable, and an alkoxy group, an alkylsulfanyl group, or an amino group is still more preferable. Specific examples of the oxime compound OX include compounds described in paragraph Nos. 0083 to 0105 of JP4600600B.

Specific examples of the oxime compound which are preferably used in the present invention are shown below, but the present invention is not limited thereto.

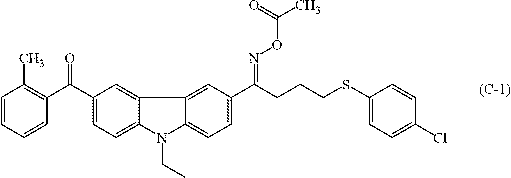 [SMILES: CCn1c2ccc(C(=O)c3ccccc3C)cc2c2cc(/C(CCCSc3ccc(Cl)cc3)=N/OC(C)=O)ccc21]

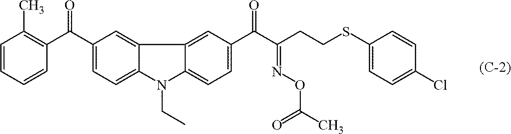 [SMILES: CCn1c2ccc(C(=O)/C(CCSc3ccc(Cl)cc3)=N/OC(C)=O)cc2c2cc(C(=O)c3ccccc3C)ccc21]

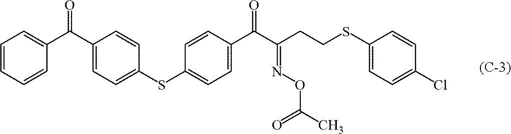 [SMILES: CC(=O)O/N=C(\CCSc1ccc(Cl)cc1)C(=O)c1ccc(Sc2ccc(C(=O)c3ccccc3)cc2)cc1]

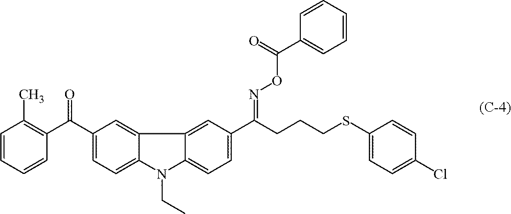 [SMILES: CCn1c2ccc(C(=O)c3ccccc3C)cc2c2cc(/C(CCCSc3ccc(Cl)cc3)=N/OC(=O)c3ccccc3)ccc21]

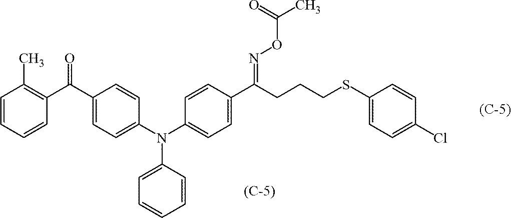 [SMILES: CC(=O)O/N=C(\CCCSc1ccc(Cl)cc1)c1ccc(N(c2ccccc2)c2ccc(C(=O)c3ccccc3C)cc2)cc1 ; "(C-5)"]

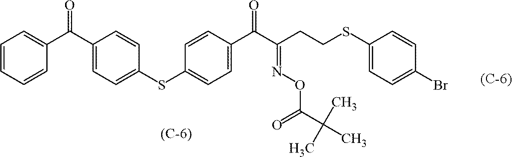 [SMILES: CC(C)(C)C(=O)O/N=C(\CCSc1ccc(Br)cc1)C(=O)c1ccc(Sc2ccc(C(=O)c3ccccc3)cc2)cc1 ; "(C-6)"]

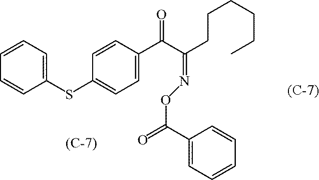 [SMILES: CCCCCC/C(=N/OC(=O)c1ccccc1)C(=O)c1ccc(Sc2ccccc2)cc1 ; "(C-7)"]

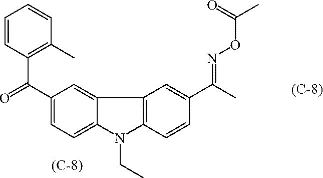

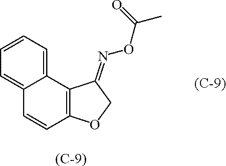

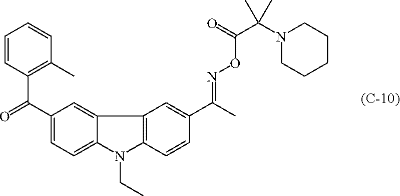 [SMILES: CCn1c2ccc(C(=O)c3ccccc3C)cc2c2cc(/C(C)=N/OC(=O)C(C)(C)N3CCCCC3)ccc21]

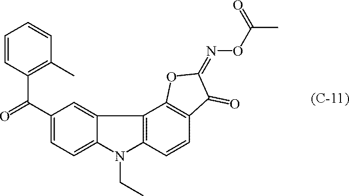 [SMILES: CCn1c2ccc(C(=O)c3ccccc3C)cc2c2c3c(ccc21)C(=O)/C(=N\OC(C)=O)O3]

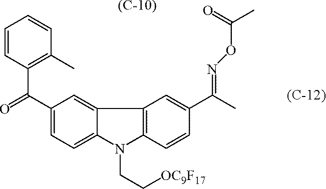

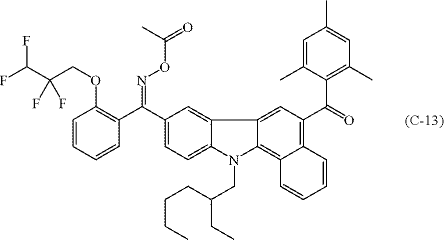 [SMILES: CCCCC(CC)Cn1c2ccc(/C(=N\OC(C)=O)c3ccccc3OCC(F)(F)C(F)F)cc2c2cc(C(=O)c3c(C)cc(C)cc3C)c3ccccc3c21]

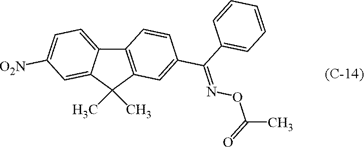 [SMILES: CC(=O)O/N=C(\c1ccccc1)c1ccc2c(c1)C(C)(C)c1cc([N+](=O)[O-])ccc1-2]

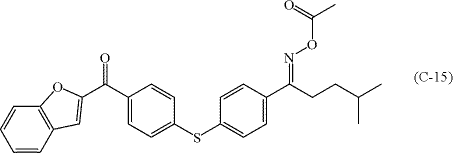 [SMILES: CC(=O)O/N=C(\CCC(C)C)c1ccc(Sc2ccc(C(=O)c3cc4ccccc4o3)cc2)cc1]

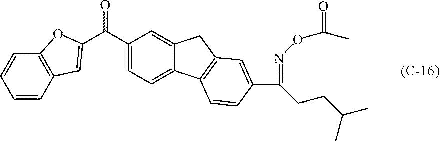 [SMILES: CC(=O)O/N=C(\CCC(C)C)c1ccc2c(c1)Cc1cc(C(=O)c3cc4ccccc4o3)ccc1-2]

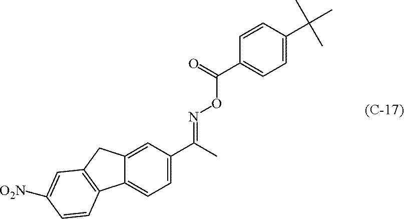 [SMILES: C/C(=N\OC(=O)c1ccc(C(C)(C)C)cc1)c1ccc2c(c1)Cc1cc([N+](=O)[O-])ccc1-2]

The oxime compound is preferably a compound having a maximal absorption wavelength in a wavelength range of 350 to 500 nm and more preferably a compound having a maximal absorption wavelength in a wavelength range of 360 to 480 nm. In addition, from the viewpoint of sensitivity, a molar absorption coefficient of the oxime compound at a wavelength of 365 nm or 405 nm is preferably high, more preferably 1000 to 300000, still more preferably 2000 to 300000, and particularly preferably 5000 to 200000. The molar absorption coefficient of a compound can be measured using a known method. For example, the molar absorption coefficient is preferably measured by a spectrophotometer (Cary-5 spectrophotometer, manufactured by Varian Medical Systems, Inc.) using an ethyl acetate solvent at a concentration of 0.01 g/L.

As the photopolymerization initiator, a bifunctional or tri- or higher functional photoradical polymerization initiator may be used. By using such a photoradical polymerization initiator, two or more radicals are generated from one molecule of the photoradical polymerization initiator, and as a result, good sensitivity is obtained. In addition, in a case of using a compound having an asymmetric structure, crystallinity is reduced so that solubility in a solvent or the like is improved, precipitation is to be difficult over time, and temporal stability of the photosensitive composition can be improved. Specific examples of the bifunctional or tri- or higher functional photoradical polymerization initiator include dimers of the oxime compounds described in JP2010-527339A, JP2011-524436A, WO2015/004565A, paragraph Nos. 0407 to 0412 of JP2016-532675A, and paragraph Nos. 0039 to 0055 of WO2017/033680A; the compound (E) and compound (G) described in JP2013-522445A; Cmpd 1 to 7 described in WO2016/034963A; the oxime ester photoinitiators described in paragraph No. 0007 of JP2017-523465A; the photoinitiators described in paragraph Nos. 0020 to 0033 of JP2017-167399A; the photopolymerization initiator (A) described in paragraph Nos. 0017 to 0026 of JP2017-151342A; and the oxime ester photoinitiators described in JP6469669B.

In a case where the composition for forming an underlayer film contains a photopolymerization initiator, a content of the photopolymerization initiator in the total solid content of the composition for forming an underlayer film is preferably 0.5% to 20% by mass. The lower limit is preferably 0.7% by mass or more and more preferably 1% by mass or more. The upper limit is preferably 15% by mass or less and more preferably 10% by mass or less. In addition, the content of the photopolymerization initiator is preferably 0.001% to 0.5% by mass with respect to the total mass of the composition for forming an underlayer film. The lower limit is preferably 0.005% by mass or more and more preferably 0.01% by mass or more. The upper limit is preferably 0.3% by mass or less and more preferably 0.1% by mass or less.

The photopolymerization initiator may be used singly or in combination of two or more kinds thereof. In a case where two or more kinds thereof are used in combination, the total amount thereof is within the above-described range.

### «Polymerization Inhibitor»

The composition for forming an underlayer film can contain a polymerization inhibitor. Examples of the polymerization inhibitor include hydroquinone, p-methoxyphenol, di-tert-butyl-p-cresol, pyrogallol, tert-butyl catechol, benzoquinone, 4,4′-thiobis(3-methyl-6-tert-butylphenol), 2,2′-methylenebis(4-methyl-6-t-butylphenol), and an N-nitrosophenylhydroxylamine salt (an ammonium salt, a cerous salt, or the like). Among these, p-methoxyphenol is preferable.

In a case where the composition for forming an underlayer film contains a polymerization inhibitor, a content of the polymerization inhibitor in the total solid content of the composition for forming an underlayer film is preferably 0.0001% to 1% by mass. The lower limit is preferably 0.001% by mass or more and more preferably 0.01% by mass or more. The upper limit is preferably 0.5% by mass or less and more preferably 0.1% by mass or less.

In addition, the content of the polymerization inhibitor is preferably 0.00001% to 0.1% by mass with respect to the total mass of the composition for forming an underlayer film. The lower limit is preferably 0.0001% by mass or more and more preferably 0.001% by mass or more. The upper limit is preferably 0.05% by mass or less and more preferably 0.01% by mass or less.

The polymerization inhibitor may be used singly or in combination of two or more kinds thereof. In a case where two or more kinds thereof are used in combination, the total amount thereof is within the above-described range.

### «Other Components»

The composition for forming an underlayer film may further include other additives such as an ultraviolet absorber, an antioxidant, and a thermal acid generator, and with respect to the total solid content of the composition for forming an underlayer film, a content of the other additives is preferably 1% by mass or less and more preferably 0.1% by mass or less, and it is still more preferable that the composition for forming an underlayer film does not contain the other additives.

In the composition for forming an underlayer film, a content of halogen is preferably 0.01% by mass or less, more preferably 0.001% by mass or less, and still more preferably 0.0001% by mass or less, and it is particularly preferable that the composition for forming an underlayer film does not substantially contain halogen.

### Color Filter

Next, the color filter according to an embodiment of the present invention will be described.

The color filter according to the embodiment of the present invention includes a support, an underlayer film formed on the support, and a pixel formed on the underlayer film, in which the underlayer film includes a resin a-1 having an alkyleneoxy structure in an amount of 50% by mass or more, and a film thickness of the underlayer film is 30 nm or less.

A material of the support in the color filter is not particularly limited. Examples thereof include a silicon substrate, a SiN substrate, SiO₂, a glass substrate, a quartz substrate, and an InGaAs substrate. In addition, a support 10 may be provided with a photoelectric conversion unit. Examples of the photoelectric conversion unit include a silicon photodiode, an InGaAs photodiode, an organic photoelectric conversion film, and a quantum dot. In addition, a gap may be formed between the adjacent photoelectric conversion units.

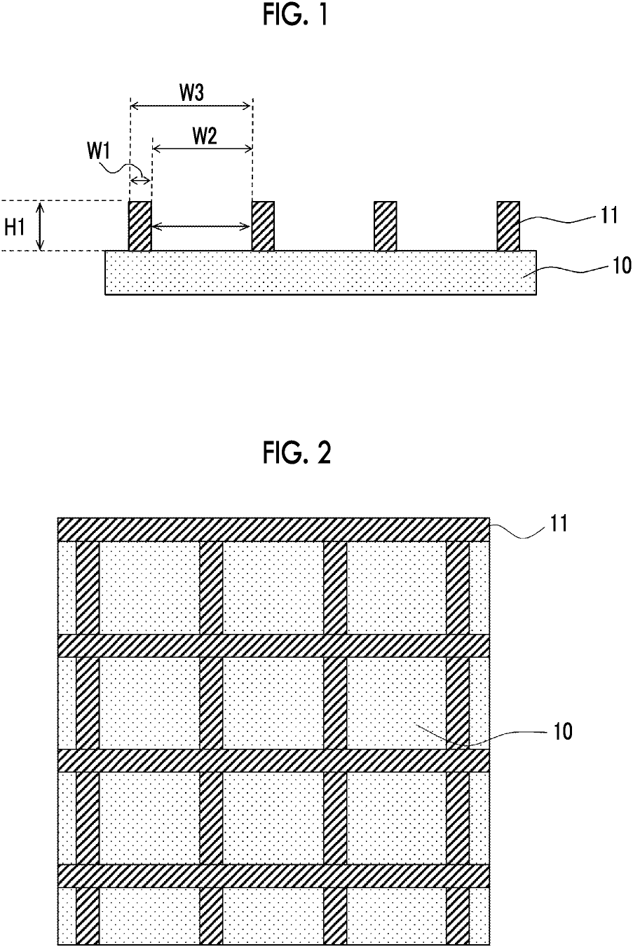

In addition, as shown in FIGS. 1 and 2, a partition wall 11 may be formed on a surface of the support 10. In FIG. 2, a shape of a region comparted by the partition wall 11 on the support 10 (hereinafter, also referred to as a shape of an opening portion of the partition wall) is a square shape, but the shape of the opening portion of the partition wall is not particularly limited, and may be, for example, a rectangular shape, a circular shape, an elliptical shape, a polygonal shape, or the like.

A material of the partition wall 11 is not particularly limited, but it is preferable that the partition wall 11 is formed of a material having a refractive index smaller than that of the pixel formed between the partition walls. As a result, light which is to be leaked from the pixel having a larger refractive index is easily reflected by the partition wall 11 and returned to the pixel, and it is possible to suppress the leakage of light to adjacent pixels. As a specific example of the material of the partition wall 11, various inorganic materials and organic materials can be used. Examples of the organic material include acrylic resin, polystyrene resin, polyimide resin, organic spin on glass (SOG) resin, siloxane resin, and fluororesin. Examples of the inorganic material include porous silica, polycrystalline silicon, silica particles, silicon oxide, silicon nitride, and metal materials such as tungsten and aluminum. From the reason that it is possible to increase strength of the partition wall, the partition wall 11 preferably includes silica particles.

From the reason that, in a case where the color filter is exposed to high temperatures, it is possible to suppress heat transfer from the partition wall to the pixel, the silica particles are preferably silica particles having a shape in which a plurality of spherical silicas are connected in a bead shape (hereinafter, also referred to as beaded silica) or silica particles having a hollow structure (hereinafter, also referred to as hollow silica), and more preferably beaded silica. In addition, in the silica particles, it is also preferable that at least a part of hydroxy groups on a surface of the silica particles is treated with a hydrophobizing treatment agent which reacts with the hydroxy groups. As the hydrophobizing treatment agent, a compound having a structure which reacts with the hydroxy group on the surface of the silica particles (preferably, a structure which reacts with the hydroxy group on the surface of the silica particles by coupling) so as to improve hydrophobicity of the silica particles is used. The hydrophobizing treatment agent is preferably an organic compound. Specific examples of the hydrophobizing treatment agent include an organosilane compound, an organotitanium compound, an organozirconium compound, and an organoaluminum compound, and from the reason that increase in refractive index can be suppressed, an organosilane compound is more preferable. In the present specification, the “spherical” means that the particle may be substantially spherical and may be deformed within a range in which the effect of the present invention is exhibited. For example, the “spherical” is meant to include a shape having roughness on the surface, and a flat surface having a long axis in a predetermined direction. In addition, the “a plurality of spherical silica particles are linked in a beaded shape” means a structure in which a plurality of spherical silica particles are linked in a linear and/or branched form. Examples thereof include a structure in which a plurality of spherical silica particles are linked by a joint having a smaller outer diameter. In addition, in the present invention, the structure in which “a plurality of spherical silica particles are linked in a beaded shape” includes not only a ring-shaped structure, but also a chain-shaped structure with ends.

In the beaded silica, a ratio D₁/D₂ of an average particle diameter D₁ measured by a dynamic light scattering method and an average particle diameter D₂ obtained by the following expression (1) is preferably 3 or more. The upper limit of D₁/D₂ is not particularly limited, but is preferably 1000 or less, more preferably 800 or less, and still more preferably 500 or less. By setting D₁/D₂ within such a range, good optical characteristics can be exhibited. The value of D₁/D₂ in the beaded silica is also an indicator of a degree of connection of the spherical silica.

$${\text{D}}_{2} = 2720 / \text{S} \qquad \text{(1)}$$

In the expression, D₂ is an average particle diameter of the beaded silica, in units of nm, and S is a specific surface area of the beaded silica measured by a nitrogen adsorption process, in units of m²/g.

The above-described average particle diameter D₂ of the beaded silica can be regarded as an average particle diameter close to a diameter of primary particles of the spherical silica. The average particle diameter D₂ is preferably 1 nm or more, more preferably 3 nm or more, still more preferably 5 nm or more, and particularly preferably 7 nm or more. The upper limit is preferably 100 nm or less, more preferably 80 nm or less, still more preferably 70 nm or less, even more preferably 60 nm or less, and particularly preferably 50 nm or less.

The average particle diameter D₂ can be replaced by a circle-equivalent diameter (D0) in a projection image of the spherical portion measured by a transmission electron microscope (TEM). Unless otherwise specified, the average particle diameter based on the circle-equivalent diameter is evaluated by the number average of 50 or more particles.

The above-described average particle diameter D₁ of the beaded silica can be regarded as a number average particle diameter of secondary particles in which a plurality of spherical silicas are collected. Therefore, a relationship of D₁ > D₂ is usually satisfied. The average particle diameter D₁ is preferably 5 nm or more, more preferably 7 nm or more, and particularly preferably 10 nm or more. The upper limit is preferably 100 nm or less, more preferably 70 nm or less, still more preferably 50 nm or less, and particularly preferably 45 nm or less.

Unless otherwise specified, the above-described average particle diameter D₁ of the beaded silica is measured using a dynamic light scattering type particle size distribution measuring device (Microtrac UPA-EX150, manufactured by Nikkiso Co., Ltd.). The procedure is as follows. A dispersion liquid of the beaded silica is divided into 20 ml sample bottles, and diluted with propylene glycol monomethyl ether so that the concentration of solid contents is 0.2% by mass. The diluted sample solution is irradiated with 40 kHz ultrasonic waves for 1 minute, and immediately after that, the sample solution is used for test. Data is captured 10 times using a 2 ml quartz cell for measurement at a temperature of 25° C., and the obtained “number average” is regarded as the average particle diameter. For other detailed conditions and the like, the description of “Particle size analysis - Dynamic light scattering method” in JIS Z8828:2013 can be referred to as necessary. Five samples are produced for each level and the average value thereof is adopted.

As the beaded silica, it is preferable that a plurality of spherical silicas having an average particle diameter of 1 to 80 nm are linked through a linking material. The upper limit of the average particle diameter of the spherical silica is preferably 70 nm or less, more preferably 60 nm or less, and still more preferably 50 nm or less. In addition, the lower limit of the average particle diameter of the spherical silica is preferably 3 nm or more, more preferably 5 nm or more, and still more preferably 7 nm or more. In the present invention, as the value of the average particle diameter of the spherical silica, a value of an average particle diameter obtained from the circle-equivalent diameter in the projection image of the spherical portion measured by a transmission electron microscope (TEM) is used.

In the beaded silica, examples of the linking material for linking the spherical silicas include metal oxide-containing silica. Examples of the metal oxide include an oxide of metal selected from Ca, Mg, Sr, Ba, Zn, Sn, Pb, Ni, Co, Fe, Al, In, Y, and Ti. Examples of the metal oxide-containing silica include a reactant and a mixture of these metal oxides and silica (SiO₂). With regard to the linking material, reference can be made to the description in WO2000/015552A, the content of which is incorporated herein by reference.

The number of linked spherical silicas in the beaded silica is preferably 3 or more and more preferably 5 or more. The upper limit is preferably 1000 or less, more preferably 800 or less, and still more preferably 500 or less. The number of linked spherical silicas can be measured by TEM.

Examples of a commercially available product of a particle solution including the beaded silica include SNOWTEX series and ORGANOSILICASOL series (methanol dispersion liquid, isopropyl alcohol dispersion liquid, ethylene glycol dispersion liquid, methyl ethyl ketone dispersion liquid, and the like; product numbers: IPA-ST-UP, MEK-ST-UP, and the like) manufactured by Nissan Chemical Corporation. In addition, as the particle solution including the beaded silica, for example, a silica sol described in JP4328935B can be used.

An average particle diameter of the hollow silica is preferably 10 to 500 nm. The lower limit is preferably 15 nm or more, more preferably 20 nm or more, and still more preferably 25 nm or more. The upper limit is preferably 300 nm or less, more preferably 200 nm or less, and still more preferably 100 nm or less. The average particle diameter of the hollow silica is a value measured by a dynamic light scattering method. Examples of a commercially available product of a particle solution including the hollow silica include “THRULYA 4110” (manufactured by JGC C&C).

The partition wall 11 can be formed by using a known method in the related art. For example, the partition wall can be formed as follows.

First, a partition wall material layer is formed on the support. The partition wall material layer can be formed, for example, by applying a composition (composition for forming a partition wall) including inorganic particles such as silica particles to the support, and then curing the composition. Examples of such a composition include compositions described in paragraph Nos. 0012 to 0077 and 0093 to 0105 of WO2019/017280A and compositions described in paragraph Nos. 0089 to 0091 of WO2019/111748A, the contents of which are incorporated herein by reference. A concentration of solid contents of the composition for forming a partition wall is preferably 3% to 20% by mass, more preferably 5% to 18% by mass, and still more preferably 7% to 16% by mass.

In addition, the partition wall material layer can also be formed by forming a film formed of an inorganic material such as silicon dioxide on the support by a vapor deposition method such as a chemical vapor deposition (CVD) and a vacuum vapor deposition, or a method such as sputtering.

Next, using a mask having a pattern which follows the shape of the partition wall, a resist pattern is formed on the partition wall material layer.

Next, using the resist pattern as a mask, the partition wall material layer is etched to form a pattern. Examples of the etching method include a dry etching method and a wet etching method. Etching by the dry etching method can be performed under conditions described in paragraph Nos. 0128 to 0133 of JP2016-014856A. Next, the resist pattern is peeled off from the partition wall material layer. In this way, the partition wall can be formed.

A width W1 of the partition wall 11 is preferably 80 to 150 nm. From the viewpoint of strength of the partition wall, the lower limit of the width W1 of the partition wall 11 is preferably 90 nm or more, more preferably 100 nm or more, and still more preferably 110 nm or more. From the viewpoint of ensuring an effective pixel size, the upper limit of the width W1 of the partition wall 11 is preferably 140 nm or less and more preferably 130 nm or less.

A thickness (height) H1 of the partition wall 11 is preferably 300 to 650 nm. The lower limit of the thickness H1 of the partition wall 11 is preferably 350 nm or more, more preferably 400 nm or more, and still more preferably 450 nm or more. The upper limit of the thickness H1 of the partition wall 11 is preferably 600 nm or less, more preferably 550 nm or less, and still more preferably 500 nm or less.

In the present specification, the thickness of the partition wall means a length of the partition wall in a vertical direction, and the width of the partition wall means a length of the partition wall in a horizontal direction.

A void ratio of the partition wall 11 is preferably 20% to 80%. The lower limit of the void ratio is preferably 30% or more and more preferably 40% or more. The upper limit of the void ratio is preferably 70% or less and more preferably 60% or less. In a case where the void ratio of the partition wall 11 is within the above-described range, exposure light can be more effectively collected in the pixel portion by the partition wall during formation of the pixel, and utilization efficiency of the exposure light can be further improved. Furthermore, even in a case where light is incident on the pixel of the color filter from an oblique direction, light leak to adjacent pixels can be effectively suppressed. The void ratio of the partition wall is a value measured by an X-ray reflectivity method. In addition, since the partition wall has voids, thermal conductivity of the partition wall is lowered, and the heat transfer from the partition wall to the pixel portion can be suppressed.

A pitch W3 of the partition wall 11 disposed on the support 10 is preferably 400 to 1200 nm. The lower limit of the pitch W3 is preferably 450 nm or more, and more preferably 500 nm or more. The upper limit of the pitch W3 is preferably 1000 nm or less, more preferably 900 nm or less, and still more preferably 800 nm or less. In the present specification, the pitch of the partition wall is the total value of the width W1 of the partition wall and a width W2 of a partition wall opening portion 12 (distance between facing surfaces of the partition walls arranged to face each other).

In addition, the width W2 of the partition wall opening portion is preferably 300 to 1100 nm. The lower limit is preferably 400 nm or more and more preferably 450 nm or more. The upper limit is preferably 1000 nm or less and more preferably 900 nm or less.

In the color filter according to the embodiment of the present invention, the underlayer film is formed on the support. The underlayer film includes a resin a-1 (specific resin) having an alkyleneoxy structure in an amount of 50% by mass or more. Examples of the resin a-1 include the resin described as the specific resin above, and a preferred range thereof is the same.

A content of the resin a-1 (specific resin) in the underlayer film is 50% by mass or more, preferably 70% by mass or more and more preferably 90% by mass or more. The upper limit may be 100% by mass or less.

A film thickness of the underlayer film is 30 nm or less, preferably 1 to 20 nm and more preferably 1 to 10 nm.

In a case where the partition wall is formed on the support, the underlayer film may also be formed on a side surface of the partition wall.

The underlayer film in the color filter is preferably an underlayer film formed of the composition for forming an underlayer film according to the embodiment of the present invention.

In the color filter according to the embodiment of the present invention, the pixel is formed on the support. The type of the pixel is not particularly limited. Examples thereof include colored pixels such as a red pixel, a blue pixel, a green pixel, a yellow pixel, a magenta pixel, and a cyan pixel, a transparent pixel, a pixel of an infrared transmitting filter, and a pixel of an infrared cut filter. It is preferable that at least one type of the pixel is a colored pixel. The colored pixel can be formed by using a known composition for forming a colored pixel in the related art. For example, a composition including a coloring material, a polymerizable compound, a photopolymerization initiator, a resin, and a solvent can be used.

A film thickness of the pixel is preferably 20 µm or less, more preferably 10 µm or less, and still more preferably 5 µm or less. The lower limit of the film thickness is preferably 0.1 µm or more, more preferably 0.2 µm or more, and still more preferably 0.3 µm or more.

A width of the pixel is preferably 0.4 to 10.0 µm. The lower limit is preferably 0.4 µm or more, more preferably 0.5 µm or more, and still more preferably 0.6 µm or more. The upper limit is preferably 5.0 µm or less, more preferably 2.0 µm or less, still more preferably 1.0 µm or less, and even more preferably 0.8 µm or less.

In the color filter according to the embodiment of the present invention, the underlayer film may also be formed on a side surface or a surface of the pixel.

In the color filter according to the embodiment of the present invention, a protective layer may be provided on the surface of each pixel. By providing the protective layer, various functions such as oxygen shielding, low reflection, hydrophilicity/hydrophobicity, and shielding of light (ultraviolet rays, near-infrared rays, and the like) having a specific wavelength can be imparted. The thickness of the protective layer is preferably 0.01 to 10 µm and more preferably 0.1 to 5 µm. Examples of a method for forming the protective layer include a method of forming the protective layer by applying a resin composition for forming a protective layer, a chemical vapor deposition method, and a method of attaching a molded resin with an adhesive. Examples of components constituting the protective layer include a (meth)acrylic resin, an ene-thiol resin, a polycarbonate resin, a polyether resin, a polyarylate resin, a polysulfone resin, a polyethersulfone resin, a polyphenylene resin, a polyarylene ether phosphine oxide resin, a polyimide resin, a polyamidoimide resin, a polyolefin resin, a cyclic olefin resin, a polyester resin, a styrene resin, a polyol resin, a polyvinylidene chloride resin, a melamine resin, a urethane resin, an aramid resin, a polyamide resin, an alkyd resin, an epoxy resin, a modified silicone resin, a fluororesin, a polyacrylonitrile resin, a cellulose resin, Si, C, W, Al₂O₃, Mo, SiO₂, and Si₂N₄, and two or more kinds of these components may be contained. For example, in a case of a protective layer for oxygen shielding, it is preferable that the protective layer contains a polyol resin, SiO₂, and Si₂N₄. In addition, in a case of a protective layer for low reflection, it is preferable that the protective layer contains a (meth)acrylic resin and a fluororesin.

The protective layer may contain, as desired, an additive such as organic or inorganic fine particles, an absorber of light (for example, ultraviolet rays, near-infrared rays, and the like) having a specific wavelength, a refractive index adjusting agent, an antioxidant, an adhesive agent, and a surfactant. Examples of the organic or inorganic fine particles include polymer fine particles (for example, silicone resin fine particles, polystyrene fine particles, and melamine resin fine particles), titanium oxide, zinc oxide, zirconium oxide, indium oxide, aluminum oxide, titanium nitride, titanium oxynitride, magnesium fluoride, hollow silica, silica, calcium carbonate, and barium sulfate. As the absorber of light having a specific wavelength, a known absorber can be used. The content of these additives can be appropriately adjusted, but is preferably 0.1% to 70% by mass and still more preferably 1% to 60% by mass with respect to the total mass of the protective layer.

In addition, as the protective layer, the protective layers described in paragraph Nos. 0073 to 0092 of JP2017-151176A can also be used.

Examples of a preferred aspect of the color filter according to the embodiment of the present invention include a color filter of an aspect in which the partition wall is formed on the surface of the support, the underlayer film is formed on the support and in a region comparted by the partition wall, and the pixel is formed on the underlayer film.

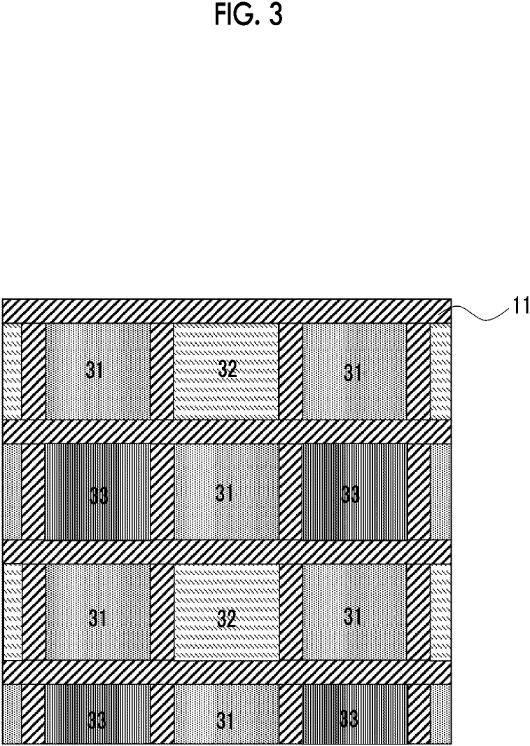

Examples of the color filter of such an aspect include a color filter of an aspect shown in FIG. 3. FIG. 3 is a view showing one embodiment of a color filter using a support which has the partition wall having the structure shown in FIGS. 1 and 2, and is a plan view as viewed from directly above the support, in which the reference numeral 11 is the partition wall and the reference numerals 31 to 33 are the pixels.

### Method for Manufacturing Color Filter

Next, a method for manufacturing the color filter according to an embodiment of the present invention will be described.

The method for manufacturing a color filter according to an embodiment of the present invention includes a step of forming an underlayer film by applying the above-described composition for forming an underlayer film according to the embodiment of the present invention onto a support, and a step of forming a pixel on the underlayer film.

In the step of forming the underlayer film, the composition for forming an underlayer film according to the embodiment of the present invention is applied onto the support to form the underlayer film. Examples of the support are as described above.

The method of applying the composition for forming an underlayer film is not particularly limited, and examples thereof include a spin coating method, a slit coating method, an ink jet method, a dip coating method, and a screen printing method. Among these, from the reason that a film can be uniformly formed with a small amount, a spin coating method is preferable.

After applying the composition for forming an underlayer film onto the support, a drying treatment may be further carried out. Drying conditions are not particularly limited. For example, drying temperature is preferably 60° C. to 150° C. The upper limit of the drying temperature is preferably 130° C. or lower and more preferably 110° C. or lower. The lower limit of the drying temperature is preferably 80° C. or higher and more preferably 90° C. or higher. Drying time is preferably 60 to 600 seconds. The upper limit of the drying time is preferably 300 seconds or less and more preferably 180 seconds or less. The lower limit of the drying time is preferably 80 seconds or more and more preferably 100 seconds or more. The drying can be carried out using a hot plate, an oven, or the like.

After drying the composition for forming an underlayer film applied onto the support, a heating treatment (post-baking) may be further carried out. In a case where post-baking is performed, for example, post-baking temperature is preferably 180° C. to 260° C. The upper limit of the post-baking temperature is preferably 250° C. or lower and more preferably 240° C. or lower. The lower limit of the post-baking temperature is preferably 190° C. or higher and more preferably 200° C. or higher. Post-baking time is preferably 60 to 600 seconds. The upper limit of the post-baking time is preferably 300 seconds or less and more preferably 180 seconds or less. The lower limit of the post-baking time is preferably 80 seconds or more and more preferably 100 seconds or more. The post-baking can be carried out using a hot plate, an oven, or the like.

In the step of forming the pixel, the pixel is formed on the underlayer film formed as described above. The step of forming the pixel includes a step of applying a composition for forming a pixel to form a composition layer for forming a pixel, a step of exposing the composition layer for forming a pixel in a patterned manner, and a step of removing a non-exposed portion of the composition layer for forming a pixel by development. Hereinafter, the respective steps will be described.

### (Step of Forming Composition Layer for Forming Pixel)

In the step of forming a composition layer for forming a pixel, a composition for forming a pixel is applied onto the underlayer film to form a composition layer for forming a pixel. As a method for applying the composition for forming a pixel, a known method can be used. Examples thereof include a dropping method (drop casting); a slit coating method; a spray method; a roll coating method; a spin coating method (spin coating); a cast coating method; a slit and spin method; a pre-wet method (for example, a method described in JP2009-145395A), various printing methods such as an inkjet (for example, on-demand type, piezo type, thermal type), a discharge printing such as nozzle jet, a flexo printing, a screen printing, a gravure printing, a reverse offset printing, and a metal mask printing; a transfer method using molds and the like; and a nanoimprinting method. A method for applying the ink jet is not particularly limited, and examples thereof include a method described in “Extension of Use of Ink Jet -Infinite Possibilities in Patent-” (February, 2005, S. B. Research Co., Ltd.) (particularly pp. 115 to 133) and methods described in JP2003-262716A, JP2003-185831A, JP2003-261827A, JP2012-126830A, and JP2006-169325A. In addition, with regard to the method for applying the coloring composition, reference can be made to the description in WO2017/030174A and WO2017/018419A, the contents of which are incorporated herein by reference.

After applying the composition for forming a pixel onto the underlayer film, a drying (pre-baking) may be further carried out. In a case of carrying out the pre-baking, the pre-baking temperature is preferably 150° C. or lower, more preferably 120° C. or lower, and still more preferably 110° C. or lower. The lower limit may be set to, for example, 50° C. or higher, or to 80° C. or higher. Pre-baking time is preferably 10 to 3000 seconds, more preferably 40 to 2500 seconds, and still more preferably 80 to 2200 seconds. The pre-baking can be carried out using a hot plate, an oven, or the like.

### (Exposing Step)

In the exposing step, the composition layer for forming a pixel, formed on the underlayer film, is exposed in a patterned manner. For example, the composition layer for forming a pixel can be exposed in a patterned manner using a stepper exposure device or a scanner exposure device through a mask having a predetermined mask pattern. As a result, the exposed portion can be cured.

Examples of radiation (light) which can be used during the exposure include g-rays and i-rays. The radiation (light) which can be used during the exposure is preferably light having a wavelength of 300 nm or less (preferably light having a wavelength of 180 to 300 nm). That is, in the exposing step, it is preferable to perform exposure by irradiation with light having a wavelength of 300 nm or less. Examples of the light having a wavelength of 300 nm or less include KrF-rays (wavelength: 248 nm) and ArF-rays (wavelength: 193 nm), and KrF-rays (wavelength: 248 nm) are preferable. In addition, the exposure may be performed using light having a wavelength of more than 300 nm.

In addition, in a case of exposure, the photosensitive composition layer may be irradiated with light continuously to expose the photosensitive composition layer, or the photosensitive composition layer may be irradiated with light in a pulse to expose the photosensitive composition layer (pulse exposure). The pulse exposure refers to an exposing method in which light irradiation and resting are repeatedly performed in a short cycle (for example, millisecond-level or less).

The irradiation amount (exposure amount) is, for example, preferably 0.03 to 2.5 J/cm² and more preferably 0.05 to 1.0 J/cm². The oxygen concentration during the exposure can be appropriately selected, and the exposure may also be performed, for example, in a low-oxygen atmosphere having an oxygen concentration of 19% by volume or less (for example, 15% by volume, 5% by volume, and substantially oxygen-free) or in a high-oxygen atmosphere having an oxygen concentration of more than 21% by volume (for example, 22% by volume, 30% by volume, and 50% by volume), in addition to an atmospheric air. In addition, the exposure illuminance can be appropriately set, and can be usually selected from a range of 1000 W/m² to 100000 W/m² (for example, 5000 W/m², 15000 W/m², or 35000 W/m²). Appropriate conditions of each of the oxygen concentration and the exposure illuminance may be combined, and for example, a combination of the oxygen concentration of 10% by volume and the illuminance of 10000 W/m², a combination of the oxygen concentration of 35% by volume and the illuminance of 20000 W/m², or the like is available.

### (Developing and Removing Step)

Next, the non-exposed portion of the composition layer for forming a pixel is removed by development. The non-exposed portion of the composition layer for forming a pixel can be removed by development using a developer. As a result, the composition layer for forming a pixel of the non-exposed portion in the exposure step is eluted into the developer, and as a result, only a photocured portion remains and the pixel is formed. The temperature of the developer is preferably, for example, 20° C. to 30° C. The development time is preferably 20 to 180 seconds. In addition, in order to improve residue removing properties, a step of removing the developer by shaking off per 60 seconds and supplying a fresh developer may be repeated multiple times.

Examples of the developer include an organic solvent and an alkali developer, and an alkali developer is preferably used. As the alkali developer, an alkaline aqueous solution (alkali developer) in which an alkaline agent is diluted with pure water is preferable. Examples of the alkali agent include organic alkaline compounds such as ammonia, ethylamine, diethylamine, dimethylethanolamine, diglycol amine, diethanolamine, hydroxyamine, ethylenediamine, tetramethylammonium hydroxide, tetraethylammonium hydroxide, tetrapropylammonium hydroxide, tetrabutylammonium hydroxide, ethyltrimethylammonium hydroxide, benzyltrimethylammonium hydroxide, dimethylbis(2-hydroxyethyl)ammonium hydroxide, choline, pyrrole, piperidine, and 1,8-diazabicyclo-[5.4.0]-7-undecene, and inorganic alkaline compounds such as sodium hydroxide, potassium hydroxide, sodium carbonate, sodium hydrogen carbonate, sodium silicate, and sodium metasilicate. In consideration of environmental aspects and safety aspects, the alkali agent is preferably a compound having a high molecular weight. The concentration of the alkali agent in the alkaline aqueous solution is preferably 0.001% to 10% by mass and more preferably 0.01% to 1% by mass. In addition, the developer may further contain a surfactant. From the viewpoint of transportation, storage, and the like, the developer may be first produced as a concentrated solution and then diluted to a concentration required upon the use. The dilution ratio is not particularly limited, and can be set to, for example, a range of 1.5 to 100 times. In addition, it is also preferable to wash (rinse) with pure water after development. In addition, it is preferable that the rinsing is performed by supplying a rinsing liquid to the composition layer for forming a pixel after development while rotating the support on which the composition layer for forming a pixel after development is formed. In addition, it is preferable that the rinsing is performed by moving a nozzle discharging the rinsing liquid from a center of the support to a peripheral edge of the support. In this case, in the movement of the nozzle from the center of the support to the peripheral edge of the support, the nozzle may be moved while gradually decreasing the moving speed of the nozzle. By performing rinsing in this manner, in-plane variation of rinsing can be suppressed. In addition, the same effect can be obtained by gradually decreasing the rotating speed of the support while moving the nozzle from the center of the support to the peripheral edge of the support.

After the development, it is preferable to carry out an additional exposure treatment or a heating treatment (post-baking) after carrying out drying. The additional exposure treatment or the post-baking is a curing treatment after development in order to complete curing. The heating temperature in the post-baking is preferably, for example, 100° C. to 240° C. and more preferably 200° C. to 240° C. The film after development is post-baked continuously or batchwise using a heating unit such as a hot plate, a convection oven (hot air circulation dryer), and a high-frequency heater under the above-described conditions. In a case of performing the additional exposure treatment, light used for the exposure is preferably light having a wavelength of 400 nm or less. In addition, the additional exposure treatment may be carried out by the method described in KR10-2017-0122130A.

In a case where a plurality of types of pixels are formed, a color filter including the plurality of pixels can be manufactured by repeating the above-described step of forming the pixel for each type of pixel.

In a case of forming a plurality of types of pixels, it is preferable that the above-described step of forming the underlayer film and the above-described step of forming the pixel are alternately performed two or more times to form two or more kinds of pixels. According to this aspect, by alternately performing the step of forming the underlayer film and the step of forming a pixel of each color, residues of subsequent composition for forming a pixel remain on the previously formed pixel can be suppressed, and a color filter with better image performance can be manufactured.

Next, the composition for forming a pixel will be described.

The composition for forming a pixel preferably contains a coloring material. Examples of the coloring material include a yellow coloring material, an orange coloring material, a red coloring material, a green coloring material, a violet coloring material, and a blue coloring material. The coloring material may be a pigment or a dye. The pigment and the dye may be used in combination. In addition, the pigment may be either an inorganic pigment or an organic pigment. In addition, as the pigment, a material in which a part of an inorganic pigment or an organic-inorganic pigment is substituted with an organic chromophore can also be used. By substituting an inorganic pigment or an organic-inorganic pigment with an organic chromophore, hue design can be easily performed.

An average primary particle diameter of the pigment is preferably 1 to 200 nm. The lower limit is preferably 5 nm or more and more preferably 10 nm or more. The upper limit is preferably 180 nm or less, more preferably 150 nm or less, and still more preferably 100 nm or less. In a case where the average primary particle diameter of the pigment is within the above-described range, dispersion stability of the pigment in the photosensitive composition is good. In the present invention, the primary particle diameter of the pigment can be determined from a captured image obtained by observing primary particles of the pigment using a transmission electron microscope. Specifically, a projected area of the primary particles of the pigment is determined, and the corresponding circle-equivalent diameter is calculated as the primary particle diameter of the pigment. In addition, the average primary particle diameter in the present invention is an arithmetic average of the primary particle diameters with respect to 400 primary particles of the pigment. In addition, the primary particle of the pigment refers to a particle which is independent without aggregation.

It is preferable to use a coloring material including the pigment. A content of the pigment in the coloring material is preferably 50% by mass or more, more preferably 70% by mass or more, still more preferably 80% by mass or more, and particularly preferably 90% by mass or more. Examples of the pigment include the following pigments:
Color Index (C. I.) Pigment Yellow 1, 2, 3, 4, 5, 6, 10, 11, 12, 13, 14, 15, 16, 17, 18, 20, 24, 31, 32, 34, 35, 35:1, 36, 36:1, 37, 37:1, 40, 42, 43, 53, 55, 60, 61, 62, 63, 65, 73, 74, 77, 81, 83, 86, 93, 94, 95, 97, 98, 100, 101, 104, 106, 108, 109, 110, 113, 114, 115, 116, 117, 118, 119, 120, 123, 125, 126, 127, 128, 129, 137, 138, 139, 147, 148, 150, 151, 152, 153, 154, 155, 156, 161, 162, 164, 166, 167, 168, 169, 170, 171, 172, 173, 174, 175, 176, 177, 179, 180, 181, 182, 185, 187, 188, 193, 194, 199, 213, 214, 215, 228, 231, 232 (methine-based), 233 (quinoline-based), 234 (aminoketone-based), 235 (aminoketone-based), 236 (aminoketone-based), and the like (all of which are yellow pigments);
C. I. Pigment Orange 2, 5, 13, 16, 17:1, 31, 34, 36, 38, 43, 46, 48, 49, 51, 52, 55, 59, 60, 61, 62, 64, 71, and 73 (all of which are orange pigments);
C. I. Pigment Red 1, 2, 3, 4, 5, 6, 7, 9, 10, 14, 17, 22, 23, 31, 38, 41, 48:1, 48:2, 48:3, 48:4, 49, 49:1, 49:2, 52:1, 52:2, 53:1, 57:1, 60:1, 63:1, 66, 67, 81:1, 81:2, 81:3, 83, 88, 90, 105, 112, 119, 122, 123, 144, 146, 149, 150, 155, 166, 168, 169, 170, 171, 172, 175, 176, 177, 178, 179, 184, 185, 187, 188, 190, 200, 202, 206, 207, 208, 209, 210, 216, 220, 224, 226, 242, 246, 254, 255, 264, 269, 270, 272, 279, 291, 294 (xanthene-based, Organo Ultramarine, Bluish Red), 295 (monoazo-based), 296 (diazo-based), 297 (aminoketone-based), and the like (all of which are red pigments);
C. I. Pigment Green 7, 10, 36, 37, 58, 59, 62, 63, 64 (phthalocyanine-based), 65 (phthalocyanine-based), 66 (phthalocyanine-based), and the like (all of which are green pigments);
C. I. Pigment Violet 1, 19, 23, 27, 32, 37, 42, 60 (triarylmethane-based), 61 (xanthene-based), and the like (all of which are violet pigments); and
C. I. Pigment Blue 1, 2, 15, 15:1, 15:2, 15:3, 15:4, 15:6, 16, 22, 29, 60, 64, 66, 79, 80, 87 (monoazo-based), 88 (methine-based), and the like (all of which are blue pigments).

In addition, a halogenated zinc phthalocyanine pigment having an average number of halogen atoms in one molecule of 10 to 14, an average number of bromine atoms in one molecule of 8 to 12, and an average number of chlorine atoms in one molecule of 2 to 5 can also be used as the green coloring material. Specific examples thereof include the compounds described in WO2015/118720A. In addition, as the green coloring material, a compound described in CN2010-6909027A, a phthalocyanine compound described in WO2012/102395A, which has phosphoric acid ester as a ligand, a phthalocyanine compound described in JP2019-008014A, a phthalocyanine compound described in JP2018-180023A, a compound described in JP2019-038958A, and the like can also be used. In addition, as the green coloring material, a core-shell type coloring agent described in JP2020-076995A can also be used.

In addition, as the blue coloring material, an aluminum phthalocyanine compound having a phosphorus atom can also be used. Specific examples thereof include the compounds described in paragraph Nos. 0022 to 0030 of JP2012-247591A and paragraph No. 0047 of JP2011-157478A.

In addition, as the yellow coloring material, an azobarbiturate nickel complex having the following structure can also be used.

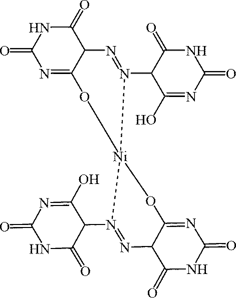

In addition, as the yellow coloring material, compounds described in JP2017-201003A, compounds described in JP2017-197719A, compounds described in paragraph Nos. 0011 to 0062 and 0137 to 0276 of JP2017-171912A, compounds described in paragraph Nos. 0010 to 0062 and 0138 to 0295 of JP2017-171913A, compounds described in paragraph Nos. 0011 to 0062 and 0139 to 0190 of JP2017-171914A, compounds described in paragraph Nos. 0010 to 0065 and 0142 to 0222 of JP2017-171915A, quinophthalone compounds described in paragraph Nos. 0011 to 0034 of JP2013-054339A, quinophthalone compounds described in paragraph Nos. 0013 to 0058 of JP2014-026228A, isoindoline compounds described JP2018-062644A, quinophthalone compounds described in JP2018-203798A, quinophthalone compounds described in JP2018-062578A, quinophthalone compounds described in JP6432076B, quinophthalone compounds described in JP2018-155881A, quinophthalone compounds described in JP2018-111757A, quinophthalone compounds described in JP2018-040835A, quinophthalone compounds described in JP2017-197640A, quinophthalone compounds described in JP2016-145282A, quinophthalone compounds described in JP2014-085565A, quinophthalone compounds described in JP2014-021139A, quinophthalone compounds described in JP2013-209614A, quinophthalone compounds described in JP2013-209435A, quinophthalone compounds described in JP2013-181015A, quinophthalone compounds described in JP2013-061622A, quinophthalone compounds described in JP2013-032486A, quinophthalone compounds described in JP2012-226110A, quinophthalone compounds described in JP2008-074987A, quinophthalone compounds described in JP2008-081565A, quinophthalone compounds described in JP2008-074986A, quinophthalone compounds described in JP2008-074985A, quinophthalone compounds described in JP2008-050420A, quinophthalone compounds described in JP2008-031281A, quinophthalone compounds described in JP1973-032765A (JP-S48-032765A), quinophthalone compounds described in JP2019-008014A, quinophthalone compounds described in JP6607427B, methine dyes described in JP2019-073695A, methine dyes described in JP2019-073696A, methine dyes described in JP2019-073697A, methine dyes described in JP2019-073698A, a compound represented by Formula (QP1), a compound represented by Formula (QP2), compounds described in KR10-2014-0034963A, compounds described in JP2017-095706A, compounds described in TW2019-20495A, compounds described in JP6607427B, and quinophthalone dimers described in JP2020-033521A can also be used. In addition, from the viewpoint of improving a color value, a multimerized compound of these compounds is also preferably used.

As the red coloring material, diketopyrrolopyrrole compounds described in JP2017-201384A, in which the structure has at least one substituted bromine atom, diketopyrrolopyrrole compounds described in paragraph Nos. 0016 to 0022 of JP6248838B, diketopyrrolopyrrole compounds described in WO2012/102399A, diketopyrrolopyrrole compounds described in WO2012/117965A, naphtholazo compounds described in JP2012-229344A, red coloring materials described in JP6516119B, red coloring materials described in JP6525101B, brominated diketopyrrolopyrrole compounds described in paragraph No. 0229 of JP2020-090632A, anthraquinone compounds described in KR10-2019-0140741A, anthraquinone compounds described in KR10-2019-0140744A, perylene compounds described in JP2020-079396A, and the like can also be used. In addition, as the red pigment, a compound having a structure that an aromatic ring group in which a group bonded with an oxygen atom, a sulfur atom, or a nitrogen atom is introduced to an aromatic ring is bonded to a diketopyrrolopyrrole skeleton can be used.

In addition, as the coloring material, diarylmethane compounds described in JP2020-504758A can also be used.

Regarding diffraction angles preferably possessed by various pigments, descriptions of JP6561862B, JP6413872B, JP6281345B, and JP2020-026503A can be referred to, the contents of which are incorporated herein by reference. In addition, in the pyrrolopyrrole-based pigment, it is also preferable that a crystallite size in a plane direction corresponding to the maximum peak in the X-ray diffraction pattern among eight planes (±1 ±1 ±1) of the crystal lattice planes is 140 Å or less. In addition, it is also preferable that physical properties of the pyrrolopyrrole-based pigment are set as described in paragraph Nos. 0028 to 0073 of JP2020-097744A.

A content of the coloring material in the total solid content of the composition for forming a pixel is preferably 10% by mass or more, more preferably 20% by mass or more, and still more preferably 30% by mass or more. The upper limit is preferably 80% by mass or less, more preferably 75% by mass or less, and still more preferably 70% by mass or less. The coloring material contained in the composition for forming a pixel may be used singly or in a combination of two or more kinds thereof. In a case where the composition for forming a pixel contains two or more kinds of coloring materials, it is preferable that the total amount thereof is within the above-described range.

In a case where the pigment is used as the coloring material, the composition for forming a pixel preferably contains a pigment derivative. Examples of the pigment derivative include a compound having a structure in which an acid group or a basic group is bonded to a coloring agent skeleton. Examples of the coloring agent skeleton constituting the pigment derivative include a quinoline coloring agent skeleton, a benzoimidazolone coloring agent skeleton, a benzoisoindole coloring agent skeleton, a benzothiazole coloring agent skeleton, an iminium coloring agent skeleton, a squarylium coloring agent skeleton, a croconium coloring agent skeleton, an oxonol coloring agent skeleton, a pyrrolopyrrole coloring agent skeleton, a diketopyrrolopyrrole coloring agent skeleton, an azo coloring agent skeleton, an azomethine coloring agent skeleton, a phthalocyanine coloring agent skeleton, a naphthalocyanine coloring agent skeleton, an anthraquinone coloring agent skeleton, a quinacridone coloring agent skeleton, a dioxazine coloring agent skeleton, a perinone coloring agent skeleton, a perylene coloring agent skeleton, a thioindigo coloring agent skeleton, an isoindrin coloring agent skeleton, a isoindolinone coloring agent skeleton, a quinophthalone coloring agent skeleton, a dithiol coloring agent skeleton, a triarylmethane coloring agent skeleton, and a pyrromethene coloring agent skeleton. Examples of the acid group include a sulfo group, a carboxyl group, a phosphoric acid group, and a salt thereof. Examples of an atom or atomic group constituting the salts include alkali metal ions (Li⁺, Na⁺, K⁺, and the like), alkaline earth metal ions (Ca²⁺, Mg²⁺, and the like), an ammonium ion, an imidazolium ion, a pyridinium ion, and a phosphonium ion. Examples of the basic group included in the pigment derivative include an amino group, a pyridinyl group, or a salt thereof, a salt of an ammonium group, and a phthalimidomethyl group. Examples of an atom or atomic group constituting the salts include a hydroxide ion, a halogen ion, a carboxylate ion, a sulfonate ion, and a phenoxide ion.

As the pigment derivative, a pigment derivative having excellent visible transparency (hereinafter, also referred to as a transparent pigment derivative) can be contained. The maximum value (εmax) of a molar absorption coefficient of the transparent pigment derivative in a wavelength range of 400 to 700 nm is preferably 3000 L·mol⁻¹·cm⁻¹ or less, more preferably 1000 L·mol⁻¹·cm⁻¹ or less, and still more preferably 100 L·mol⁻¹·cm⁻¹ or less. The lower limit of εmax is, for example, 1 L·mol⁻¹·cm⁻¹ or more and may be 10 L·mol⁻¹·cm⁻¹ or more.

Specific examples of the pigment derivative include compounds described in Example described later and compounds described in JP1981-118462A (JP-S56-118462A), JP1988-264674A (JP-S63-264674A), JP1989-217077A (JP-H01-217077A), JP1991-009961A (JP-H03-009961A), JP1991-026767A (JP-H03-026767A), JP1991-153780A (JP-H03-153780A), JP1991-045662A (JP-H03-045662A), JP1992-285669A (JP-H04-285669A), JP1994-145546A (JP-H06-145546A), JP1994-212088A (JP-H06-212088A), JP1994-240158A (JP-H06-240158A), JP1998-030063A (JP-H10-030063A), JP1998-195326A (JP-H10-195326A), paragraph Nos. 0086 to 0098 of WO2011/024896A, paragraph Nos. 0063 to 0094 of WO2012/102399A, paragraph No. 0082 of WO2017/038252A, paragraph No. 0171 of JP2015-151530A, paragraph Nos. 0162 to 0183 of JP2011-252065A, JP2003-081972A, JP5299151B, JP2015-172732A, JP2014-199308A, JP2014-085562A, JP2014-035351A, and JP2008-081565A.

A content of the pigment derivative is preferably 1 to 30 parts by mass, more preferably 3 to 25 parts by mass, and still more preferably 5 to 20 parts by mass with respect to 100 parts by mass of the pigment. The pigment derivative may be used singly or in a combination of two or more kinds thereof. In a case where two or more kinds thereof are used in combination, the total amount thereof is preferably within the above-described range.

The composition for forming a pixel preferably contains a polymerizable compound. Examples of the polymerizable compound include the polymerizable compound described above as being contained in the above-described composition for forming an underlayer film, and a compound having an ethylenically unsaturated bond-containing group is preferable. In addition, it is also preferable to use a compound having an ethylenically unsaturated bond-containing group and a compound having a cyclic ether group in combination. A content of the polymerizable compound in the total solid content of the composition for forming a pixel is preferably 0.1% to 50% by mass. The lower limit is preferably 0.5% by mass or more and more preferably 1% by mass or more. The upper limit is preferably 40% by mass or less and more preferably 30% by mass or less. The polymerizable compound contained in the composition for forming a pixel may be used singly or in a combination of two or more kinds thereof. In a case where the composition for forming a pixel contains two or more kinds of polymerizable compounds, it is preferable that the total amount thereof is within the above-described range.

The composition for forming a pixel preferably contains a photopolymerization initiator. Examples of the photopolymerization initiator include the photopolymerization initiator described above as being contained in the above-described composition for forming an underlayer film, and a preferred range thereof is also the same. A content of the photopolymerization initiator in the total solid content of the composition for forming a pixel is preferably 0.1% to 30% by mass, more preferably 0.5% to 20% by mass, and still more preferably 1% to 15% by mass. The photopolymerization initiator contained in the composition for forming a pixel may be used singly or in a combination of two or more kinds thereof. In a case where the composition for forming a pixel contains two or more kinds of photopolymerization initiators, it is preferable that the total amount thereof is within the above-described range.

The composition for forming a pixel preferably contains a resin. The resin is blended in, for example, an application for dispersing particles such as the pigment in the composition for forming a pixel or an application as a binder. Mainly, a resin which is used for dispersing particles such as a pigment is also referred to as a dispersant. However, such applications of the resin are only exemplary, and the resin can also be used for other purposes in addition to such applications.

A weight-average molecular weight (Mw) of the resin is preferably 3000 to 2000000. The upper limit is preferably 1000000 or less and more preferably 500000 or less. The lower limit is preferably 4000 or more and more preferably 5000 or more.

Examples of the resin include a (meth)acrylic resin, an ene-thiol resin, a polycarbonate resin, a polyether resin, a polyarylate resin, a polysulfone resin, a polyethersulfone resin, a polyphenylene resin, a polyarylene ether phosphine oxide resin, a polyimide resin, a polyamidoimide resin, a polyolefin resin, a cyclic olefin resin, a polyester resin, and a styrene resin. These resins may be used singly or as a mixture of two or more kinds thereof. In addition, resins described in paragraph Nos. 0041 to 0060 of JP2017-206689A, resins described in paragraph Nos. 0022 to 0071 of JP2018-010856A, resins described in JP2017-057265A, resins described in JP2017-032685A, resins described in JP2017-075248A, and resins described in JP2017-066240A can also be used.

As the resin, it is preferable to use a resin having an acid group. According to this aspect, developability of the composition for forming a pixel can be further improved. Examples of the acid group include a carboxyl group, a phosphoric acid group, a sulfo group, and a phenolic hydroxy group, and a carboxyl group is preferable. The resin having an acid group can be used, for example, as an alkali-soluble resin. The resin having an acid group is preferably a resin including a repeating unit having an acid group in the side chain, and more preferably a resin including 5 to 70 mol% of repeating units having an acid group in the side chain with respect to the total repeating units of the resin. The upper limit of the content of the repeating unit having an acid group in the side chain is still more preferably 50 mol% or less and particularly preferably 30 mol% or less. The lower limit of the content of the repeating unit having an acid group in the side chain is still more preferably 10 mol% or more and particularly preferably 20 mol% or more. With regard to the resin having an acid group, reference can be made to the description in paragraph Nos. 0558 to 0571 of JP2012-208494A (paragraph Nos. 0685 to 0700 of the corresponding US2012/0235099A) and the description in paragraph Nos. 0076 to 0099 of JP2012-198408A, the contents of which are incorporated herein by reference. In addition, as the resin having an acid group, a commercially available product may also be used.

In addition, it is also preferable to use a resin having an ethylenically unsaturated bond-containing group as the resin.

In addition, a resin as a dispersant can also be used as the resin. Examples of the dispersant include an acidic dispersant (acidic resin) and a basic dispersant (basic resin). Here, the acidic dispersant (acidic resin) represents a resin in which the amount of the acid group is larger than the amount of the basic group. The acidic dispersant (acidic resin) is preferably a resin in which the amount of the acid group occupies 70 mol% or more in a case where the total amount of the acid group and the basic group is 100 mol%, and more preferably a resin substantially consisting of only an acid group. The acid group included in the acidic dispersant (acidic resin) is preferably a carboxyl group. The acid value of the acidic dispersant (acidic resin) is preferably 40 to 105 mgKOH/g, more preferably 50 to 105 mgKOH/g, and still more preferably 60 to 105 mgKOH/g. In addition, the basic dispersant (basic resin) represents a resin in which the amount of the basic group is larger than the amount of the acid group. The basic dispersant (basic resin) is preferably a resin in which the amount of the basic group is more than 50 mol% in a case where the total amount of the acid group and the basic group is 100 mol%. The basic group included in the basic dispersant is preferably an amino group. In addition, it is also preferable that the resin used as a dispersant is a graft resin. Examples of the graft resin include resins described in paragraph Nos. 0025 to 0094 of JP2012-255128A, the contents of which are incorporated herein by reference. In addition, it is also preferable that the resin used as a dispersant is a polyimine-based dispersant including a nitrogen atom in at least one of the main chain or the side chain. As the polyimine-based dispersant, a resin having a main chain which has a partial structure having a functional group of pKa 14 or less, and a side chain which has 40 to 10000 atoms, in which at least one of the main chain or the side chain has a basic nitrogen atom, is preferable. The basic nitrogen atom is not particularly limited as long as it is a nitrogen atom exhibiting basicity. Examples of the polyimine-based dispersant include resins described in paragraph Nos. 0102 to 0166 of JP2012-255128A, the contents of which are incorporated herein by reference. In addition, it is also preferable that the resin used as a dispersant is a resin having a structure in which a plurality of polymer chains are bonded to a core portion. Examples of such a resin include dendrimers (including star polymers). In addition, specific examples of the dendrimer include polymer compounds C-1 to C-31 described in paragraph Nos. 0196 to 0209 of JP2013-043962A. In addition, as the dispersant, polyethyleneimine having a polyester side chain, described in WO2016/104803A, a block copolymer described in WO2019/125940A, a block polymer having an acrylamide structural unit, described in JP2020-066687A, a block polymer having an acrylamide structural unit, described in JP2020-066688A, or the like can also be used. A commercially available product is also available as the dispersant, and specific examples thereof include DISPERBYK series (for example, DISPERBYK-111, 161, and the like) manufactured by BYK Chemie, and Solsperse series (for example, Solsperse 76500) manufactured by Lubrizol Corporation. Dispersing agents described in paragraph Nos. 0041 to 0130 of JP2014-130338A can also be used, the contents of which are incorporated herein by reference. The resin described as a dispersant can be used for an application other than the dispersant. For example, the resin can also be used as a binder.

A content of the resin in the total solid content of the composition for forming a pixel is preferably 1% to 50% by mass. The lower limit is more preferably 5% by mass or more and still more preferably 10% by mass or more. The upper limit is more preferably 40% by mass or less and still more preferably 30% by mass or less. The resin contained in the composition for forming a pixel may be used singly or in a combination of two or more kinds thereof. In a case where the composition for forming a pixel contains two or more kinds of resins, it is preferable that the total amount thereof is within the above-described range.

The composition for forming a pixel preferably contains a solvent. Examples of the solvent include the solvent described above as being contained in the above-described composition for forming an underlayer film, and a preferred range thereof is also the same. A content of the solvent in the composition for forming a pixel is preferably 10% to 95% by mass, more preferably 20% to 90% by mass, and still more preferably 30% to 90% by mass. The solvent contained in the composition for forming a pixel may be used singly or in a combination of two or more kinds thereof. In a case where the composition for forming a pixel contains two or more kinds of solvents, it is preferable that the total amount thereof is within the above-described range.

The composition for forming a pixel can contain a surfactant. Examples of the surfactant include the surfactant described above as being contained in the above-described composition for forming an underlayer film, and a preferred range thereof is also the same. A content of the surfactant in the total solid content of the composition for forming a pixel is preferably 0.001% by mass to 5.0% by mass and more preferably 0.005% to 3.0% by mass. The surfactant contained in the composition for forming a pixel may be used singly or in a combination of two or more kinds thereof. In a case where the composition for forming a pixel contains two or more kinds of surfactants, it is preferable that the total amount thereof is within the above-described range.

The composition for forming a pixel can contain a polymerization inhibitor. Examples of the polymerization inhibitor include the polymerization inhibitor described above as being contained in the above-described composition for forming an underlayer film, and a preferred range thereof is also the same. A content of the polymerization inhibitor in the total solid content of the composition for forming a pixel is preferably 0.0001% to 5% by mass. The polymerization inhibitor contained in the composition for forming a pixel may be used singly or in a combination of two or more kinds thereof. In a case where the composition for forming a pixel contains two or more kinds of polymerization inhibitors, it is preferable that the total amount thereof is within the above-described range.

The composition for forming a pixel can contain an ultraviolet absorber. As the ultraviolet absorber, a conjugated diene compound, an aminodiene compound, a salicylate compound, a benzophenone compound, a benzotriazole compound, an acrylonitrile compound, a hydroxyphenyltriazine compound, an indole compound, a triazine compound, or the like can be used. Examples of such a compound include compounds described in paragraph Nos. 0038 to 0052 of JP2009-217221A, paragraph Nos. 0052 to 0072 of JP2012-208374A, paragraph Nos. 0317 to 0334 of JP2013-068814A, and paragraph Nos. 0061 to 0080 of JP2016-162946A, the contents of which are incorporated herein by reference. Examples of a commercially available product of the ultraviolet absorber include UV-503 (manufactured by Daito Chemical Co., Ltd). In addition, examples of the benzotriazole compound include MYUA series manufactured by Miyoshi Oil & Fat Co., Ltd. (The Chemical Daily, Feb. 1, 2016). In addition, as the ultraviolet absorber, compounds described in paragraph Nos. 0049 to 0059 of JP6268967B can also be used. A content of the ultraviolet absorber in the total solid content of the composition for forming a pixel is preferably 0.01% to 10% by mass and more preferably 0.01% to 5% by mass. The ultraviolet absorber contained in the composition for forming a pixel may be used singly or in a combination of two or more kinds thereof. In a case where the composition for forming a pixel contains two or more kinds of ultraviolet absorbers, it is preferable that the total amount thereof is within the above-described range.

The composition for forming a pixel can contain a silane coupling agent. In the present invention, the silane coupling agent means a silane compound having a hydrolyzable group and other functional groups. In addition, the hydrolyzable group refers to a substituent directly linked to a silicon atom and capable of forming a siloxane bond due to at least one of a hydrolysis reaction or a condensation reaction. Examples of the hydrolyzable group include a halogen atom, an alkoxy group, and an acyloxy group, and an alkoxy group is preferable. That is, it is preferable that the silane coupling agent is a compound having an alkoxysilyl group. Examples of the functional group other than the hydrolyzable group include a vinyl group, a (meth)allyl group, a (meth)acryloyl group, a mercapto group, an epoxy group, an oxetanyl group, an amino group, a ureido group, a sulfide group, an isocyanate group, and a phenyl group, and an amino group, a (meth)acryloyl group, or an epoxy group is preferable. Specific examples of the silane coupling agent include the compounds described in paragraph Nos. 0018 to 0036 of JP2009-288703A and the compounds described in paragraph Nos. 0056 to 0066 of JP2009-242604A, the contents of which are incorporated herein by reference. A content of the silane coupling agent in the total solid content of the composition for forming a pixel is preferably 0.1% to 5% by mass. The upper limit is preferably 3% by mass or less and more preferably 2% by mass or less. The lower limit is preferably 0.5% by mass or more and more preferably 1% by mass or more. The silane coupling agent contained in the composition for forming a pixel may be used singly or in a combination of two or more kinds thereof. In a case where the composition for forming a pixel contains two or more kinds of silane coupling agents, the total amount thereof is preferably within the range.

Optionally, the composition for forming a pixel may further contain an antioxidant, a sensitizer, a curing accelerator, a filler, a thermal curing accelerator, a plasticizer, and other auxiliary agents (for example, conductive particles, an antifoaming agent, a flame retardant, a leveling agent, a peeling accelerator, an aromatic chemical, a surface tension adjuster, or a chain transfer agent). By appropriately containing these components, properties such as film properties can be adjusted. The details of the components can be found in, for example, paragraph No. 0183 of JP2012-003225A (corresponding to paragraph No. 0237 of US2013/0034812A) and paragraph Nos. 0101 to 0104 and 0107 to 0109 of JP2008-250074A, the contents of which are incorporated herein by reference. In addition, optionally, the composition for forming a pixel may contain a potential antioxidant. Examples of the potential antioxidant include a compound in which a site functioning as an antioxidant is protected by a protective group, and the protective group is eliminated by heating the compound at 100° C. to 250° C. or heating the compound at 80° C. to 200° C. in the presence of an acid or base catalyst so that the compound functions as an antioxidant. Examples of the potential antioxidant include compounds described in WO2014/021023A, WO2017/030005A, and JP2017-008219A. Examples of a commercially available product of the potential antioxidant include ADEKAARKLS GPA-5001 (manufactured by ADEKA Corporation).

### Solid-State Imaging Element

The solid-state imaging element according to an embodiment of the present invention includes the above-described color filter according to the embodiment of the present invention. The configuration of the solid-state imaging element is not particularly limited as long as the solid-state imaging element is configured to include the color filter according to the embodiment of the present invention and functions as a solid-state imaging element. Examples of the configuration include the following configurations.

The solid-state imaging element is configured to have a plurality of photodiodes constituting a light receiving area of the solid-state imaging element (a charge coupled device (CCD) image sensor, a complementary metal-oxide semiconductor (CMOS) image sensor, or the like), and a transfer electrode formed of polysilicon or the like on a substrate; have a light-shielding film having openings only over the light receiving section of the photodiodes on the photodiodes and the transfer electrodes; have a device-protective film formed of silicon nitride or the like, which is formed to coat the entire surface of the light-shielding film and the light receiving section of the photodiodes, on the light-shielding film; and have a color filter on the device-protective film. Furthermore, the solid-state imaging element may also be configured, for example, such that it has a light collecting unit (for example, a microlens, which is the same hereinafter) on a device-protective film under a color filter (a side closer to the substrate), or has a light collecting unit on a color filter. In addition, as described in JP2019-211559A, an ultraviolet absorbing layer may be provided in the structure of the solid-state imaging element to improve light resistance. An imaging device including the solid-state imaging element according to the embodiment of the present invention can also be used as a vehicle camera or a surveillance camera, in addition to a digital camera or electronic apparatus (mobile phones or the like) having an imaging function.

### Image Display Device

The image display device according to an embodiment of the present invention includes the above-described color filter according to the embodiment of the present invention. Examples of the image display device include a liquid crystal display device or an organic electroluminescent display device. The definitions of image display devices or the details of the respective image display devices are described in, for example, “Electronic Display Device (Akio Sasaki, Kogyo Chosakai Publishing Co., Ltd., published in 1990)”, “Display Device (Sumiaki Ibuki, Sangyo Tosho Co., Ltd.)”, and the like. In addition, the liquid crystal display device is described in, for example, “Liquid Crystal Display Technology for Next Generation (edited by Tatsuo Uchida, Kogyo Chosakai Publishing Co., Ltd., published in 1994)”. The liquid crystal display device to which the present invention can be applied is not particularly limited, and can be applied to, for example, liquid crystal display devices employing various systems described in the “Liquid Crystal Display Technology for Next Generation”.

### EXAMPLES

Hereinafter, the present invention will be described in more detail with reference to Examples. The materials, the amounts of materials to be used, the proportions, the treatment details, the treatment procedure, or the like shown in the examples below may be modified appropriately as long as the modifications do not depart from the spirit of the present invention. Therefore, the scope of the present invention is not limited to the specific examples shown below.

### Production of Composition for Forming Underlayer Film

Each material was mixed at a proportion of Formulations 1 to 5 shown below, and the obtained mixture was filtered through a nylon filter (manufactured by Pall Corporation) having a pore size of 0.45 µm to produce each composition for forming an underlayer film. The total of the resin, the polymerizable compound, the photopolymerization initiator, the surfactant, and the polymerization inhibitor is a value expressed in terms of solid contents.

| (Formulation 1) | |
|---|---|
| Total of resin, polymerizable compound, photopolymerization initiator, surfactant, | |
| and polymerization inhibitor | ··· 0.3 parts by mass |
| Solvent | ··· 99.7 parts by mass |
| (Formulation 2) | |
| Total of resin, polymerizable compound, photopolymerization initiator, surfactant, | |
| and polymerization inhibitor | ··· 0.1 parts by mass |
| Solvent | ··· 99.9 parts by mass |
| Total of resin, polymerizable compound, photopolymerization initiator, surfactant, | |
| and polymerization inhibitor | ··· 0.5 parts by mass |
| Solvent | ··· 99.5 parts by mass |
| Total of resin, polymerizable compound, photopolymerization initiator, surfactant, | |
| and polymerization inhibitor | ··· 0.7 parts by mass |
| Solvent | ··· 99.3 parts by mass |
| Total of resin, polymerizable compound, photopolymerization initiator, surfactant, | |
| and polymerization inhibitor | ··· 0.9 parts by mass |
| Solvent | ··· 99.1 parts by mass |

TABLE 1

| | Type of formulation | Resin | | | | Polymerizable compound | | | |
|---|---|---|---|---|---|---|---|---|---|
| | | Type | | Concentration in solid content (% by mass) | | Type | | Concentration in solid content (% by mass) | |
| | | Resin 1 | Resin 2 | Resin 1 | Resin 2 | Polymerizable compound 1 | Polymerizable compound 2 | Polymerizable compound 1 | Polymerizable compound 2 |
| Composition for forming underlayer film 1 | Formulation 1 | U-1 | - | 89.99 | - | M-1 | - | 10 | - |
| Composition for forming underlayer film 2 | Formulation 1 | U-2 | - | 89.99 | - | M-1 | - | 10 | - |
| Composition for forming underlayer film 3 | Formulation 1 | U-3 | - | 89.99 | - | M-1 | - | 10 | - |
| Composition for forming underlayer film 4 | Formulation 1 | U-4 | - | 89.99 | - | M-1 | - | 10 | - |
| Composition for forming underlayer film 5 | Formulation 1 | U-5 | - | 89.99 | - | M-1 | - | 10 | - |
| Composition for forming underlayer film 6 | Formulation 1 | U-6 | - | 89.99 | - | M-1 | - | 10 | - |
| Composition for forming underlayer film 7 | Formulation 1 | U-7 | - | 89.99 | - | M-1 | - | 10 | - |
| Composition for forming underlayer film 8 | Formulation 1 | U-8 | - | 89.99 | - | M-1 | - | 10 | - |
| Composition for forming underlayer film 9 | Formulation 1 | U-9 | - | 89.99 | - | M-1 | - | 10 | - |
| Composition for forming underlayer film 10 | Formulation 1 | U-10 | - | 89.99 | - | M-1 | - | 10 | - |
| Composition for forming underlayer film 11 | Formulation 1 | U-11 | - | 89.99 | - | M-1 | - | 10 | - |
| Composition for forming underlayer film 12 | Formulation 1 | U-12 | - | 89.99 | - | M-1 | - | 10 | - |
| Composition for forming underlayer film 13 | Formulation 1 | U-13 | - | 89.99 | - | M-1 | - | 10 | - |
| Composition for forming underlayer film 14 | Formulation 1 | U-14 | - | 89.99 | - | M-1 | - | 10 | - |
| Composition for forming underlayer film 15 | Formulation 1 | U-15 | - | 89.99 | - | M-1 | - | 10 | - |
| Composition for forming underlayer film 16 | Formulation 1 | U-16 | - | 89.99 | - | M-1 | - | 10 | - |
| Composition for forming underlayer film 17 | Formulation 1 | U-17 | - | 89.99 | - | M-1 | - | 10 | - |
| Composition for forming underlayer film 18 | Formulation 1 | U-1 | - | 99.99 | - | - | - | - | - |
| Composition for forming underlayer film 19 | Formulation 1 | U-7 | - | 99.99 | - | - | - | - | - |
| Composition for forming underlayer film 20 | Formulation 1 | U-8 | - | 99.99 | - | - | - | - | - |
| Composition for forming underlayer film 21 | Formulation 1 | U-9 | - | 99.99 | - | - | - | - | - |
| Composition for forming underlayer film 22 | Formulation 1 | U-10 | - | 99.99 | - | - | - | - | - |
| Composition for forming underlayer film 23 | Formulation 1 | U-11 | - | 99.99 | - | - | - | - | - |
| Composition for forming underlayer film 24 | Formulation 1 | U-12 | - | 99.99 | - | - | - | - | - |
| Composition for forming underlayer film 25 | Formulation 1 | U-13 | - | 99.99 | - | - | - | - | - |
| Composition for forming underlayer film 26 | Formulation 1 | U-14 | - | 99.99 | - | - | - | - | - |
| Composition for forming underlayer film 27 | Formulation 1 | U-15 | - | 99.99 | - | - | - | - | - |
| Composition for forming underlayer film 28 | Formulation 1 | U-16 | - | 99.99 | - | - | - | - | - |
| Composition for forming underlayer film 29 | Formulation 1 | U-17 | - | 99.99 | - | - | - | - | - |
| Composition for forming underlayer film 30 | Formulation 1 | U-6 | - | 54.99 | - | M-1 | - | 45 | - |
| Composition for forming underlayer film 31 | Formulation 1 | U-6 | - | 74.99 | - | M-1 | - | 25 | - |
| Composition for forming underlayer film 32 | Formulation 1 | U-6 | - | 94.99 | - | M-1 | - | 5 | - |
| Composition for forming underlayer film 33 | Formulation 1 | U-6 | - | 74.99 | - | M-2 | - | 25 | - |
| Composition for forming underlayer film 34 | Formulation 1 | U-6 | - | 74.99 | - | M-3 | - | 25 | - |
| Composition for forming underlayer film 35 | Formulation 1 | U-6 | - | 74.99 | - | M-4 | - | 25 | - |
| Composition for forming underlayer film 36 | Formulation 1 | U-6 | - | 74.99 | - | M-5 | - | 25 | - |
| Composition for forming underlayer film 37 | Formulation 1 | U-6 | - | 74.99 | - | M-1 | M-3 | 15 | 10 |
| Composition for forming underlayer film 38 | Formulation 1 | U-6 | - | 74.99 | - | M-1 | M-4 | 15 | 10 |
| Composition for forming underlayer film 39 | Formulation 1 | U-6 | - | 74.99 | - | M-1 | M-5 | 15 | 10 |
| Composition for forming underlayer film 40 | Formulation 1 | U-6 | - | 74.99 | - | M-1 | M-3 | 10 | 10 |
| Composition for forming underlayer film 41 | Formulation 1 | U-6 | - | 74.99 | - | M-1 | M-4 | 10 | 10 |
| Composition for forming underlayer film 42 | Formulation 1 | U-6 | U-11 | 69.99 | 20 | M-1 | - | 10 | - |
| Composition for forming underlayer film 43 | Formulation 1 | U-6 | U-13 | 69.99 | 20 | M-1 | - | 10 | - |
| Composition for forming underlayer film 44 | Formulation 1 | U-6 | U-15 | 69.99 | 20 | M-1 | - | 10 | - |
| Composition for forming underlayer film 45 | Formulation 1 | U-6 | U-16 | 69.99 | 20 | M-1 | - | 10 | - |

TABLE 2

| | Photopolymerization initiator | | | | Surfactant | |
|---|---|---|---|---|---|---|
| | Type | | Concentration in solid content (% by mass) | | Type | Concentration in solid content (% by mass) |
| | Photo polymerization initiator 1 | Photo polymerization initiator 2 | Photo polymerization initiator 1 | Photo polymerization initiator 2 | | |
| Composition for forming underlayer film 1 | - | - | - | - | - | - |
| Composition for forming underlayer film 2 | - | - | - | - | - | - |
| Composition for forming underlayer film 3 | - | - | - | - | - | - |
| Composition for forming underlayer film 4 | - | - | - | - | - | - |
| Composition for forming underlayer film 5 | - | - | - | - | - | - |
| Composition for forming underlayer film 6 | - | - | - | - | - | - |
| Composition for forming underlayer film 7 | - | - | - | - | - | - |
| Composition for forming underlayer film 8 | - | - | - | - | - | - |
| Composition for forming underlayer film 9 | - | - | - | - | - | - |
| Composition for forming underlayer film 10 | - | - | - | - | - | - |
| Composition for forming underlayer film 11 | - | - | - | - | - | - |
| Composition for forming underlayer film 12 | - | - | - | - | - | - |
| Composition for forming underlayer film 13 | - | - | - | - | - | - |
| Composition for forming underlayer film 14 | - | - | - | - | - | - |
| Composition for forming underlayer film 15 | - | - | - | - | - | - |
| Composition for forming underlayer film 16 | - | - | - | - | - | - |
| Composition for forming underlayer film 17 | - | - | - | - | - | - |
| Composition for forming underlayer film 18 | - | - | - | - | - | - |
| Composition for forming underlayer film 19 | - | - | - | - | - | - |
| Composition for forming underlayer film 20 | - | - | - | - | - | - |
| Composition for forming underlayer film 21 | - | - | - | - | - | - |
| Composition for forming underlayer film 22 | - | - | - | - | - | - |
| Composition for forming underlayer film 23 | - | - | - | - | - | - |
| Composition for forming underlayer film 24 | - | - | - | - | - | - |
| Composition for forming underlayer film 25 | - | - | - | - | - | - |
| Composition for forming underlayer film 26 | - | - | - | - | - | - |
| Composition for forming underlayer film 27 | - | - | - | - | - | - |
| Composition for forming underlayer film 28 | - | - | - | - | - | - |
| Composition for forming underlayer film 29 | - | - | - | - | - | - |
| Composition for forming underlayer film 30 | - | - | - | - | - | - |
| Composition for forming underlayer film 31 | - | - | - | - | - | - |
| Composition for forming underlayer film 32 | - | - | - | - | - | - |
| Composition for forming underlayer film 33 | - | - | - | - | - | - |
| Composition for forming underlayer film 34 | - | - | - | - | - | - |
| Composition for forming underlayer film 35 | - | - | - | - | - | - |
| Composition for forming underlayer film 36 | - | - | - | - | - | - |
| Composition for forming underlayer film 37 | - | - | - | - | - | - |
| Composition for forming underlayer film 38 | - | - | - | - | - | - |
| Composition for forming underlayer film 39 | - | - | - | - | - | - |
| Composition for forming underlayer film 40 | I-1 | 1-2 | 3 | 2 | - | - |
| Composition for forming underlayer film 41 | I-1 | 1-3 | 3 | 2 | - | - |
| Composition for forming underlayer film 42 | - | - | - | - | - | - |
| Composition for forming underlayer film 43 | - | - | - | - | - | - |
| Composition for forming underlayer film 44 | - | - | - | - | - | - |
| Composition for forming underlayer film 45 | - | - | - | - | - | - |

TABLE 3

| | Polymerization inhibitor | | Solvent | | | |
|---|---|---|---|---|---|---|
| | Type | Concentration in solid content(% by mass) | Type | | Mixing ratio (mass ratio) | |
| | | | Solvent 1 | Solvent 2 | Solvent 1 | Solvent 2 |
| Composition for forming underlayer film 1 | In-1 | 0.01 | S-1 | - | 100 | - |
| Composition for forming underlayer film 2 | In-1 | 0.01 | S-1 | - | 100 | - |
| Composition for forming underlayer film 3 | In-1 | 0.01 | S-1 | - | 100 | - |
| Composition for forming underlayer film 4 | In-1 | 0.01 | S-1 | - | 100 | - |
| Composition for forming underlayer film 5 | In-1 | 0.01 | S-1 | - | 100 | - |
| Composition for forming underlayer film 6 | In-1 | 0.01 | S-1 | - | 100 | - |
| Composition for forming underlayer film 7 | In-1 | 0.01 | S-1 | - | 100 | - |
| Composition for forming underlayer film 8 | In-1 | 0.01 | S-1 | - | 100 | - |
| Composition for forming underlayer film 9 | In-1 | 0.01 | S-1 | - | 100 | - |
| Composition for forming underlayer film 10 | In-1 | 0.01 | S-1 | - | 100 | - |
| Composition for forming underlayer film 11 | In-1 | 0.01 | S-1 | - | 100 | - |
| Composition for forming underlayer film 12 | In-1 | 0.01 | S-1 | - | 100 | - |
| Composition for forming underlayer film 13 | In-1 | 0.01 | S-1 | - | 100 | - |
| Composition for forming underlayer film 14 | In-1 | 0.01 | S-1 | - | 100 | - |
| Composition for forming underlayer film 15 | In-1 | 0.01 | S-1 | - | 100 | - |
| Composition for forming underlayer film 16 | In-1 | 0.01 | S-1 | - | 100 | - |
| Composition for forming underlayer film 17 | In-1 | 0.01 | S-1 | - | 100 | - |
| Composition for forming underlayer film 18 | In-1 | 0.01 | S-1 | - | 100 | - |
| Composition for forming underlayer film 19 | In-1 | 0.01 | S-1 | - | 100 | - |
| Composition for forming underlayer film 20 | In-1 | 0.01 | S-1 | - | 100 | - |
| Composition for forming underlayer film 21 | In-1 | 0.01 | S-1 | - | 100 | - |
| Composition for forming underlayer film 22 | In-1 | 0.01 | S-1 | - | 100 | - |
| Composition for forming underlayer film 23 | In-1 | 0.01 | S-1 | - | 100 | - |
| Composition for forming underlayer film 24 | In-1 | 0.01 | S-1 | - | 100 | - |
| Composition for forming underlayer film 25 | In-1 | 0.01 | S-1 | - | 100 | - |
| Composition for forming underlayer film 26 | In-1 | 0.01 | S-1 | - | 100 | - |
| Composition for forming underlayer film 27 | In-1 | 0.01 | S-1 | - | 100 | - |
| Composition for forming underlayer film 28 | In-1 | 0.01 | S-1 | - | 100 | - |
| Composition for forming underlayer film 29 | In-1 | 0.01 | S-1 | - | 100 | - |
| Composition for forming underlayer film 30 | In-1 | 0.01 | S-1 | - | 100 | - |
| Composition for forming underlayer film 31 | In-1 | 0.01 | S-1 | - | 100 | - |
| Composition for forming underlayer film 32 | In-1 | 0.01 | S-1 | - | 100 | - |
| Composition for forming underlayer film 33 | In-1 | 0.01 | S-1 | - | 100 | - |
| Composition for forming underlayer film 34 | In-1 | 0.01 | S-1 | - | 100 | - |
| Composition for forming underlayer film 35 | In-1 | 0.01 | S-1 | - | 100 | - |
| Composition for forming underlayer film 36 | In-1 | 0.01 | S-1 | - | 100 | - |
| Composition for forming underlayer film 37 | In-1 | 0.01 | S-1 | - | 100 | - |
| Composition for forming underlayer film 38 | In-1 | 0.01 | S-1 | - | 100 | - |
| Composition for forming underlayer film 39 | In-1 | 0.01 | S-1 | - | 100 | - |
| Composition for forming underlayer film 40 | In-1 | 0.01 | S-1 | - | 100 | - |
| Composition for forming underlayer film 41 | In-1 | 0.01 | S-1 | - | 100 | - |
| Composition for forming underlayer film 42 | In-1 | 0.01 | S-1 | - | 100 | - |
| Composition for forming underlayer film 43 | In-1 | 0.01 | S-1 | - | 100 | - |
| Composition for forming underlayer film 44 | In-1 | 0.01 | S-1 | - | 100 | - |
| Composition for forming underlayer film 45 | In-1 | 0.01 | S-1 | - | 100 | - |

TABLE 4

| | Type of formulation | Resin | | | | Polymerizable compound | | | |
|---|---|---|---|---|---|---|---|---|---|
| | | Type | | Concentration in solid content (% by mass) | | Type | | Concentration in solid content (% by mass) | |
| | | Resin 1 | Resin 2 | Resin 1 | Resin 2 | Polymerizable compound 1 | Polymerizable compound 2 | Polymerizable compound 1 | Polymerizable compound 2 |
| Composition for forming underlayer film 46 | Formulation 1 | U-6 | B-1 | 69.99 | 20 | M-1 | - | 10 | - |
| Composition for forming underlayer film 47 | Formulation 1 | U-6 | B-3 | 69.99 | 20 | M-1 | - | 10 | - |
| Composition for forming underlayer film 48 | Formulation 1 | U-6 | B-5 | 69.99 | 20 | M-1 | - | 10 | - |
| Composition for forming underlayer film 49 | Formulation 1 | U-11 | U-13 | 49.99 | 40 | M-1 | - | 10 | - |
| Composition for forming underlayer film 50 | Formulation 1 | U-11 | U-15 | 49.99 | 40 | M-1 | - | 10 | - |
| Composition for forming underlayer film 51 | Formulation 1 | U-11 | U-16 | 49.99 | 40 | M-1 | - | 10 | - |
| Composition for forming underlayer film 52 | Formulation 1 | U-11 | - | 99.89 | - | - | - | - | - |
| Composition for forming underlayer film 53 | Formulation 1 | U-11 | - | 99.89 | - | - | - | - | - |
| Composition for forming underlayer film 54 | Formulation 1 | U-11 | - | 99.69 | - | - | - | - | - |
| Composition for forming underlayer film 55 | Formulation 1 | U-11 | - | 99.49 | - | - | - | - | - |
| Composition for forming underlayer film 56 | Formulation 1 | U-11 | - | 98.99 | - | - | - | - | - |
| Composition for forming underlayer film 57 | Formulation 1 | U-11 | - | 99.89 | - | - | - | - | - |
| Composition for forming underlayer film 58 | Formulation 1 | U-11 | - | 99.89 | - | - | - | - | - |
| Composition for forming underlayer film 59 | Formulation 1 | U-11 | - | 99.89 | - | - | - | - | - |
| Composition for forming underlayer film 60 | Formulation 1 | U-11 | - | 99.89 | - | - | - | - | - |
| Composition for forming underlayer film 61 | Formulation 1 | U-11 | - | 99.89 | - | - | - | - | - |
| Composition for forming underlayer film 62 | Formulation 1 | U-11 | - | 99.89 | - | - | - | - | - |
| Composition for forming underlayer film 63 | Formulation 1 | U-11 | - | 99.89 | - | - | - | - | - |
| Composition for forming underlayer film 64 | Formulation 1 | U-11 | - | 99.89 | - | - | - | - | - |
| Composition for forming underlayer film 65 | Formulation 1 | U-11 | - | 99.89 | - | - | - | - | - |
| Composition for forming underlayer film 66 | Formulation 1 | U-11 | - | 99.89 | - | - | - | - | - |
| Composition for forming underlayer film 67 | Formulation 2 | U-1 | - | 99.99 | - | - | - | - | - |
| Composition for forming underlayer film 68 | Formulation 3 | U-1 | - | 99.99 | - | - | - | - | - |
| Composition for forming underlayer film 69 | Formulation 4 | U-1 | - | 99.99 | - | - | - | - | - |
| Composition for forming underlayer film 70 | Formulation 5 | U-1 | - | 99.99 | - | - | - | - | - |
| Composition for forming underlayer film 71 | Formulation 1 | U-201 | - | 99.99 | - | - | - | - | - |
| Composition for forming underlayer film 72 | Formulation 1 | U-202 | - | 99.99 | - | - | - | - | - |
| Composition for forming underlayer film 73 | Formulation 1 | U-203 | - | 99.99 | - | - | - | - | - |
| Composition for forming underlayer film 74 | Formulation 1 | U-204 | - | 99.99 | - | - | - | - | - |
| Composition for forming underlayer film 75 | Formulation 1 | U-205 | - | 99.99 | - | - | - | - | - |
| Composition for forming underlayer film 76 | Formulation 1 | U-206 | - | 99.99 | - | - | - | - | - |
| Composition for forming underlayer film 77 | Formulation 1 | U-207 | - | 99.99 | - | - | - | - | - |
| Composition for forming underlayer film 78 | Formulation 1 | U-208 | - | 99.99 | - | - | - | - | - |
| Composition for forming underlayer film 79 | Formulation 1 | U-209 | - | 99.99 | - | - | - | - | - |
| Composition for forming underlayer film 80 | Formulation 1 | U-210 | - | 99.99 | - | - | - | - | - |
| Composition for forming underlayer film r1 | Formulation 1 | U-r1 | - | 89.99 | - | M-1 | - | 10 | - |

TABLE 5

| | Photopolymerization initiator | | | | Surfactant | |
|---|---|---|---|---|---|---|
| | Type | | Concentration in solid content (% by mass) | | Type | Concentration in solid content (% by mass) |
| | Photo polymerization initiator 1 | Photo polymerization initiator 2 | Photo polymerization initiator 1 | Photo polymerization initiator 2 | | |
| Composition for forming underlayer film 46 | - | - | - | - | - | - |
| Composition for forming underlayer film 47 | - | - | - | - | - | - |
| Composition for forming underlayer film 48 | - | - | - | - | - | - |
| Composition for forming underlayer film 49 | - | - | - | - | - | - |
| Composition for forming underlayer film 50 | - | - | - | - | - | - |
| Composition for forming underlayer film 51 | - | - | - | - | - | - |
| Composition for forming underlayer film 52 | - | - | - | - | W-5 | 0.1 |
| Composition for forming underlayer film 53 | - | - | - | - | W-8 | 0.1 |
| Composition for forming underlayer film 54 | - | - | - | - | W-8 | 0.3 |
| Composition for forming underlayer film 55 | - | - | - | - | W-8 | 0.5 |
| Composition for forming underlayer film 56 | - | - | - | - | W-8 | 1 |
| Composition for forming underlayer film 57 | - | - | - | - | W-5 | 0.1 |
| Composition for forming underlayer film 58 | - | - | - | - | W-5 | 0.1 |
| Composition for forming underlayer film 59 | - | - | - | - | W-5 | 0.1 |
| Composition for forming underlayer film 60 | - | - | - | - | W-5 | 0.1 |
| Composition for forming underlayer film 61 | - | - | - | - | W-5 | 0.1 |
| Composition for forming underlayer film 62 | - | - | - | - | W-5 | 0.1 |
| Composition for forming underlayer film 63 | - | - | - | - | W-5 | 0.1 |
| Composition for forming underlayer film 64 | - | - | - | - | W-5 | 0.1 |
| Composition for forming underlayer film 65 | - | - | - | - | W-5 | 0.1 |
| Composition for forming underlayer film 66 | - | - | - | - | W-5 | 0.1 |
| Composition for forming underlayer film 67 | - | - | - | - | - | - |
| Composition for forming underlayer film 68 | - | - | - | - | - | - |
| Composition for forming underlayer film 69 | - | - | - | - | - | - |
| Composition for forming underlayer film 70 | - | - | - | - | - | - |
| Composition for forming underlayer film 71 | - | - | - | - | - | - |
| Composition for forming underlayer film 72 | - | - | - | - | - | - |
| Composition for forming underlayer film 73 | - | - | - | - | - | - |
| Composition for forming underlayer film 74 | - | - | - | - | - | - |
| Composition for forming underlayer film 75 | - | - | - | - | - | - |
| Composition for forming underlayer film 76 | - | - | - | - | - | - |
| Composition for forming underlayer film 77 | - | - | - | - | - | - |
| Composition for forming underlayer film 78 | - | - | - | - | - | - |
| Composition for forming underlayer film 79 | - | - | - | - | - | - |
| Composition for forming underlayer film 80 | - | - | - | - | - | - |
| Composition for forming underlayer film r1 | - | - | - | - | - | - |

TABLE 6

| | Polymerization inhibitor | | Solvent | | | |
|---|---|---|---|---|---|---|
| | Type | Concentration in solid content(% by mass) | Type | | Mixing ratio (mass ratio) | |
| | | | Solvent 1 | Solvent 2 | Solvent 1 | Solvent 2 |
| Composition for forming underlayer film 46 | In-1 | 0.01 | S-1 | - | 100 | - |
| Composition for forming underlayer film 47 | In-1 | 0.01 | S-1 | - | 100 | - |
| Composition for forming underlayer film 48 | In-1 | 0.01 | S-1 | - | 100 | - |
| Composition for forming underlayer film 49 | In-1 | 0.01 | S-1 | - | 100 | - |
| Composition for forming underlayer film 50 | In-1 | 0.01 | S-1 | - | 100 | - |
| Composition for forming underlayer film 51 | In-1 | 0.01 | S-1 | - | 100 | - |
| Composition for forming underlayer film 52 | In-1 | 0.01 | S-1 | - | 100 | - |
| Composition for forming underlayer film 53 | In-1 | 0.01 | S-1 | - | 100 | - |
| Composition for forming underlayer film 54 | In-1 | 0.01 | S-1 | - | 100 | - |
| Composition for forming underlayer film 55 | In-1 | 0.01 | S-1 | - | 100 | - |
| Composition for forming underlayer film 56 | In-1 | 0.01 | S-1 | - | 100 | - |
| Composition for forming underlayer film 57 | In-1 | 0.01 | S-2 | - | 100 | - |
| Composition for forming underlayer film 58 | In-1 | 0.01 | S-3 | - | 100 | - |
| Composition for forming underlayer film 59 | In-1 | 0.01 | S-4 | - | 100 | - |
| Composition for forming underlayer film 60 | In-1 | 0.01 | S-5 | - | 100 | - |
| Composition for forming underlayer film 61 | In-1 | 0.01 | S-6 | - | 100 | - |
| Composition for forming underlayer film 62 | In-1 | 0.01 | S-1 | S-2 | 70 | 30 |
| Composition for forming underlayer film 63 | In-1 | 0.01 | S-1 | S-3 | 70 | 30 |
| Composition for forming underlayer film 64 | In-1 | 0.01 | S-1 | S-4 | 70 | 30 |
| Composition for forming underlayer film 65 | In-1 | 0.01 | S-1 | S5 | 70 | 30 |
| Composition for forming underlayer film 66 | In-1 | 0.01 | S-1 | S-6 | 70 | 30 |
| Composition for forming underlayer film 67 | In-1 | 0.01 | S-1 | - | 100 | - |
| Composition for forming underlayer film 68 | In-1 | 0.01 | S-1 | - | 100 | - |
| Composition for forming underlayer film 69 | In-1 | 0.01 | S-1 | - | 100 | - |
| Composition for forming underlayer film 70 | In-1 | 0.01 | S-1 | - | 100 | - |
| Composition for forming underlayer film 71 | In-1 | 0.01 | S-1 | - | 100 | - |
| Composition for forming underlayer film 72 | In-1 | 0.01 | S-1 | - | 100 | - |
| Composition for forming underlayer film 73 | In-1 | 0.01 | S-1 | - | 100 | - |
| Composition for forming underlayer film 74 | In-1 | 0.01 | S-1 | - | 100 | - |
| Composition for forming underlayer film 75 | In-1 | 0.01 | S-1 | - | 100 | - |
| Composition for forming underlayer film 76 | In-1 | 0.01 | S-1 | - | 100 | - |
| Composition for forming underlayer film 77 | In-1 | 0.01 | S-1 | - | 100 | - |
| Composition for forming underlayer film 78 | In-1 | 0.01 | S-1 | - | 100 | - |
| Composition for forming underlayer film 79 | In-1 | 0.01 | S-1 | - | 100 | - |
| Composition for forming underlayer film 80 | In-1 | 0.01 | S-1 | - | 100 | - |
| Composition for forming underlayer film r1 | In-1 | 0.01 | S-1 | - | 100 | - |

The materials described in the above tables are as follows.

### (Resin)

TABLE 7

| No. | Structure | | Weight-average molecular weight | Acid value (mgKOH/g) |
|---|---|---|---|---|
| U-1 | 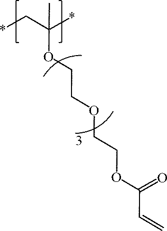 | | 15000 | 0 |
| U-2 | 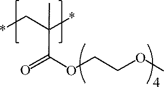 | | 20000 | 0 |
| U-3 | 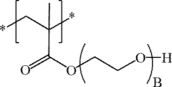 | | 22000 | 0 |
| U-4 | 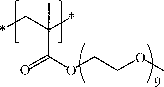 | | 22000 | 0 |
| U-5 | 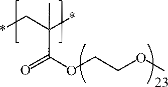 | | 23000 | 0 |
| U-6 | 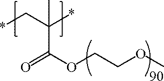 | | 18000 | 0 |
| U-7 | 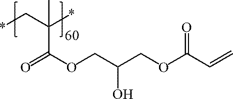 | 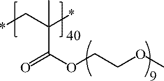 | 26000 | 0 |
| U-8 | 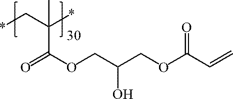 | 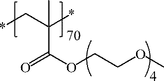 | 24000 | 0 |
| U-9 | 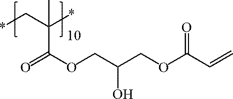 | 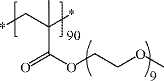 | 26000 | 0 |

TABLE 8

| No. | Structure | | | | Weight-average molecular weight | Acid value (mgKOH/g) |
|---|---|---|---|---|---|---|
| U-10 | 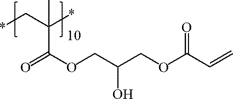 | | 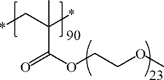 | | 24000 | 0 |
| U-11 | 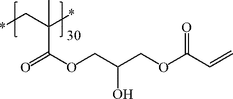 | | 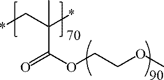 | | 24000 | 0 |
| U-12 | 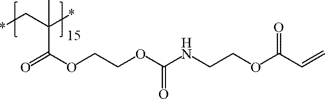 | | | 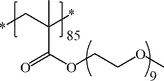 | 26000 | 0 |
| U-13 | 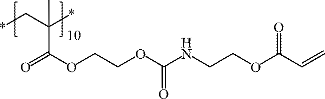 | | | 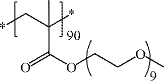 | 26000 | 0 |
| U-14 | 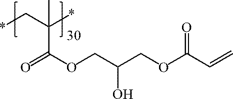 | 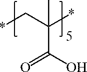 | | 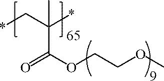 | 24000 | 33 |
| U-15 | 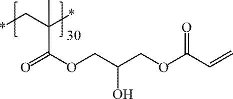 | 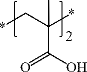 | | 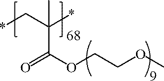 | 24000 | 10 |
| U-16 | 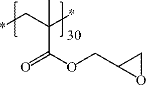 | 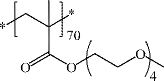 | | | 24000 | 0 |
| U-17 | 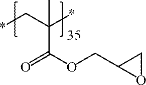 | 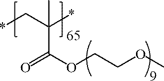 | | | 24000 | 0 |

TABLE 9

| No. | Structure | | | Weight-average molecular weight | Acid value (mgKOH/g) |
|---|---|---|---|---|---|
| U-201 | 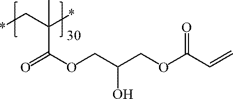 | 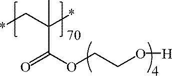 | | 24000 | 0 |
| U-202 | 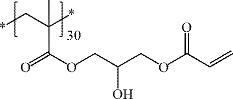 | 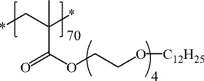 | | 25000 | 0 |
| U-203 | 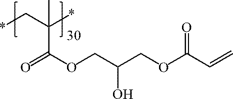 | 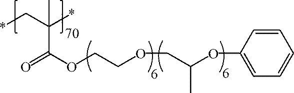 | | 26000 | 0 |
| U-204 | 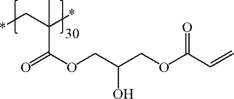 | 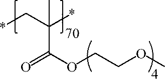 | | 24000 | 0 |
| U-205 | 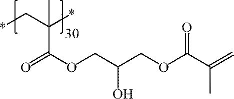 | 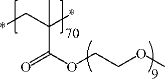 | | 24000 | 0 |
| U-206 | 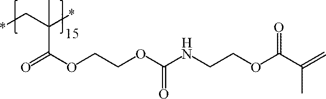 | | 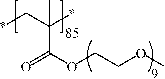 | 26000 | 0 |
| U-207 | 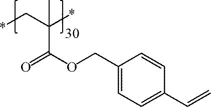 | 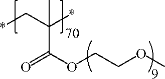 | | 25000 | 0 |
| U-208 | 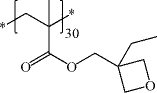 | 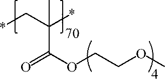 | | 24000 | 0 |
| U-209 | 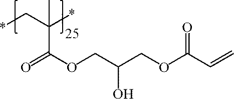 | 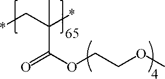 | 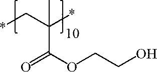 | 25000 | 0 |
| U-210 | 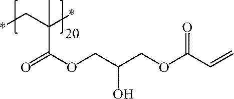 | 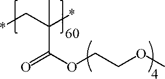 | 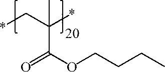 | 25000 | 0 |
| U-r1 | 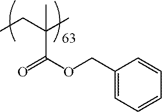 | 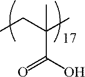 | | 18000 | 113 |

In the structural formulae, the numerical value described together with the main chain indicates a mass ratio, and the numerical value described together with the side chain indicates the number of repeating units.

The amount of halogen in the solid content of the above-described resins was 0.3% by weight in U-7, and was below the detection limit except for U-7.

### (Polymerizable Compound)

M-1: KAYARAD DPHA (manufactured by Nippon Kayaku Co., Ltd.; compound having an ethylenically unsaturated bond-containing group)
M-2: compound having the following structure (compound having an ethylenically unsaturated bond-containing group)

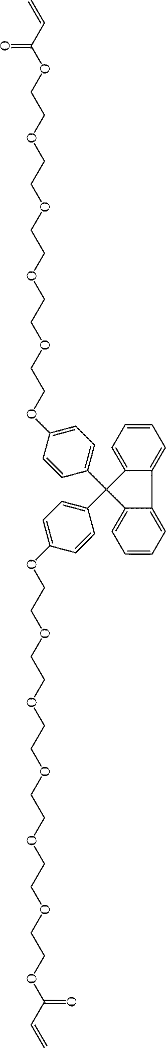 [SMILES: C=CC(=O)OCCOCCOCCOCCOCCOCCOc1ccc(C2(c3ccc(OCCOCCOCCOCCOCCOC(=O)C=C)cc3)c3ccccc3-c3ccccc32)cc1]

M-3: compound having the following structure (compound having an ethylenically unsaturated bond-containing group)

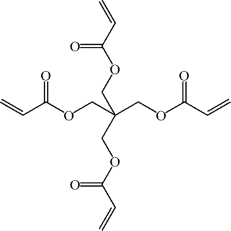 [SMILES: C=CC(=O)OCC(COC(=O)C=C)(COC(=O)C=C)COC(=O)C=C]

M-4: compound having the following structure (compound having an ethylenically unsaturated bond-containing group)

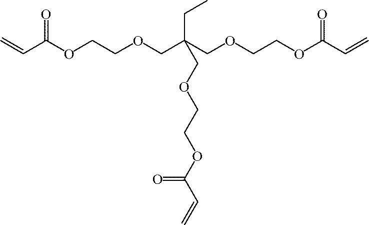 [SMILES: C=CC(=O)OCCOCC(CC)(COCCOC(=O)C=C)COCCOC(=O)C=C]

M-5: JER-1031S (manufactured by Mitsubishi Chemical Corporation; compound having an epoxy group)

### (Photopolymerization Initiator)

I-1: compound having the following structure

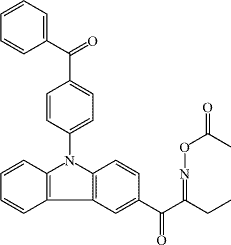 [SMILES: CCC(=NOC(C)=O)C(=O)c1ccc2c(c1)c1ccccc1n2-c1ccc(C(=O)c2ccccc2)cc1]

I-2: Irgacure OXE02 (manufactured by BASF SE, oxime compound)
I-3: Omnirad 2959, Omnirad 127 (manufactured by IGM Resins B.V.)

### (Surfactant)

W-5: BYK-330 (manufactured by BYK Chemie; silicone-based surfactant)
W-8: KF-6001 (Shin-Etsu Chemical Co., Ltd.; silicone-based surfactant)

### (Polymerization Inhibitor)

In-1: p-methoxyphenol

### (Solvent)

S-1: propylene glycol monomethyl ether acetate (PGMEA)
S-2: 3-methylcyclohexanone
S-3: cyclopentanone
S-4: diacetone alcohol
S-5: anisole
S-6: propylene glycol monomethyl ether (PGME)

### Production of Coloring Composition

### -Production of Dispersion Liquid-

A mixed solution of a total of 14.0 parts by mass of a pigment and a pigment derivative, 16.3 parts by mass of a dispersant, and 69.7 parts by mass of a solvent was mixed and dispersed for 3 hours using a beads mill (zirconia beads, 0.1 mm diameter) to prepare a dispersion liquid. Thereafter, using a high-pressure disperser NANO-3000-10 (manufactured by Nippon BEE Chemical Co., Ltd.) equipped with a pressure reducing mechanism, the dispersion liquid was dispersed under a pressure of 2000 kg/cm³ at a flow rate of 500 g/min. The dispersion treatment was repeated up to a total of 10 times to obtain a dispersion liquid. Materials shown in the tables below were used as the pigment, the pigment derivative, the dispersant, and the solvent. In addition, the mixing ratio of each material in the tables below is a value expressed in terms of solid contents.

TABLE 10

| | Pigment and pigment derivative | | | | | | | | | | Dispersant | Solvent | | | |
|---|---|---|---|---|---|---|---|---|---|---|---|---|---|---|---|
| | Type | | | | | Mixing ratio (mass ratio) | | | | | Type | Type | | Mixing ratio (mass ratio) | |
| | Pigment 1 | Pigment 2 | Pigment 3 | Pigment derivative 1 | Pigment derivative 2 | Pigment 1 | Pigment 2 | Pigment 3 | Pigment derivative 1 | Pigment derivative 2 | | Solvent 1 | Solvent 2 | Solvent 1 | Solvent 2 |
| Dispersion liquid G-1 | P-1 | P-3 | - | Syn-1 | - | 0.75 | 0.15 | - | 0.1 | - | B-1 | S-1 | S-2 | 0.7 | 0.3 |
| Dispersion liquid G-2 | P-1 | P-3 | - | Syn-1 | - | 0.75 | 0.15 | - | 0.1 | - | B-1 | S-1 | S-3 | 0.7 | 0.3 |
| Dispersion liquid G-3 | P-2 | P-4 | - | Syn-1 | - | 0.5 | 0.4 | - | 0.1 | - | B-2 | S-1 | S-4 | 0.7 | 0.3 |
| Dispersion liquid G-4 | P-2 | P-4 | - | Syn-1 | - | 0.5 | 0.4 | - | 0.1 | - | B-2 | S-1 | S-5 | 0.7 | 0.3 |
| Dispersion liquid R-1 | P-5 | P-6 | P-7 | Syn-1 | Syn-2 | 0.3 | 0.2 | 0.4 | 0.05 | 0.05 | B-3 | S-1 | S-2 | 0.7 | 0.3 |
| Dispersion liquid R-2 | P-5 | P-6 | P-7 | Syn-1 | Syn-2 | 0.3 | 0.2 | 0.4 | 0.05 | 0.05 | B-3 | S-1 | S-3 | 0.7 | 0.3 |
| Dispersion liquid R-3 | P-6 | P-7 | - | Syn-1 | Syn-2 | 0.5 | 0.4 | - | 0.05 | 0.05 | B-4 | S-1 | S-4 | 0.7 | 0.3 |
| Dispersion liquid R-4 | P-6 | P-7 | - | Syn-1 | Syn-2 | 0.5 | 0.4 | - | 0.05 | 0.05 | B-4 | S-1 | S-5 | 0.7 | 0.3 |
| Dispersion liquid B-1 | P-8 | P-9 | - | Syn-3 | Syn-4 | 0.75 | 0.15 | - | 0.08 | 0.02 | B-2 | S-1 | S-2 | 0.7 | 0.3 |
| Dispersion liquid B-2 | P-8 | P-9 | - | Syn-3 | Syn-4 | 0.75 | 0.15 | - | 0.08 | 0.02 | B-2 | S-1 | S-3 | 0.7 | 0.3 |
| Dispersion liquid B-3 | P-8 | P-9 | - | Syn-3 | Syn-4 | 0.75 | 0.15 | - | 0.08 | 0.02 | B-2 | S-1 | S-4 | 0.7 | 0.3 |
| Dispersion liquid B-4 | P-8 | P-9 | - | Syn-3 | Syn-4 | 0.75 | 0.15 | - | 0.08 | 0.02 | B-2 | S-1 | S-5 | 0.7 | 0.3 |

### (Pigment)

P-1: C. I. Pigment Green 58 (green pigment)
P-2: C. I. Pigment Green 36 (green pigment)
P-3: C. I. Pigment Yellow 185 (yellow pigment)
P-4: C. I. Pigment Yellow 150 (yellow pigment)
P-5: C. I. Pigment Red 272 (red pigment)
P-6: C. I. Pigment Red 254 (red pigment)
P-7: C. I. Pigment Yellow 139 (yellow pigment)
P-8: C. I. Pigment Blue 15:6 (blue pigment)
P-9: C. I. Pigment Violet 23 (violet pigment)

### (Pigment Derivative)

Syn-1 to Syn-4: compounds having the following structures

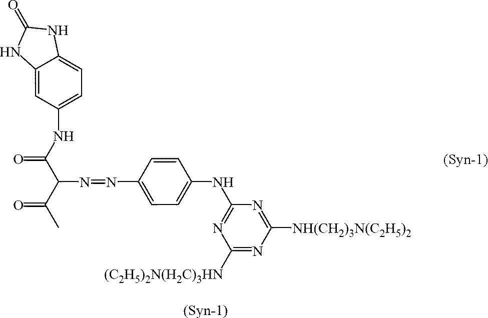

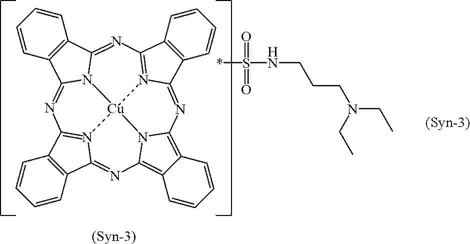

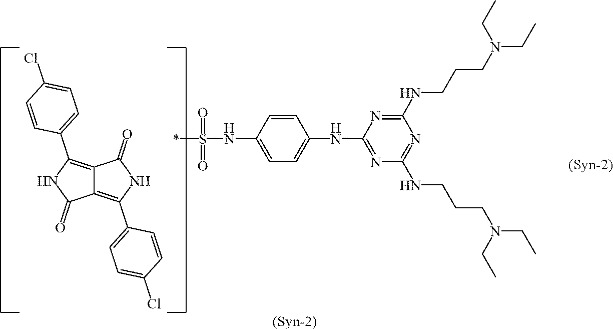

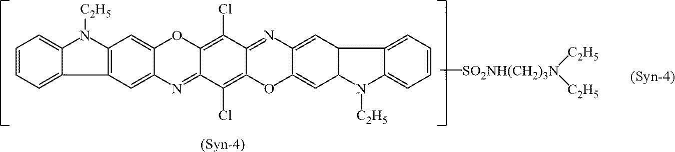

### (Dispersant)

B-1: 30% by mass of PGMEA solution of a resin B-1 synthesized by the following method

108 parts by mass of 1-thioglycerol, 174 parts by mass of pyromellitic acid anhydride, 650 parts by mass of methoxypropyl acetate, and 0.2 parts by mass of monobutyltin oxide as a catalyst were charged into a reaction container, the atmosphere gas was replaced with nitrogen gas, and the mixture was reacted at 120° C. for 5 hours (first step). It was confirmed by acid value measurement that 95% or more of the acid anhydride was half-esterified. Next, 160 parts by mass of the compound obtained in the first step expressed in terms of solid contents, 200 parts by mass of 2-hydroxypropyl methacrylate, 200 parts by mass of ethyl acrylate, 150 parts by mass of t-butyl acrylate, 200 parts by mass of 2-methoxyethyl acrylate, 200 parts by mass of methyl acrylate, 50 parts by mass of methacrylic acid, and 663 parts by mass of PGMEA were charged to a reaction container, the inside of the reaction container was heated to 80° C., 1.2 parts by mass of 2,2′-azobis(2,4-dimethylvaleronitrile) was added thereto, and the mixture was reacted for 12 hours (second step). It was confirmed by solid content measurement that 95% thereof was reacted. Finally, 500 parts by mass of PGMEA solution of 50% by mass of the compound obtained in the second step, 27.0 parts by mass of 2-methacryloyloxyethyl isocyanate (MOI), 0.1 parts by mass of hydroquinone were charged to a reaction container, the reaction was performed until the disappearance of the peak of 2270 cm⁻¹ based on the isocyanate group was confirmed (third step). After confirming the disappearance of the peak, the reaction solution was cooled to obtain a resin B-1 (resin having an acid group) having the following structure, in which an acid value was 68 mgKOH/g, an ethylenically unsaturated bond group value was 0.62 mmol/g, and a weight-average molecular weight was 13000.

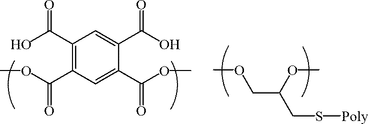

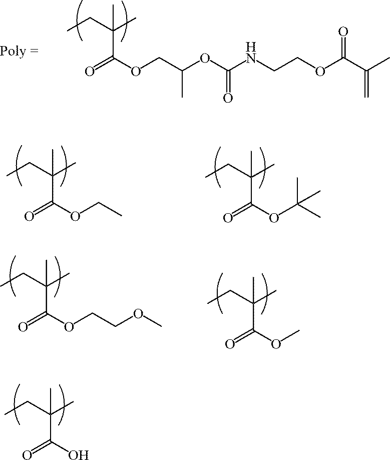

B-2: 30% by mass PGMEA solution of a resin having the following structure (the numerical value described together with the main chain indicates a molar ratio, and the numerical value described together with the side chain indicates the number of repeating units; resin having an acid group; weight-average molecular weight: 24,000, acid value: 52.5 mgKOH/g)

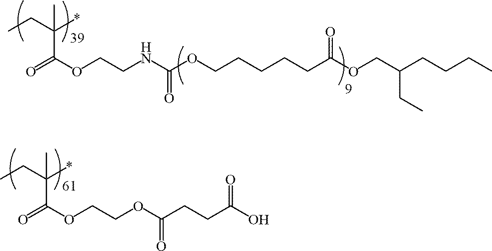

B-3: 30% by mass PGMEA solution of a resin having the following structure (the numerical value described together with the main chain indicates a molar ratio, and the numerical value described together with the side chain indicates the number of repeating units; resin having an acid group; weight-average molecular weight: 18,000, acid value: 82.1 mgKOH/g)

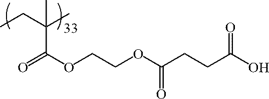

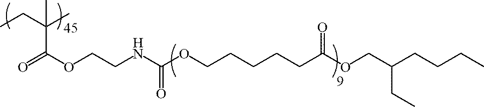

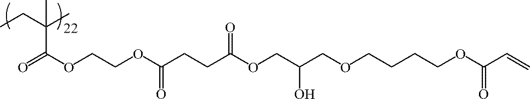

B-4: 30% by mass PGMEA solution of a resin having the following structure (the numerical value described together with the main chain indicates a molar ratio, and the numerical value described together with the side chain indicates the number of repeating units; resin having an acid group; weight-average molecular weight: 18,000, acid value: 82.1 mgKOH/g)

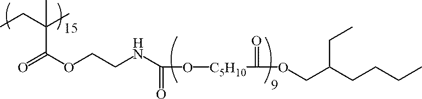

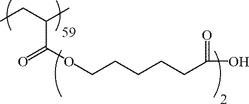

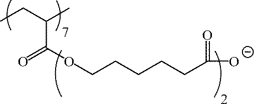

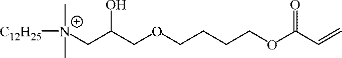

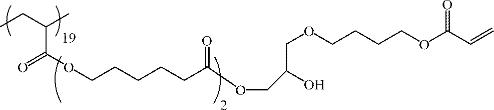

### (Solvent)

S-1 to S-5: solvents S-1 to S-5 described above

### -Production of Coloring Composition-

Each material was mixed at a proportion of Formulation 1 or 2 shown below, and the obtained mixture was filtered through a nylon filter (manufactured by Pall Corporation) having a pore size of 0.45 µm to produce a coloring composition.

Formulation 1

| | |
|---|---|
| Dispersion liquid described in table | ··· 77.1 parts by mass |
| Polymerizable compound described in table | ··· 0.9 parts by mass |
| 30% by mass PGMEA solution of resin B-5 | ··· 5.9 parts by mass |
| Photopolymerization initiator described in table | ··· 0.7 parts by mass |
| Surfactant described in table | ··· 0.02 parts by mass |
| Polymerization inhibitor (p-methoxyphenol) | ··· 0.0002 parts by mass |
| Solvent (PGMEA) | ··· 15.3 parts by mass |

Formulation 2

| | |
|---|---|
| Dispersion liquid described in table | ··· 83.6 parts by mass |
| Polymerizable compound described in table | ··· 0.7 parts by mass |
| 30% by mass PGMEA solution of resin B-5 | ··· 1.3 parts by mass |
| Photopolymerization initiator described in table | ··· 1.1 parts by mass |
| Surfactant described in table | ··· 0.02 parts by mass |
| Polymerization inhibitor (p-methoxyphenol) | ··· 0.0002 parts by mass |
| Solvent (PGMEA) | ··· 13.3 parts by mass |

TABLE 11

| | Type of formulation | Dispersion liquid | Polymerizable compound | | | | Photo polymerization initiator | Surfactant | Coloring material concentration (% by mass) |
|---|---|---|---|---|---|---|---|---|---|
| | | | Type | | Mixing ratio (mass ratio) | | | | |
| | | | Polymerizable compound 1 | Polymerizable compound 2 | Polymerizable compound 1 | Polymerizable compound 2 | | | |
| Green composition 1 | Formulation 1 | G-1 | M-1 | M-2 | 0.5 | 0.5 | I-1 | W-5 | 60 |
| Green composition 2 | Formulation 1 | G-2 | M-1 | M-3 | 0.5 | 0.5 | I-1 | W-5 | 60 |
| Green composition 3 | Formulation 1 | G-3 | M-1 | M-2 | 0.5 | 0.5 | I-1 | W-5 | 60 |
| Green composition 4 | Formulation 1 | G-4 | M-1 | M-3 | 0.5 | 0.5 | I-1 | W-5 | 60 |
| Red composition 1 | Formulation 2 | R-1 | M-1 | M-4 | 0.5 | 0.5 | I-1 | W-5 | 65 |
| Red composition 2 | Formulation 2 | R-2 | M-1 | M-4 | 0.5 | 0.5 | I-2 | W-5 | 65 |
| Red composition 3 | Formulation 2 | R-3 | M-1 | M-4 | 0.5 | 0.5 | I-1 | W-5 | 65 |
| Red composition 4 | Formulation 2 | R-4 | M-1 | M-4 | 0.5 | 0.5 | I-2 | W-5 | 65 |
| Blue composition 1 | Formulation 1 | B-1 | M-1 | M-4 | 0.5 | 0.5 | I-2 | W-5 | 60 |
| Blue composition 2 | Formulation 1 | B-2 | M-1 | M-4 | 0.5 | 0.5 | I-2 | W-5 | 60 |
| Blue composition 3 | Formulation 1 | B-3 | M-1 | M-4 | 0.5 | 0.5 | I-2 | W-5 | 60 |
| Blue composition 4 | Formulation 1 | B-4 | M-1 | M-4 | 0.5 | 0.5 | I-2 | W-5 | 60 |

### (Dispersion Liquid)

G-1 to G-4, R-1 to R-4, and B-1 to B-4: dispersion liquids G-1 to G-4, R-1 to R-4, and B-1 to B-4 described above

### (Resin)

B-5: resin having the following structure (the numerical value described together with the main chain indicates a molar ratio; resin having an acid group; weight-average molecular weight: 11,000, acid value: 69.2 mgKOH/g)

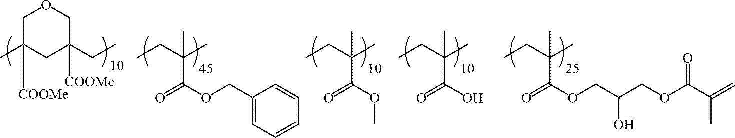

### (Polymerizable Compound)

M-1 to M-4: polymerizable compounds M-1 to M-4 described above

### (Photopolymerization Initiator)

I-1 and I-2: photopolymerization initiators I-1 and I-2 described above

### (Surfactant)

W-5: BYK-330 (manufactured by BYK Chemie; silicone-based surfactant)

### Test Example 1

As a support, a support (diameter: 8 inches (= 203.2 mm)) formed of materials shown in the following table was used. The composition for forming an underlayer film described in the forming table was applied onto the support by a spin coating method, and then the support was heated at 220° C. for 5 minutes using a hot plate to obtain an underlayer film. The coloring composition described in the following table was applied onto the support with an underlayer film by a spin coating method so that a film thickness after post-baking was 0.4 µm. Next, the support with an underlayer film was heated using a hot plate at 100° C. for 2 minutes to form a composition layer. Next, using an i-ray stepper exposure device (FPA-3000 i5+, manufactured by Canon Inc.), the composition layer was irradiated with light having a wavelength of 365 nm through a mask pattern in which each of the square pixels with a side length of 1.0 µm was arranged on the support in a region of 4 mm × 3 mm to perform exposure thereon with an exposure amount of 500 mJ/cm². The composition layer after exposure was subjected to puddle development for 60 seconds at 23° C. using a 0.3% by mass of aqueous solution of tetramethylammonium hydroxide. Next, the composition layer was rinsed by spin showering with water and was cleaned with pure water. Thereafter, water droplets were splashed by high-pressure air, and the silicon wafer was naturally dried. Next, post-baking was performed for 300 seconds at 200° C. using a hot plate to form a pixel. With regard to the obtained pixel, an image including the pixel and 8 pixels around the pixel (unexposed base portion) was acquired using a length measurement SEM “S-9260A” (manufactured by Hitachi High-Tech Corporation), an area occupied by residues in the base portion was calculated by image analysis, and the residues were evaluated according to the following standard. A case of 0% means that there is no residue at all, and a case of 100% means that the residues are completely filled. In the following evaluation standard, “5” is the most excellent.

### [Evaluation Standard]

1: 51% to 100%
2: 31% to 50%
3: 11% to 30%
4: 4% to 10%
5: 0% to 3%

TABLE 12

| | Material of support | Composition for forming underlayer film | | Type of coloring composition | Evaluation result of residues |
|---|---|---|---|---|---|
| | | Type | Film thickness (nm) | | |
| Example 1-1 | Si | Composition for forming underlayer film 1 | 3 | Green composition 1 | 5 |
| Example 1-2 | SiN | Composition for forming underlayer film 1 | 3 | Green composition 1 | 5 |
| Example 1-3 | SiO₂ | Composition for forming underlayer film 1 | 3 | Green composition 1 | 5 |
| Example 1-4 | Quartz | Composition for forming underlayer film 1 | 3 | Green composition 1 | 5 |
| Comparative Example 1-1 | Si | Composition for forming underlayer film r1 | 3 | Green composition 1 | 1 |

As shown in the above table, in Examples, the generation of residues was suppressed.

### Test Example 2

### -Production of Support With Partition Wall-

A composition for a partition wall was applied onto a silicon wafer with a diameter of 8 inches (= 203.2 mm) by a spin coating method so that a film thickness after post-baking was 0.4 µm, and the silicon wafer was heated at 100° C. for 120 seconds and then at 200° C. for 300 seconds using a hot plate to form a partition wall material layer.

A positive type photoresist for KrF was applied onto the partition wall material layer with a spin coater, and a heating treatment was performed at 100° C. for 2 minutes to form a photoresist layer having a film thickness of 1.0 µm. Next, the corresponding region was exposed in a patterned manner with an exposure amount of 30 mJ/cm², and then heat-treated at 110° C. for 1 minute. Thereafter, a development treatment was performed with a developer for 1 minute, and then a post-baking treatment was performed at 100° C. for 1 minute to remove a photoresist in a region where pixels were to be formed. Next, the partition wall material layer was treated under the following dry etching conditions, and in a case where the pixel size was 1.0 µm, partition walls having a width of 0.1 µm were formed in a lattice form with a pitch width of 1.1 µm. A width of the partition wall opening portion was 1.0 µm. In addition, in a case where the pixel size was 0.7 µm, partition walls having a width of 0.1 µm were formed in a lattice form with a pitch width of 0.8 µm. A width of the partition wall opening portion was 0.7 µm. The pitch width of the partition wall is the total of the width of the opening portion of the partition wall and the width of the partition wall.

### (Composition for Partition Wall)

As the composition for a partition wall, a composition for a partition wall in which 44.8 parts by mass of a silica particle solution 1, 0.2 parts by mass of a surfactant (KF-6001, Shin-Etsu Chemical Co., Ltd.; silicone-based surfactant), 8 parts by mass of 1,4-butanediol diacetate, 43 parts by mass of propylene glycol monomethyl ether (PGMEA), 2 parts by mass of methanol, 1 part by mass of ethanol, and 1 part by mass of water were mixed, and filtration was performed using DFA4201NIEY (0.45 µm nylon filter) manufactured by Nihon Pall Corporation was used.

Materials used for the composition for a partition wall are as follows.

· Silica particle solution 1: silica particle solution which was prepared by 3.0 g of trimethylmethoxysilane as a hydrophobizing treatment agent was added to 100.0 g of PGME solution (silica particle concentration: 20 mass%) of silica particles (beaded silica) in which a plurality of spherical silicas having an average particle diameter of 15 nm were linked in a beaded shape by metal oxide-containing silica (linking material), and the mixture was reacted at 20° C. for 6 hours. As the average particle diameter of the spherical silica in the silica particle solution 1, the number average of circle-equivalent diameters in a projection image of the spherical portions of 50 spherical silicas measured by a transmission electron microscope (TEM) was calculated and obtained. In addition, in the silica particle solution 1, by a method of TEM observation, it was investigated whether or not the silica particle solution included silica particles having a shape in which a plurality of spherical silicas were linked in a beaded shape.

### (Dry Etching Conditions)

The dry etching conditions were as follows.
Equipment used: U-621 manufactured by Hitachi High-Tech Corporation
Pressure: 2.0 Pa
$${\text{Gas used: Ar/C}}_{4} {\text{F}}_{6} {\text{/O}}_{2} \text{= 1000/20/50} \text{mL} / \text{min}$$
Treatment temperature: 20° C.
Source power: 500 W
$$\text{Upper bias} / \text{electrode bias} = 500 / 1000 \text{W}$$
Treatment time: 220 sec

A refractive index of the partition wall with respect to light having a wavelength of 300 nm was 1.26 The refractive index of the partition wall was measured by the following method. That is, the composition for a partition wall was applied to a quartz glass substrate using a spin coater (manufactured by Mikasa Co., Ltd.) to form a coating film, heated (pre-baked) at 100° C. for 120 seconds using a hot plate, and then heated (post-baked) at 200° C. for 300 seconds using a hot plate to form a film having a thickness of 0.3 µm. With regard to the obtained film, the refractive index with respect to light having a wavelength of 300 nm was measured using ellipsometry VUV-VASE (manufactured by J.A. Woollam Co., Inc.).

### -Evaluation of Residues-

The composition for forming an underlayer film described in the following table was applied onto the support on which the partition walls were formed by a spin coating method, and then the support was heated at 220° C. for 5 minutes using a hot plate to obtain an underlayer film. The support with an underlayer film was used for pixels in the same manner as in Test Example 1, and the residues were evaluated by the same method as in Test Example 1.

TABLE 13

| | Composition for forming underlayer film | | Type of coloring composition | Evaluation result of residues |
|---|---|---|---|---|
| | Type | Film thickness (nm) | | |
| Example 2-1 | Composition for forming underlayer film 1 | 3 | Green composition 1 | 5 |
| Example 2-2 | Composition for forming underlayer film 2 | 3 | Green composition 1 | 5 |
| Example 2-3 | Composition for forming underlayer film 3 | 3 | Green composition 1 | 5 |
| Example 2-4 | Composition for forming underlayer film 4 | 3 | Green composition 1 | 5 |
| Example 2-5 | Composition for forming underlayer film 5 | 3 | Green composition 1 | 5 |
| Example 2-6 | Composition for forming underlayer film 6 | 3 | Green composition 1 | 5 |
| Example 2-7 | Composition for forming underlayer film 7 | 3 | Green composition 1 | 4 |
| Example 2-8 | Composition for forming underlayer film 8 | 3 | Green composition 1 | 5 |
| Example 2-9 | Composition for forming underlayer film 9 | 3 | Green composition 1 | 5 |
| Example 2-10 | Composition for forming underlayer film 10 | 3 | Green composition 1 | 5 |
| Example 2-11 | Composition for forming underlayer film 11 | 3 | Green composition 1 | 5 |
| Example 2-12 | Composition for forming underlayer film 12 | 3 | Green composition 1 | 5 |
| Example 2-13 | Composition for forming underlayer film 13 | 3 | Green composition 1 | 5 |
| Example 2-14 | Composition for forming underlayer film 14 | 3 | Green composition 1 | 4 |
| Example 2-15 | Composition for forming underlayer film 15 | 3 | Green composition 1 | 5 |
| Example 2-16 | Composition for forming underlayer film 16 | 3 | Green composition 1 | 5 |
| Example 2-17 | Composition for forming underlayer film 17 | 3 | Green composition 1 | 5 |
| Example 2-18 | Composition for forming underlayer film 18 | 3 | Green composition 1 | 5 |
| Example 2-19 | Composition for forming underlayer film 19 | 3 | Green composition 1 | 4 |
| Example 2-20 | Composition for forming underlayer film 20 | 3 | Green composition 1 | 5 |
| Example 2-21 | Composition for forming underlayer film 21 | 3 | Green composition 1 | 5 |
| Example 2-22 | Composition for forming underlayer film 22 | 3 | Green composition 1 | 5 |
| Example 2-23 | Composition for forming underlayer film 23 | 3 | Green composition 1 | 5 |
| Example 2-24 | Composition for forming underlayer film 24 | 3 | Green composition 1 | 5 |
| Example 2-25 | Composition for forming underlayer film 25 | 3 | Green composition 1 | 5 |
| Example 2-26 | Composition for forming underlayer film 26 | 3 | Green composition 1 | 4 |
| Example 2-27 | Composition for forming underlayer film 27 | 3 | Green composition 1 | 5 |
| Example 2-28 | Composition for forming underlayer film 28 | 3 | Green composition 1 | 5 |
| Example 2-29 | Composition for forming underlayer film 29 | 3 | Green composition 1 | 5 |
| Example 2-30 | Composition for forming underlayer film 30 | 3 | Green composition 1 | 4 |
| Example 2-31 | Composition for forming underlayer film 31 | 3 | Green composition 1 | 4 |
| Example 2-32 | Composition for forming underlayer film 32 | 3 | Green composition 1 | 5 |
| Example 2-33 | Composition for forming underlayer film 33 | 3 | Green composition 1 | 4 |
| Example 2-34 | Composition for forming underlayer film 34 | 3 | Green composition 1 | 4 |
| Example 2-35 | Composition for forming underlayer film 35 | 3 | Green composition 1 | 4 |
| Example 2-36 | Composition for forming underlayer film 36 | 3 | Green composition 1 | 4 |
| Example 2-37 | Composition for forming underlayer film 37 | 3 | Green composition 1 | 4 |
| Example 2-38 | Composition for forming underlayer film 38 | 3 | Green composition 1 | 4 |
| Example 2-39 | Composition for forming underlayer film 39 | 3 | Green composition 1 | 4 |
| Example 2-40 | Composition for forming underlayer film 40 | 3 | Green composition 1 | 4 |

TABLE 14

| | Composition for forming underlayer film | | Type of coloring composition | Evaluation result of residues |
|---|---|---|---|---|
| | Type | Film thickness (nm) | | |
| Example 2-41 | Composition for forming underlayer film 41 | 3 | Green composition 1 | 4 |
| Example 2-42 | Composition for forming underlayer film 42 | 3 | Green composition 1 | 5 |
| Example 2-43 | Composition for forming underlayer film 43 | 3 | Green composition 1 | 5 |
| Example 2-44 | Composition for forming underlayer film 44 | 3 | Green composition 1 | 5 |
| Example 2-45 | Composition for forming underlayer film 45 | 3 | Green composition 1 | 5 |
| Example 2-46 | Composition for forming underlayer film 46 | 3 | Green composition 1 | 5 |
| Example 2-47 | Composition for forming underlayer film 47 | 3 | Green composition 1 | 5 |
| Example 2-48 | Composition for forming underlayer film 48 | 3 | Green composition 1 | 5 |
| Example 2-49 | Composition for forming underlayer film 49 | 3 | Green composition 1 | 5 |
| Example 2-50 | Composition for forming underlayer film 50 | 3 | Green composition 1 | 5 |
| Example 2-51 | Composition for forming underlayer film 51 | 3 | Green composition 1 | 5 |
| Example 2-52 | Composition for forming underlayer film 52 | 3 | Green composition 1 | 5 |
| Example 2-53 | Composition for forming underlayer film 53 | 3 | Green composition 1 | 5 |
| Example 2-54 | Composition for forming underlayer film 54 | 3 | Green composition 1 | 5 |
| Example 2-55 | Composition for forming underlayer film 55 | 3 | Green composition 1 | 4 |
| Example 2-56 | Composition for forming underlayer film 56 | 3 | Green composition 1 | 4 |
| Example 2-57 | Composition for forming underlayer film 57 | 3 | Green composition 1 | 5 |
| Example 2-58 | Composition for forming underlayer film 58 | 3 | Green composition 1 | 5 |
| Example 2-59 | Composition for forming underlayer film 59 | 3 | Green composition 1 | 5 |
| Example 2-60 | Composition for forming underlayer film 60 | 3 | Green composition 1 | 5 |
| Example 2-61 | Composition for forming underlayer film 61 | 3 | Green composition 1 | 5 |
| Example 2-62 | Composition for forming underlayer film 62 | 3 | Green composition 1 | 5 |
| Example 2-63 | Composition for forming underlayer film 63 | 3 | Green composition 1 | 5 |
| Example 2-64 | Composition for forming underlayer film 64 | 3 | Green composition 1 | 5 |
| Example 2-65 | Composition for forming underlayer film 65 | 3 | Green composition 1 | 5 |
| Example 2-66 | Composition for forming underlayer film 66 | 3 | Green composition 1 | 5 |
| Example 2-67 | Composition for forming underlayer film 67 | 1 | Green composition 1 | 5 |
| Example 2-68 | Composition for forming underlayer film 68 | 10 | Green composition 1 | 5 |
| Example 2-69 | Composition for forming underlayer film 69 | 20 | Green composition 1 | 4 |
| Example 2-70 | Composition for forming underlayer film 70 | 30 | Green composition 1 | 4 |
| Example 2-71 | Composition for forming underlayer film 1 | 3 | Green composition 2 | 5 |
| Example 2-72 | Composition for forming underlayer film 1 | 3 | Green composition 3 | 5 |
| Example 2-73 | Composition for forming underlayer film 1 | 3 | Green composition 4 | 5 |
| Example 2-74 | Composition for forming underlayer film 1 | 3 | Red composition 1 | 5 |
| Example 2-75 | Composition for forming underlayer film 1 | 3 | Red composition 2 | 5 |
| Example 2-76 | Composition for forming underlayer film 1 | 3 | Red composition 3 | 5 |
| Example 2-77 | Composition for forming underlayer film 1 | 3 | Red composition 4 | 5 |
| Example 2-78 | Composition for forming underlayer film 1 | 3 | Blue composition 1 | 5 |
| Example 2-79 | Composition for forming underlayer film 1 | 3 | Blue composition 2 | 5 |
| Example 2-80 | Composition for forming underlayer film 1 | 3 | Blue composition 3 | 5 |

TABLE 15

| | Composition for forming underlayer film | | Type of coloring composition | Evaluation result of residues |
|---|---|---|---|---|
| | Type | Film thickness (nm) | | |
| Example 2-81 | Composition for forming underlayer film 1 | 3 | Blue composition 4 | 5 |
| Example 2-82 | Composition for forming underlayer film 71 | 3 | Green composition 1 | 5 |
| Example 2-83 | Composition for forming underlayer film 72 | 3 | Green composition 1 | 5 |
| Example 2-84 | Composition for forming underlayer film 73 | 3 | Green composition 1 | 5 |
| Example 2-85 | Composition for forming underlayer film 74 | 3 | Green composition 1 | 5 |
| Example 2-86 | Composition for forming underlayer film 75 | 3 | Green composition 1 | 5 |
| Example 2-87 | Composition for forming underlayer film 76 | 3 | Green composition 1 | 5 |
| Example 2-88 | Composition for forming underlayer film 77 | 3 | Green composition 1 | 5 |
| Example 2-89 | Composition for forming underlayer film 78 | 3 | Green composition 1 | 5 |
| Example 2-90 | Composition for forming underlayer film 79 | 3 | Green composition 1 | 5 |
| Example 2-91 | Composition for forming underlayer film 80 | 3 | Green composition 1 | 4 |
| Comparative Example 2-1 | Composition for forming underlayer film r1 | 3 | Green composition 1 | 1 |

As shown in the above table, in Examples, the generation of residues was suppressed.

The same effect was obtained even in a case where, from the Green compositions 1 to 4, Red compositions 1 to 4, and Blue compositions 1 to 4, the surfactant W-5 were changed to surfactants W-1 to W-4, and W-6 to W-44.

### (Surfactant)

W-1: compound having the following structure (weight-average molecular weight: 14,000; in the formula, “%” representing the proportion of a repeating unit is mol%)

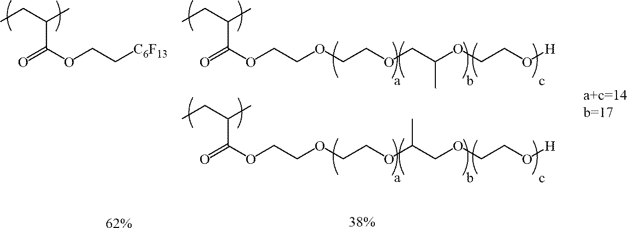

W-2: FZ-2122 (manufactured Dow Corning Toray Co., Ltd.; silicone-based surfactant)
W-3: BYK-322 (manufactured by BYK Chemie; silicone-based surfactant)
W-4: BYK-323 (manufactured by BYK Chemie; silicone-based surfactant)
W-6: BYK-3760 (manufactured by BYK Chemie; silicone-based surfactant)
W-7: BYK-UV3510 (manufactured by BYK Chemie; silicone-based surfactant)
W-8: KF-6001 (Shin-Etsu Chemical Co., Ltd.; silicone-based surfactant)
W-9: MEGAFACE F-477 (manufactured by DIC Corporation; fluorine-based surfactant)
W-10: MEGAFACE F-554 (manufactured by DIC Corporation; fluorine-based surfactant)
W-11: MEGAFACE F-555-A (manufactured by DIC Corporation; fluorine-based surfactant)
W-12: MEGAFACE F-556 (manufactured by DIC Corporation; fluorine-based surfactant)
W-13: MEGAFACE F-557 (manufactured by DIC Corporation; fluorine-based surfactant)
W-14: MEGAFACE F-558 (manufactured by DIC Corporation; fluorine-based surfactant)
W-15: MEGAFACE F-559 (manufactured by DIC Corporation; fluorine-based surfactant)
W-16: MEGAFACE F-560 (manufactured by DIC Corporation; fluorine-based surfactant)
W-17: MEGAFACE F-561 (manufactured by DIC Corporation; fluorine-based surfactant)
W-18: MEGAFACE F-563 (manufactured by DIC Corporation; fluorine-based surfactant)
W-19: MEGAFACE F-565 (manufactured by DIC Corporation; fluorine-based surfactant)
W-20: MEGAFACE F-568 (manufactured by DIC Corporation; fluorine-based surfactant)
W-21: MEGAFACE F-575 (manufactured by DIC Corporation; fluorine-based surfactant)
W-22: MEGAFACE R-01 (manufactured by DIC Corporation; fluorine-based surfactant)
W-23: MEGAFACE R-40 (manufactured by DIC Corporation; fluorine-based surfactant)
W-24: MEGAFACE R-40-LM (manufactured by DIC Corporation; fluorine-based surfactant)
W-25: MEGAFACE R-41 (manufactured by DIC Corporation; fluorine-based surfactant)
W-26: MEGAFACE R-41-LM (manufactured by DIC Corporation; fluorine-based surfactant)
W-27: MEGAFACE R-94 (manufactured by DIC Corporation; fluorine-based surfactant)
W-28: MEGAFACE DS-21 (manufactured by DIC Corporation; fluorine-based surfactant)
W-29: MEGAFACE RS-43 (manufactured by DIC Corporation; fluorine-based surfactant)
W-30: MEGAFACE RS-72-K (manufactured by DIC Corporation; fluorine-based surfactant)
W-31: MEGAFACE RS-90 (manufactured by DIC Corporation; fluorine-based surfactant)
W-32: MEGAFACE TF-1956 (manufactured by DIC Corporation; fluorine-based surfactant)
W-33: FTERGENT 208G (NEOS COMPANY LIMITED; fluorine-based surfactant)
W-34: FTERGENT 215 M (NEOS COMPANY LIMITED; fluorine-based surfactant)
W-35: FTERGENT 245F (NEOS COMPANY LIMITED; fluorine-based surfactant)
W-36: FTERGENT 601AD (NEOS COMPANY LIMITED; fluorine-based surfactant)
W-37: FTERGENT 601ADH2 (NEOS COMPANY LIMITED; fluorine-based surfactant)
W-38: FTERGENT 602A (NEOS COMPANY LIMITED; fluorine-based surfactant)
W-39: FTERGENT 610FM (NEOS COMPANY LIMITED; fluorine-based surfactant)
W-40: FTERGENT 710FL (NEOS COMPANY LIMITED; fluorine-based surfactant)
W-41: FTERGENT 710FM (NEOS COMPANY LIMITED; fluorine-based surfactant)
W-42: FTERGENT 710FS (NEOS COMPANY LIMITED; fluorine-based surfactant)
W-43: FTERGENT FTX-218 (NEOS COMPANY LIMITED; fluorine-based surfactant)
W-44: PolyFox PF6320 (manufactured by OMNOVA Solutions Inc.; fluorine-based surfactant)

### Test Example 3

The composition 40 or 41 for an underlayer film was applied onto a silicon wafer with a diameter of 8 inches (= 203.2 mm) by a spin coating method, and then heated and dried at 90° C. for 2 minutes using a hot plate. Furthermore, using an ultraviolet photoresist curing device (UMA-802-HC-552, manufactured by USHIO INC.), the entire surface of the composition for forming an underlayer film was irradiated with ultraviolet rays at an exposure amount of 3000 mJ/cm² to form an underlayer film having a thickness of 3 nm. The support with an underlayer film was used for pixels in the same manner as in Test Example 1, and the residues were evaluated by the same method as in Test Example 1. The Green composition 1 was used as the coloring composition. In any case where the composition 40 or 41 for forming an underlayer film was used, the evaluation standard of residues was “5” according to the above-described evaluation standard.

### Test Example 4

A partition wall was formed on a support having a diameter of 8 inches (= 203.2 mm) on which a silicon photodiode had been formed, by the same method as in Test Example 2, and then the composition 1 for forming an underlayer film was applied onto the support by a spin coating method, and heated at 220° C. for 5 minutes using a hot plate to form an underlayer film having a film thickness of 3 nm. The Green composition 1 was applied onto the support with an underlayer film by a spin coating method so that a film thickness after post-baking was 0.4 µm. Next, the support with an underlayer film was heated using a hot plate at 100° C. for 2 minutes to form a composition layer. Next, using a KrF scanner exposure device (FPA-6300 ES6a, manufactured by Canon Inc.), the composition layer was irradiated with light having a wavelength of 248 nm through a mask pattern in which Bayer patterns each having a side of 0.7 µm were arranged in a region of 4 mm × 3 mm on the support to perform exposure thereon with an exposure amount of 200 mJ/cm². The composition layer after exposure was subjected to puddle development for 60 seconds at 23° C. using a 0.3% by mass of aqueous solution of tetramethylammonium hydroxide. Next, the composition layer was rinsed by spin showering with water and was cleaned with pure water. Thereafter, water droplets were splashed by high-pressure air, and the support was naturally dried. Next, post-baking was performed for 300 seconds at 200° C. using a hot plate to form a green pixel.

The Blue composition 1 was applied onto the support on which the green pixel was formed by a spin coating method so that a film thickness after post-baking was 0.4 µm. Next, the support with an underlayer film was heated using a hot plate at 100° C. for 2 minutes to form a composition layer. Next, using a KrF scanner exposure device (FPA-6300 ES6a, manufactured by Canon Inc.), the composition layer was irradiated with light having a wavelength of 248 nm through a mask pattern in which square patterns each having a side of 0.7 µm were arranged in a region of 4 mm × 3 mm on the support to perform exposure thereon with an exposure amount of 200 mJ/cm². The composition layer after exposure was subjected to puddle development for 60 seconds at 23° C. using a 0.3% by mass of aqueous solution of tetramethylammonium hydroxide. Next, the composition layer was rinsed by spin showering with water and was cleaned with pure water. Thereafter, water droplets were splashed by high-pressure air, and the silicon wafer was naturally dried. Next, post-baking was performed for 300 seconds at 200° C. using a hot plate to form a blue pixel.

The Red composition 1 was applied onto the support on which the green pixel and the blue pixel were formed by a spin coating method so that a film thickness after post-baking was 0.4 µm. Next, the support with an underlayer film was heated using a hot plate at 100° C. for 2 minutes to form a composition layer. Next, using a KrF scanner exposure device (FPA-6300 ES6a, manufactured by Canon Inc.), the composition layer was irradiated with light having a wavelength of 248 nm through a mask pattern in which square patterns each having a side of 0.7 µm were arranged in a region of 4 mm × 3 mm on the support to perform exposure thereon with an exposure amount of 200 mJ/cm². The composition layer after exposure was subjected to puddle development for 60 seconds at 23° C. using a 0.3% by mass of aqueous solution of tetramethylammonium hydroxide. Next, the composition layer was rinsed by spin showering with water and was cleaned with pure water. Thereafter, water droplets were splashed by high-pressure air, and the support was naturally dried. Next, post-baking was performed for 300 seconds at 200° C. using a hot plate to form a red pixel, thereby manufacturing a color filter including a green pixel, a blue pixel, and a red pixel. As a result of incorporating the color filter into a solid-state imaging element according to a known method, good image performance was obtained.

### Test Example 5

A partition wall was formed on a support having a diameter of 8 inches (= 203.2 mm) on which a silicon photodiode had been formed, by the same method as in Test Example 2, and then the composition 1 for forming an underlayer film was applied onto the support by a spin coating method, and heated at 220° C. for 5 minutes using a hot plate to form an underlayer film having a film thickness of 3 nm. The Green composition 1 was applied onto the support with an underlayer film by a spin coating method so that a film thickness after post-baking was 0.4 µm. Next, the support with an underlayer film was heated using a hot plate at 100° C. for 2 minutes to form a composition layer. Next, using a KrF scanner exposure device (FPA-6300 ES6a, manufactured by Canon Inc.), the composition layer was irradiated with light having a wavelength of 248 nm through a mask pattern in which Bayer patterns each having a side of 0.7 µm were arranged in a region of 4 mm × 3 mm on the support to perform exposure thereon with an exposure amount of 200 mJ/cm². The composition layer after exposure was subjected to puddle development for 60 seconds at 23° C. using a 0.3% by mass of aqueous solution of tetramethylammonium hydroxide. Next, the composition layer was rinsed by spin showering with water and was cleaned with pure water. Thereafter, water droplets were splashed by high-pressure air, and the silicon wafer was naturally dried. Next, post-baking was performed for 300 seconds at 200° C. using a hot plate to form a green pixel.

The composition 1 for forming an underlayer film was applied onto the silicon wafer on which the green pixel was formed by a spin coating method, and then the silicon wafer was heated at 220° C. for 5 minutes using a hot plate to form an underlayer film having a film thickness of 3 nm. Furthermore, the Blue composition 1 was applied onto the support by a spin coating method so that a film thickness after post-baking was 0.4 µm. Next, the support with an underlayer film was heated using a hot plate at 100° C. for 2 minutes to form a composition layer. Next, using a KrF scanner exposure device (FPA-6300 ES6a, manufactured by Canon Inc.), the composition layer was irradiated with light having a wavelength of 248 nm through a mask pattern in which square patterns each having a side of 0.7 µm were arranged in a region of 4 mm × 3 mm on the support to perform exposure thereon with an exposure amount of 200 mJ/cm². The composition layer after exposure was subjected to puddle development for 60 seconds at 23° C. using a 0.3% by mass of aqueous solution of tetramethylammonium hydroxide. Next, the composition layer was rinsed by spin showering with water and was cleaned with pure water. Thereafter, water droplets were splashed by high-pressure air, and the silicon wafer was naturally dried. Next, post-baking was performed for 300 seconds at 200° C. using a hot plate to form a blue pixel.

The composition 1 for forming an underlayer film was applied onto the support on which the green pixel and the blue pixel were formed by a spin coating method, and then the support was heated at 220° C. for 5 minutes using a hot plate to form an underlayer film having a film thickness of 3 nm. Furthermore, the Red composition 1 was applied onto the support by a spin coating method so that a film thickness after post-baking was 0.4 µm. Next, the support with an underlayer film was heated using a hot plate at 100° C. for 2 minutes to form a composition layer. Next, using a KrF scanner exposure device (FPA-6300 ES6a, manufactured by Canon Inc.), the composition layer was irradiated with light having a wavelength of 248 nm through a mask pattern in which square patterns each having a side of 0.7 µm were arranged in a region of 4 mm × 3 mm on the support to perform exposure thereon with an exposure amount of 200 mJ/cm². The composition layer after exposure was subjected to puddle development for 60 seconds at 23° C. using a 0.3% by mass of aqueous solution of tetramethylammonium hydroxide. Next, the composition layer was rinsed by spin showering with water and was cleaned with pure water. Thereafter, water droplets were splashed by high-pressure air, and the support was naturally dried. Next, post-baking was performed for 300 seconds at 200° C. using a hot plate to form a red pixel, thereby producing a color filter including a green pixel, a blue pixel, and a red pixel. As a result of incorporating the color filter into a solid-state imaging element according to a known method, better image performance than that of Test Example 4 was obtained. It is presumed that, by alternately performing the step of forming the underlayer film and the step of forming the pixels of each color, it was possible to suppress the residues of the coloring composition to be formed next to remain on the previously formed pixels.

### EXPLANATION OF REFERENCES

10: support
11: partition wall
31 to 33: pixel

What is claimed is:

1. A composition for forming an underlayer film of a color filter, the composition comprising:
a resin A; and
a solvent B,
wherein the resin A includes a resin a-1 having an alkyleneoxy structure,
a content of the resin a-1 in a total solid content of the composition for forming an underlayer film is 50% by mass or more, and
a concentration of solid contents of the composition for forming an underlayer film is 1% by mass or less.

2. The composition for forming an underlayer film according to claim 1,
wherein a content of the resin A in the total solid content of the composition for forming an underlayer film is 50% by mass or more.

3. The composition for forming an underlayer film according to claim 1,
wherein the alkyleneoxy structure included in the resin a-1 is a structure represented by Formula (AO-1), 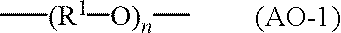
in the formula, R¹ represents an alkylene group and n represents a number of 2 or more.

4. The composition for forming an underlayer film according to claim 1,
wherein an acid value of the resin a-1 is 40 mgKOH/g or less.

5. The composition for forming an underlayer film according to claim 1,
wherein the resin a-1 includes a polymerizable group.

6. The composition for forming an underlayer film according to claim 1,
wherein the resin a-1 includes a repeating unit having a group including an alkyleneoxy structure and a repeating unit having a polymerizable group.

7. The composition for forming an underlayer film according to claim 5,
wherein the polymerizable group is an ethylenically unsaturated bond-containing group or a cyclic ether group.

8. The composition for forming an underlayer film according to claim 1, further comprising: a surfactant.

9. The composition for forming an underlayer film according to claim 1, further comprising: a polymerizable compound other than the resin A.

10. The composition for forming an underlayer film according to claim 9,
wherein a total content of the resin A and the polymerizable compound in the total solid content of the composition for forming an underlayer film is 70% to 100% by mass.

11. The composition for forming an underlayer film according to claim 9,
wherein the polymerizable compound includes a compound having an ethylenically unsaturated bond-containing group, and
the composition for forming an underlayer film further includes a photopolymerization initiator.

12. A color filter comprising:
a support;
an underlayer film formed on the support; and
a pixel formed on the underlayer film,
wherein the underlayer film includes a resin a-1 having an alkyleneoxy structure in an amount of 50% by mass or more, and
a film thickness of the underlayer film is 30 nm or less.

13. The color filter according to claim 12,
wherein a partition wall is formed on a surface of the support,
the underlayer film is formed on the support and in a region comparted by the partition wall, and
the pixel is formed on the underlayer film.

14. A method for manufacturing a color filter, comprising:
a step of forming an underlayer film by applying the composition for forming an underlayer film according to claim 1 onto a support; and
a step of forming a pixel on the underlayer film,
wherein the step of forming the pixel includes a step of applying a composition for forming a pixel to form a composition layer for forming a pixel, a step of exposing the composition layer for forming a pixel in a patterned manner, and a step of removing a non-exposed portion of the composition layer for forming a pixel by development.

15. The method for manufacturing a color filter according to claim 14,
wherein in the exposing step, the composition layer for forming a pixel is exposed by irradiation with light having a wavelength of 300 nm or less.

16. The method for manufacturing a color filter according to claim 14,
wherein the step of forming the underlayer film and the step of forming the pixel are alternately performed two or more times to form two or more types of pixels.

17. A solid-state imaging element comprising:
the color filter according to claim 12.

18. An image display device comprising:
the color filter according to claim 12.
